(19) United States
(12) Patent Application Publication
(10) Pub. No.: US 2018/0117767 A1
(43) Pub. Date: May 3, 2018

(54) ROBOT SYSTEM

(71) Applicant: Seiko Epson Corporation, Tokyo (JP)

(72) Inventors: Masato YOKOTA, Azumino (JP); Tomohiro KUMAGAI, Matsumoto (JP); Noriaki KOTANI, Hara-mura (JP)

(21) Appl. No.: 15/799,008

(22) Filed: Oct. 31, 2017

(30) Foreign Application Priority Data
Nov. 1, 2016 (JP) 2016-214723

(51) Int. Cl. B25J 9/16; G01R 31/28; B25J 13/08; B25J 15/06; B25J 21/00

(52) U.S. Cl. CPC B25J 9/1679; G01R 31/2893; B25J 21/00; B25J 13/086; B25J 15/0616; B25J 13/085

(57) ABSTRACT

A robot system includes a supply section configured to supply an object, a first test section group including a plurality of first test sections configured to test the supplied object, a second test section group including a plurality of second test sections configured to test the supplied object, a collecting section configured to collect the tested object, and a robot including a robot arm and configured to hold, convey, and release the object. The robot is capable of collectively conveying a plurality of the objects. A total of conveyance times for the conveyance of the object by the robot from the supply to the collection of the object is shorter than a total of processing times for the holding and the release of the object by the robot.

### BACKGROUND

### 1. Technical Field

The present invention relates to a robot system.

### 2. Related Art

There has been known a test handler for testing an electric characteristic of an electronic component.

As such a test handler, for example, JP-A-2013-219354 (Patent Literature 1) discloses a test handler module including a supply conveyor that conveys a substrate, a test chamber in which a test of the substrate conveyed from the supply conveyor is performed, and a discharge conveyor that conveys the substrate for which the test is completed. The test handler module further includes a conveyance robot that receives the substrate from the supply conveyor and conveys the substrate to the test chamber. The conveyance robot performs work for receiving the substrate from the test chamber and delivering the substrate to the discharge conveyor.

However, in the test handler module described in Patent Literature 1, the conveyance robot can convey only one object at a time. Therefore, a time for conveying a plurality of objects from the supply conveyor to the test chamber is long. Similarly, a time for conveying the plurality of objects from the test chamber to the discharge conveyor is long. Therefore, in the test handler module, it is difficult to increase a throughput.

### SUMMARY

An advantage of some aspects of the invention is to solve at least a part of the problems described above, and the invention can be implemented as the following configurations.

A robot system according to an aspect of the invention includes: a supply section configured to supply an object; a first test section group including a plurality of first test sections configured to test the supplied object; a second test section group including a plurality of second test sections configured to test the supplied object; a collecting section configured to collect the tested object; and a robot including a robot arm and configured to hold, convey, and release the object. The robot is capable of collectively conveying a plurality of the objects. A total of conveyance times for the conveyance of the object by the robot from the supply to the collection of the object is shorter than a total of processing times for the holding and the release of the object by the robot.

With the robot system according to the aspect of the invention, the robot can collectively convey the plurality of objects. Therefore, it is possible to collectively convey the plurality of objects to the first test section group or the second test section group at a time. Since the robot system includes the plurality of first test sections and the plurality of second test sections, it is possible to perform tests of the plurality of objects with one robot system. Further, with the robot system according to the aspect of the invention, the total of the conveyance times by the robot can be set shorter than the total of the processing times (times for the holding and the release: material supply and removal times). Therefore, it is possible to convey a larger number of objects to the first test sections or the second test sections in a shorter time while reducing occurrence of, for example, holding mistakes of the objects. Consequently, it is possible to test a larger number of objects in a shorter time. Therefore, it is possible to further improve a throughput (the number of tests of objects that can be processed per a unit time) than in the past.

The conveyance time refers to an operation time from a state in which acceleration is started in one region (e.g., any one of the supply section, the test group sections, or the collecting section) to a state in which deceleration is ended in another region different from the one region. The processing time refers to an operation time from a state in which the robot starts operation for holding (or releasing) a first object in one region (e.g., the supply section, the test group section, or the collecting section) to a state in which the holding (or the release) of a last object by the robot is completed and the robot is about to start conveyance to another unit.

In the robot system according to the aspect of the invention, it is preferable that at least one of the holding and the release of the object by the robot is performed in each of the supply section, the first test section group, the second test section group, and the collecting section.

By increasing processing times in the sections, it is possible to appropriately hold and release the object while reducing, for example, likelihood of breakage of the object.

In the robot system according to the aspect of the invention, it is preferable that the conveyance of the object by the robot is performed in each of sections between the supply section and the first test section group, between the first test section group and the collecting section, between the supply section and the second test section group, and between the second test section group and the collecting section.

By reducing conveyance times in the sections, it is possible to further reduce the total of the conveyance times and further increase the throughput.

In the robot system according to the aspect of the invention, it is preferable that the work on the object by the robot includes a first stage including at least one of the holding and the release of the object in the supply section, the first test section group, and the collecting section and the conveyance of the object between the supply section and the first test section group and between the first test section group and the collecting section and a second stage including at least one of the holding and the release of the object in the supply section, the second test section group, and the collecting section and the conveyance of the object between the supply section and the second test section group and between the second test section group and the collecting section, in the first stage, a total of conveyance times of the object by the robot is shorter than a total of processing times of the object by the robot, and, in the second stage, a total of conveyance times of the object by the robot is shorter than a total of processing times of the object by the robot.

With this configuration, since the totals of the conveyance times are shorter than the totals of the processing times in both of the first stage and the second stage, it is possible to further increase the throughput.

The “stage” indicates a unit of the work of the robot.

In the robot system according to the aspect of the invention, it is preferable that the robot performs first work for holding the plurality of objects from the supply section with the robot arm, second work for conveying the plurality of objects from the supply section to the first test section group with the robot arm after the first work, third work for performing work for releasing the plurality of objects and work for holding the plurality of objects with the robot arm in the first test section group after the second work, fourth work for conveying the plurality of objects from the first test section group to the collecting section with the robot arm after the third work, fifth work for releasing the plurality of objects in the collecting section with the robot arm after the fourth work, sixth work for holding the plurality of objects from the supply section with the robot arm after the fifth work, seventh work for conveying the plurality of objects from the supply section to the second test section group with the robot arm after the sixth work, eighth work for performing work for releasing the plurality of objects and work for holding the plurality of objects with the robot arm in the second test section group after the seventh work, ninth work for conveying the plurality of objects from the second test section group to the collecting section with the robot arm after the eighth work, and tenth work for releasing the plurality of objects in the collecting section with the robot arm after the ninth work, a total of a second time serving as the conveyance time for the second work and a fourth time serving as the conveyance time for the fourth work is shorter than a total of a first time serving as the processing time for the first work, a third time serving as the processing time for the third work, and a fifth time serving as the processing time for the fifth work, and a total of a seventh time serving as the conveyance time for the seventh work and a ninth time serving as the conveyance time for the ninth work is shorter than a total of a sixth time serving as the processing time for the sixth work, an eighth time serving as the processing time for the eighth work, and a tenth time serving as the processing time for the tenth work.

With this configuration, it is possible to test a larger number of objects in a shorter time in the first test sections and the second test sections while reducing occurrence of, for example, holding mistakes of the objects. Therefore, it is possible to further increase the throughput.

In the robot system according to the aspect of the invention, it is preferable that the robot includes an end effector connected to the robot arm, and the end effector includes a turning member capable of turning around a turning axis and a plurality of holding sections provided in the turning member and configured to hold the object.

With this configuration, it is possible to realize the end effector that is small and can collectively convey the plurality of objects.

The “end effector connected to the robot arm” includes an end effector connected via any member (e.g., a force detecting section) provided in the robot arm.

In the robot system according to the aspect of the invention, it is preferable that the plurality of first test sections and the plurality of second test sections are respectively disposed on an arc centering on the robot when viewed from a gravity direction.

With this configuration, it is possible to efficiently set the plurality of first test sections and the plurality of second test sections in a movable range of a distal end portion of the robot arm.

In the robot system according to the aspect of the invention, it is preferable that the first test section and the second test section are disposed to overlap when viewed from a gravity direction.

With this configuration, it is possible to set a larger number of the first test sections and a larger number of the second test sections in a relatively small setting area. Therefore, it is possible to achieve space saving of a setting area of the robot system.

In the robot system according to the aspect of the invention, it is preferable that the robot and the supply section are located on an inner side of the first test section group and the second test section group when viewed from a gravity direction, and height of an upper part of the supply section is equal to or smaller than height of an upper part of the first test section and height of the upper part of the supply section is equal to or smaller than height of an upper part of the second test section.

With this configuration, when the holding, the conveyance, and the release of the object by the robot are performed, it is possible to reduce or prevent likelihood that the robot interferes with the supply section, the first test section, and the second test section.

In the robot system according to the aspect of the invention, it is preferable that a setting area is 256 m² or less.

In this way, the robot system can be set in a place having a relatively small setting area. Therefore, it is possible to sufficiently reduce the robot system in size.

In the robot system according to the aspect of the invention, it is preferable that the robot system further includes a housing configured to house the supply section, the first test section, the second test section, the collecting section, and the robot, and the first test section and the second test section respectively include test tables on which the object is placed and moving mechanisms capable of moving the test tables to an outside of the housing.

With this configuration, since the test tables can be moved to the outside of the housing (the outside of the robot system), an operator can easily perform, for example, maintenance of the test tables.

In the robot system according to the aspect of the invention, it is preferable that the first test section and the second test section respectively include first members connected to the test tables and provided in the housing in a state in which the test tables are located on an inside of the housing, second members located in upper parts of the test tables in the state in which the test tables are located on the inside of the housing, and coupling members configured to couple the first members and the second members, the test tables are located on the outside of the housing by drawing out the first members to an outer side of the housing, and the second members function as partitioning sections for partitioning the inside and the outside of the housing in a state in which the test tables are located on the outside of the housing.

With this configuration, when the test tables are located on the inside of the housing, the second members function as cover sections that cover upper parts of the test tables. When the test tables are located on the outside of the housing, the second members function as the partitioning sections. Therefore, it is possible to prevent the operator from inserting a hand into the housing by mistake when the operator performs maintenance of, for example, the test tables on the outside of the housing.

In the robot system according to the aspect of the invention, it is preferable that the robot performs the holding and the release of the object in the first test section selected out of the plurality of first test sections included in the first test section group and performs the holding and the release of the object in the second test section selected out of the plurality of second test sections included in the second test section group.

With this configuration, it is possible to, for example, skip the first test section or the second test section under maintenance and perform the holding or the release of the objects on the remaining first test sections or second test sections. Therefore, since it is unnecessary to stop, for example, all kinds of work (the holding, the conveyance, and the release) by the robot during the maintenance, it is possible to reduce a standby time of the robot. As a result, it is possible to reduce a decrease in the throughput.

In the robot system according to the aspect of the invention, it is preferable that the robot arm includes coupled at least two arms, and the robot performs the conveyance of the object in a state in which the at least two arms cross from the supply to the collection of the object.

With this configuration, since it is possible to reduce vibration of the robot arm at the time of the conveyance of the object, it is possible to further increase speed and acceleration of the robot when the object is moved. Therefore, it is possible to further increase the throughput. It is possible to more quickly start the holding and the release of the object after the conveyance.

In the robot system according to the aspect of the invention, it is preferable that the robot includes: a member connected to the robot arm and including a plurality of suction sections configured to hold the object with suction; a channel section connected to the suction section and including a channel in which gas flows; a detecting section configured to detect pressure or a flow rate per unit time of the gas in the channel section; and an imaging section having an imaging function, and the robot calculates, on the basis of a detection result from the imaging section and a detection result from the detecting section, teaching points in the holding and the release of the object by the robot.

With this configuration, it is possible to highly accurately calculate the teaching points. Since the robot performs the holding and the release of the object using the teaching points, it is possible to reduce or prevent, for example, holding mistakes of the objects. Therefore, it is possible to accurately perform the holding and the release of the objects by the robot.

### BRIEF DESCRIPTION OF THE DRAWINGS

The invention will be described with reference to the accompanying drawings, wherein like numbers reference like elements.

FIG. 1 is a perspective view of a robot system according to a first embodiment of the invention viewed from the front side.

FIG. 2 is a perspective view of the robot system shown in FIG. 1 viewed from the back side.

FIG. 3 is a left side view of the robot system shown in FIG. 1.

FIG. 4 is a perspective view showing the inside of the robot system shown in FIG. 1.

FIG. 5 is a plan view showing the inside of the robot system shown in FIG. 1.

FIG. 6 is a block diagram of the robot system shown in FIG. 1.

FIG. 7 is a plan view showing a placing member included in a supply section shown in FIG. 1.

FIG. 8 is a perspective view showing a test unit shown in FIG. 1.

FIG. 9 is a side view of a test section shown in FIG. 1.

FIG. 10 is a plan view of a test table shown in FIG. 8.

FIG. 11 is a diagram showing a state in which the test table shown in FIG. 8 is drawn out to the outside of a housing.

FIG. 12 is a front view of a robot shown in FIG. 1.

FIG. 13 is a diagram showing an end effector shown in FIG. 12.

FIG. 14 is a diagram showing the end effector shown in FIG. 12.

FIG. 15 is a diagram showing a turning member and a holding section shown in FIG. 13.

FIG. 16 is a schematic diagram showing a relation between the end effector shown in FIG. 13 and the test section shown in FIG. 8.

FIG. 17 is a schematic diagram showing a relation between the end effector shown in FIG. 13 and the test section shown in FIG. 8.

FIG. 18 is a diagram showing another form of the end effector included in the robot shown in FIG. 12.

FIG. 19 is a schematic diagram showing the turning member and the holding section shown in FIG. 15.

FIG. 20 is a schematic diagram showing a modification of the turning member and the holding section shown in FIG. 19.

FIG. 21 is a schematic diagram showing a modification of the turning member and the holding section shown in FIG. 19.

FIG. 22 is a schematic diagram showing a modification of the turning member and the holding section shown in FIG. 19.

FIG. 23 is a diagram showing a part of the robot shown in FIG. 12.

FIG. 24 is a side view showing a state in which a first arm, a second arm, and a third arm of the robot shown in FIG. 12 do not overlap.

FIG. 25 is a side view showing a state in which the first arm, the second arm, and the third arm of the robot shown in FIG. 12 overlap.

FIG. 26 is a diagram showing a moving route of the distal end of a robot arm in the operation of the robot shown in FIG. 12.

FIG. 27 is a schematic side view of a state in which the first arm and the third arm of the robot shown in FIG. 12 cross.

FIG. 28 is a schematic side view of a state in which the first arm and a fourth arm of the robot shown in FIG. 12 overlap.

FIG. 29 is a diagram for explaining a movable range of the distal end portion of the robot arm included in the robot shown in FIG. 12.

FIG. 30 is a diagram for explaining the movable range of the distal end portion of the robot arm included in the robot shown in FIG. 12.

FIG. 31 is a diagram showing a movable range of the distal end of the end effector included in the robot shown in FIG. 12.

FIG. 32 is a diagram showing the movable range of the distal end of the end effector included in the robot shown in FIG. 12.

FIG. 33 is a flowchart for explaining an example of work of the robot shown in FIG. 12.

FIG. 34 is a diagram for explaining an example of the work of the robot shown in FIG. 12.

FIG. 35 is a diagram for explaining holding and release of an object by the end effector included in the robot shown in FIG. 12.

FIG. 36 is a diagram for explaining the holding and the release of the object by the end effector included in the robot shown in FIG. 12.

FIG. 37 is a diagram for explaining the holding and the release of the object by the end effector included in the robot shown in FIG. 12.

FIG. 38 is a diagram for explaining the holding and the release of the object by the end effector included in the robot shown in FIG. 12.

FIG. 39 is a graph showing a relation between the number of objects conveyed by the robot shown in FIG. 12 and a tact time.

FIG. 40 is a flowchart for explaining an example of auto-teaching of a socket to the robot shown in FIG. 12.

FIG. 41 is a diagram showing the distal end portion of the robot for explaining the auto-teaching of the socket to the robot shown in FIG. 12.

FIG. 42 is a diagram showing a test table for explaining the auto-teaching of the socket to the robot shown in FIG. 12.

FIG. 43 is a diagram showing a reference mark provided in the socket shown in FIG. 42.

FIG. 44 is a diagram showing the distal end portion of the robot for explaining the auto-teaching of the socket to the robot shown in FIG. 12.

FIG. 45 is a diagram showing the distance between a holding section of the end effector and the object on the test table for explaining the auto-teaching of the socket to the robot shown in FIG. 12.

FIG. 46 is a side view showing a test section included in a robot system according to a second embodiment of the invention.

FIG. 47 is a diagram showing an example of an object tested in the test section shown in FIG. 46.

FIG. 48 is a schematic diagram of the inside of a robot system according to a third embodiment of the invention viewed from the upper side.

FIG. 49 is a schematic diagram of the inside of a robot system according to a fourth embodiment of the invention viewed from the upper side.

FIG. 50 is a diagram showing a robot system unit including a plurality of the robot systems shown in FIG. 49.

FIG. 51 is a schematic diagram showing a modification of a supply and collection unit shown in FIG. 49.

FIG. 52 is a schematic diagram showing a modification of the supply and collection unit shown in FIG. 49.

FIG. 53 is a left side view of a robot system according to a fifth embodiment of the invention.

FIG. 54 is a front view of a robot system according to a sixth embodiment of the invention.

FIG. 55 is a schematic diagram of a robot system according to a seventh embodiment of the invention viewed from an upper side.

FIG. 56 is a diagram showing an example of a placing member provided on a placing table included in the robot system shown in FIG. 55.

FIG. 57 is a schematic diagram of a robot system according to an eighth embodiment of the invention viewed from the upper side.

FIG. 58 is a schematic diagram of a robot system according to a ninth embodiment of the invention viewed from the upper side.

FIG. 59 is a schematic diagram of a robot system according to a tenth embodiment of the invention viewed from the upper side.

### DESCRIPTION OF EXEMPLARY EMBODIMENTS

Preferred embodiments of the invention are explained in detail below with reference to the accompanying drawings.

### First Embodiment

### 1. Configuration of a Robot System

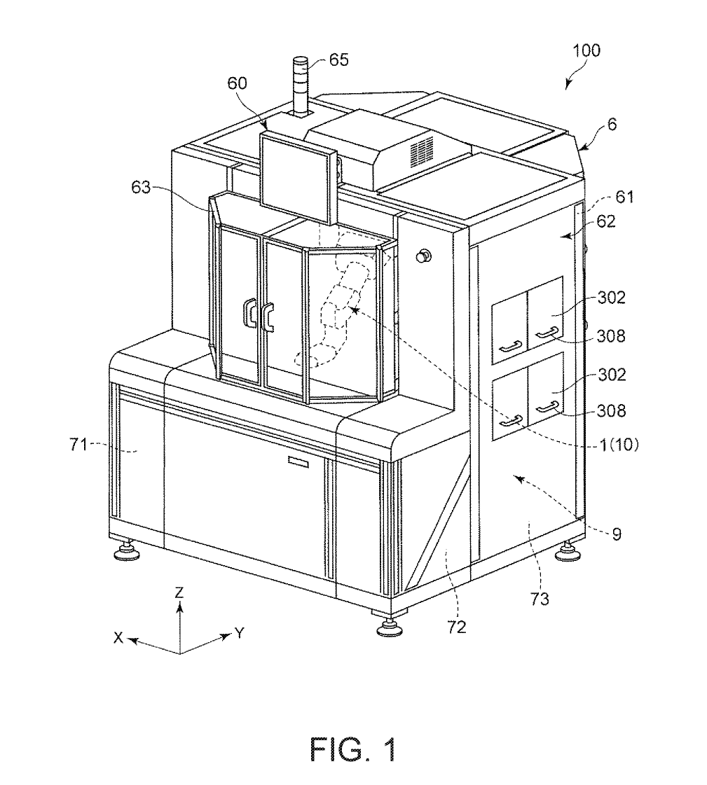

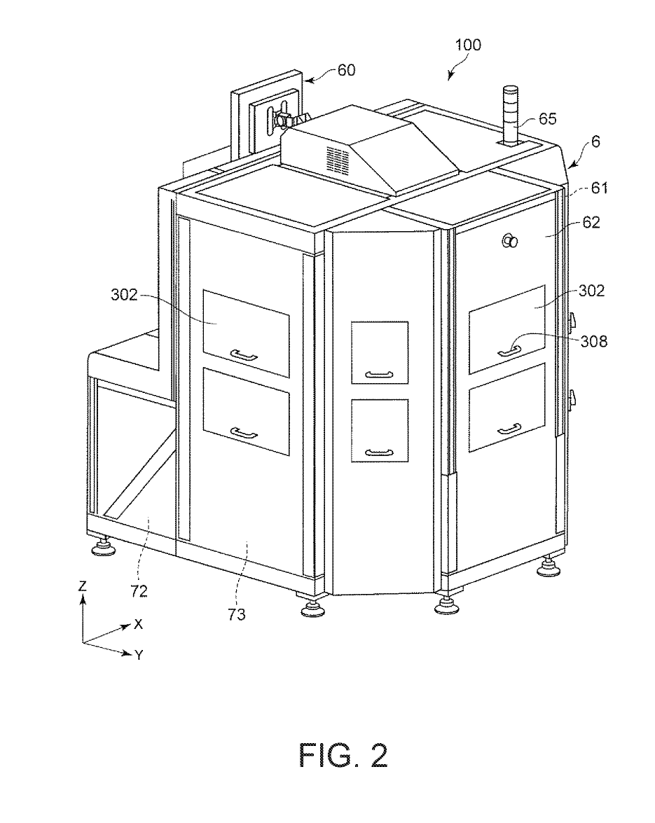

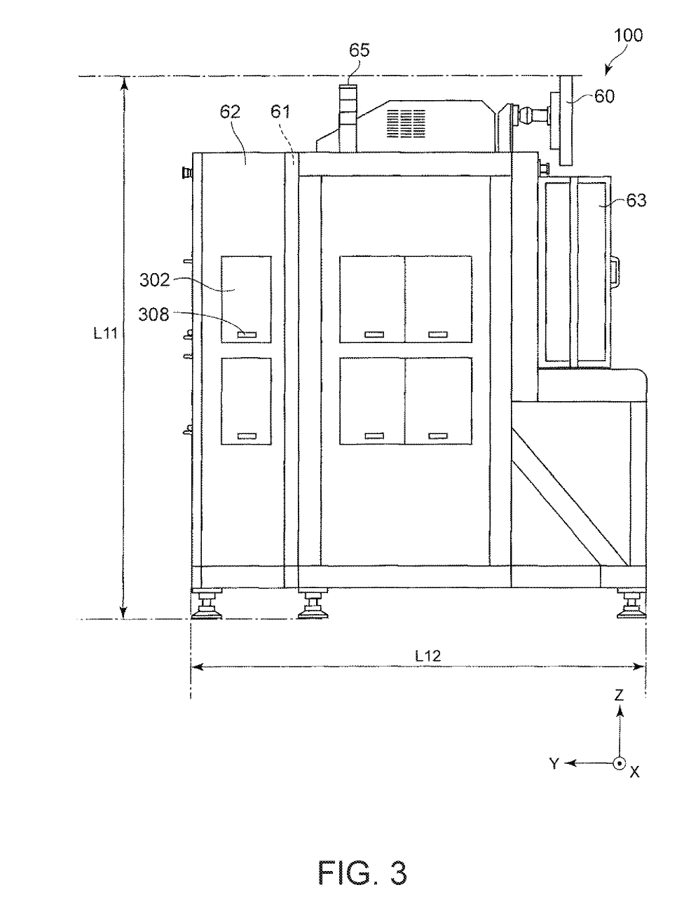

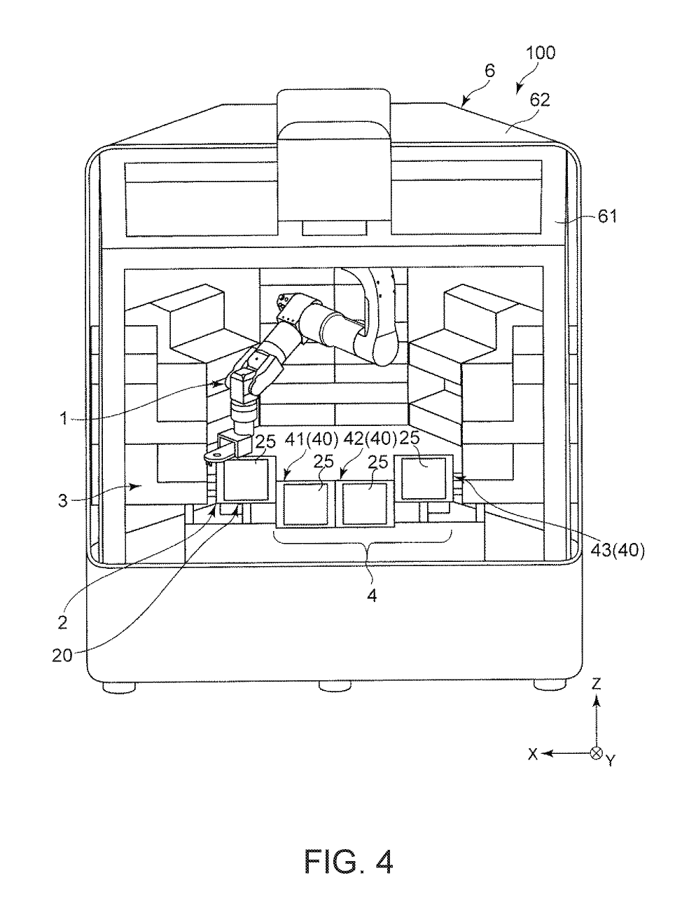

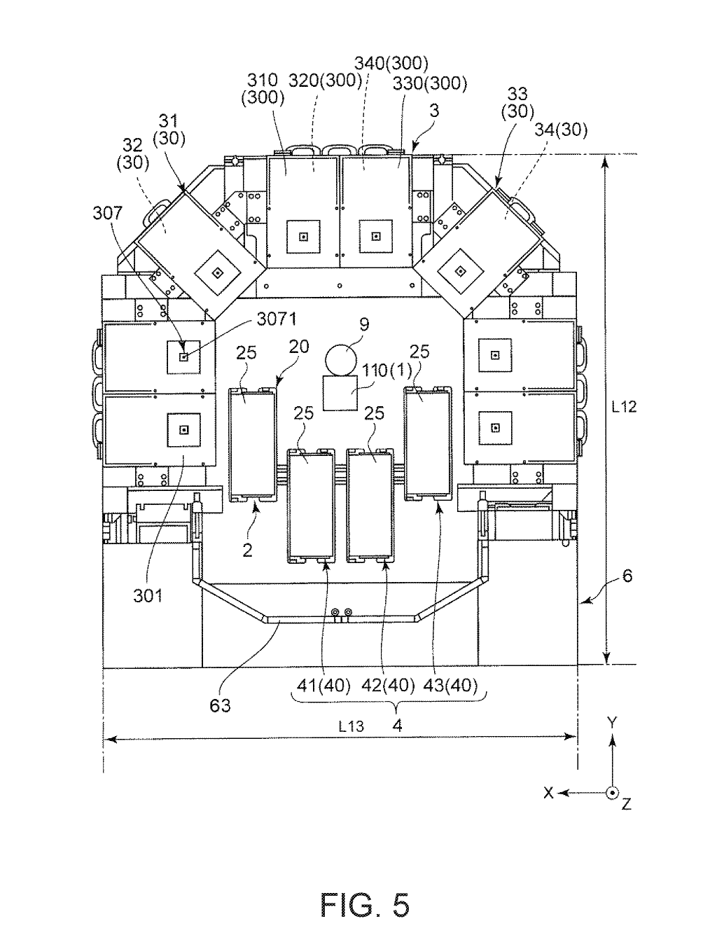

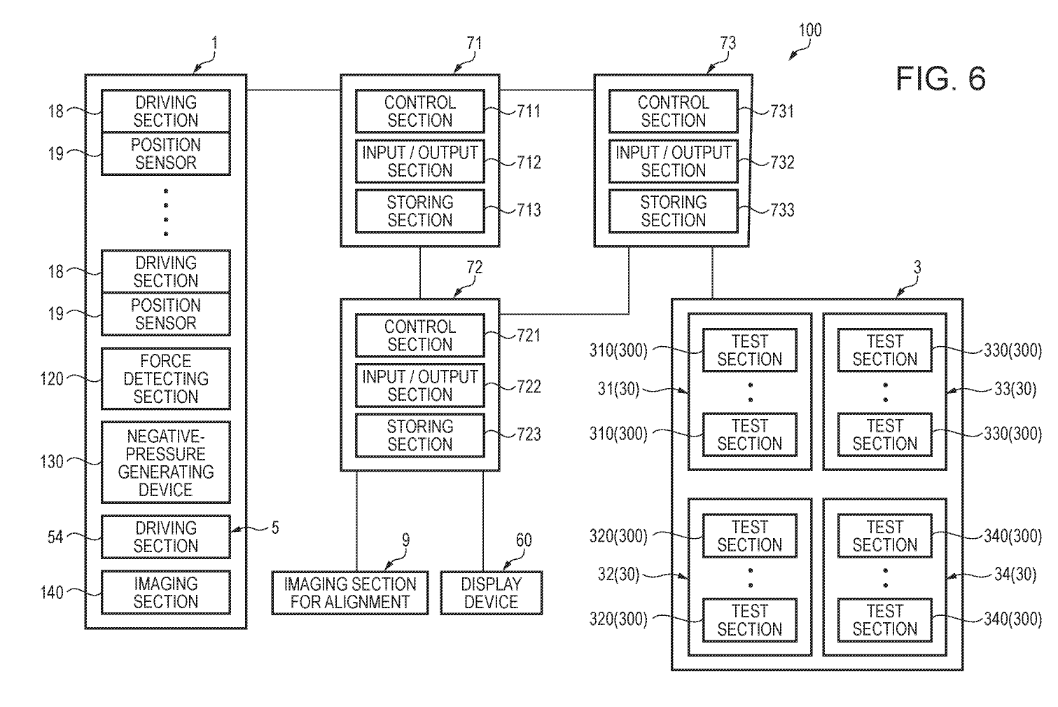

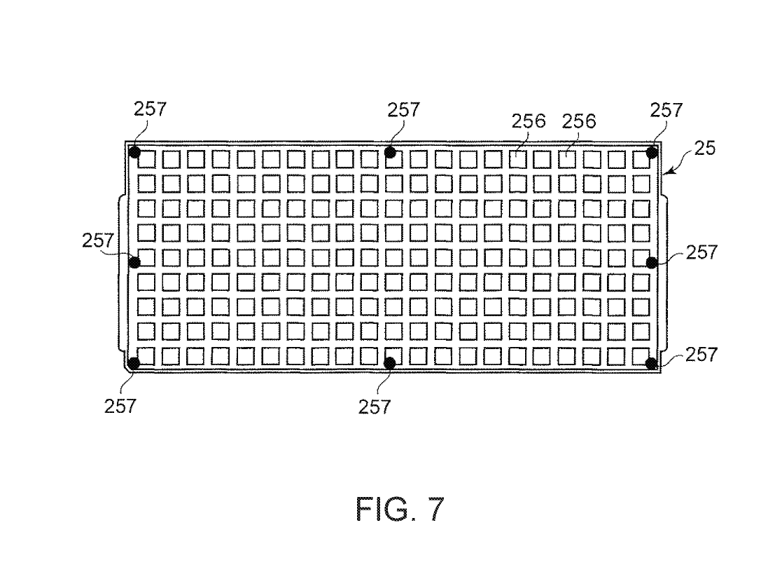

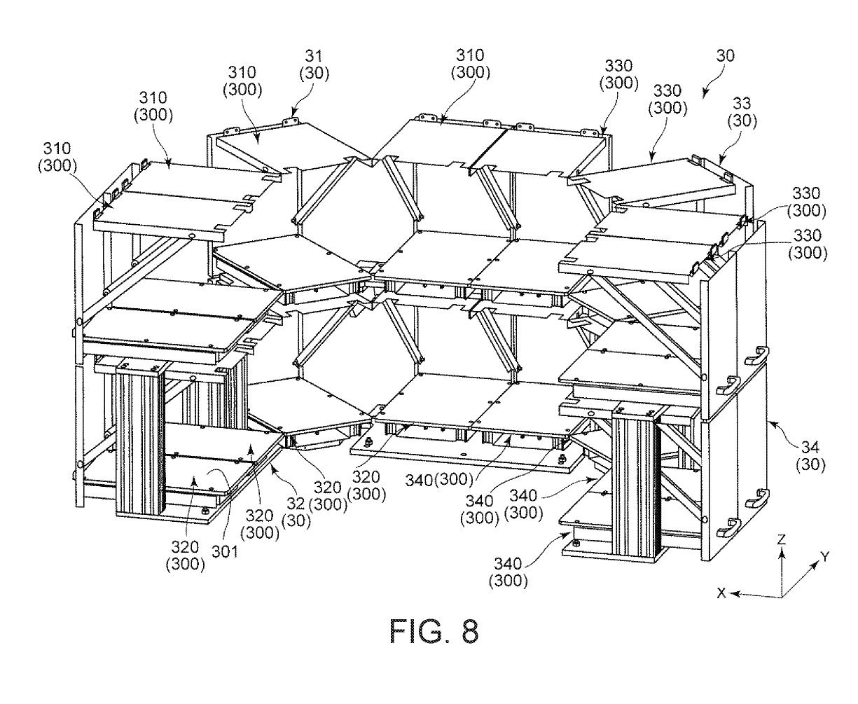

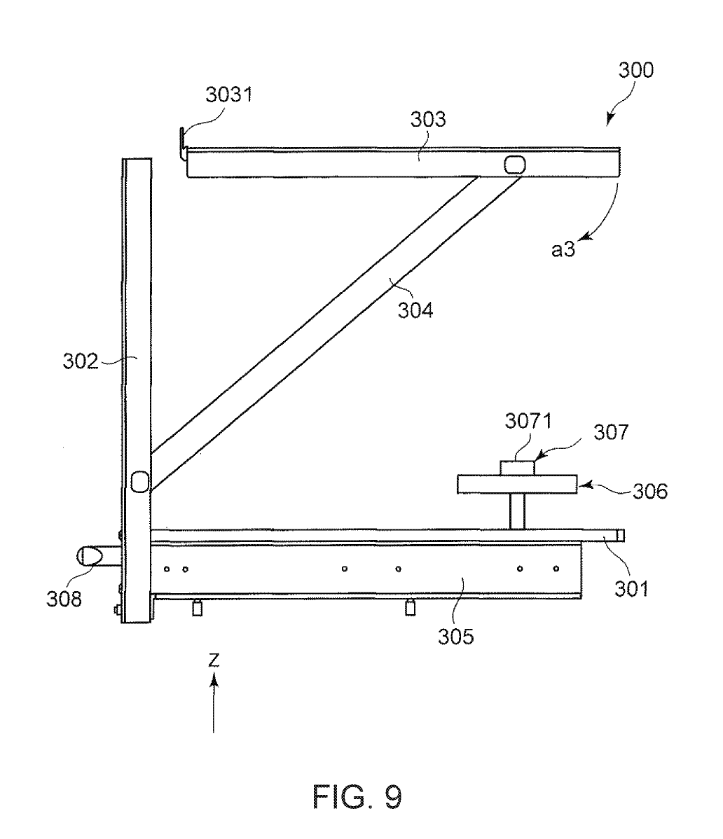

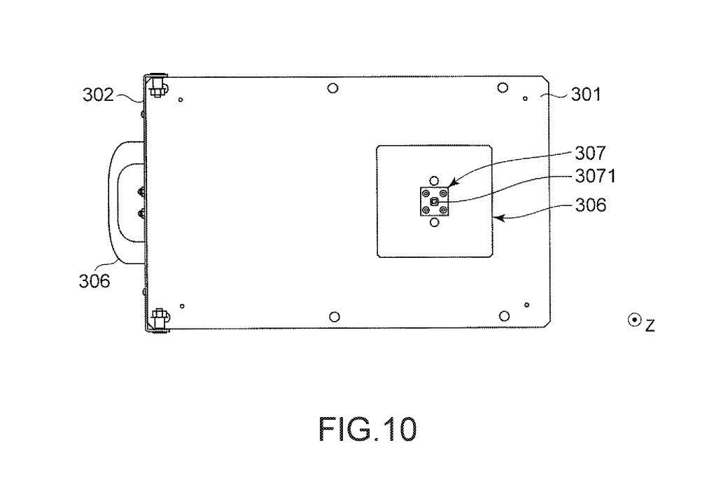

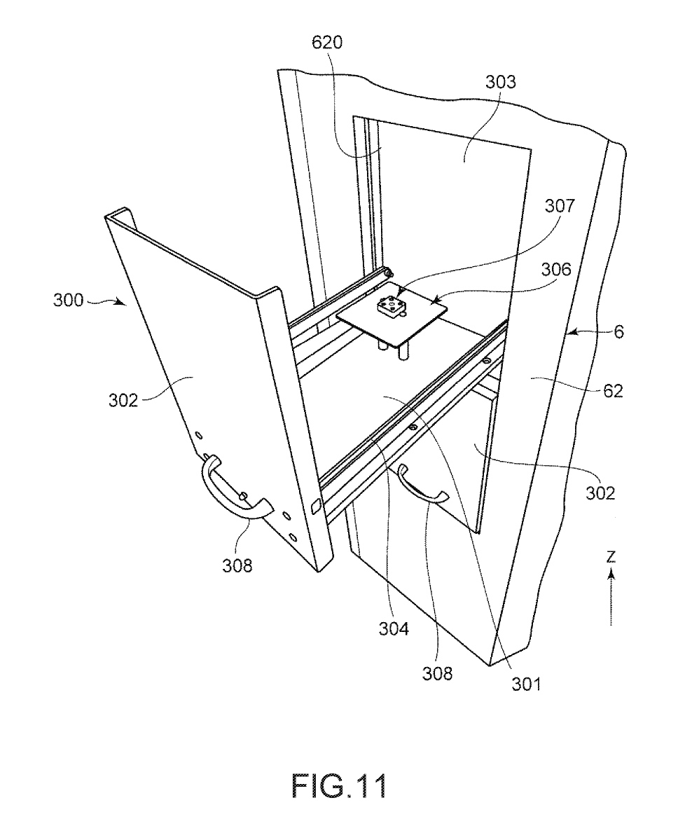

FIG. 1 is a perspective view of a robot system according to a first embodiment of the invention viewed from the front side. FIG. 2 is a perspective view of the robot system shown in FIG. 1 viewed from the back side. FIG. 3 is a left side view of the robot system shown in FIG. 1. FIG. 4 is a perspective view showing the inside of the robot system shown in FIG. 1. FIG. 5 is a plan view showing the inside of the robot system shown in FIG. 1. FIG. 6 is a block diagram of the robot system shown in FIG. 1. FIG. 7 is a plan view showing a placing member included in a supply section shown in FIG. 1. FIG. 8 is a perspective view showing a test unit shown in FIG. 1. FIG. 9 is a side view of a test section shown in FIG. 1. FIG. 10 is a plan view of a test table shown in FIG. 8. FIG. 11 is a diagram showing a state in which the test table shown in FIG. 8 is drawn out to the outside of a housing. Note that, in FIG. 7, illustration of a socket 307 included in the test section is omitted.

Note that, in the following explanation, for convenience of explanation, an X axis, a Y axis, and a Z axis, which are three axes orthogonal to one another, are indicated by arrows. The distal end side of the arrows is represented as “+(plus)” and the proximal end side of the arrows is represented as “−(minus)”. In the following explanation, a direction parallel to the X axis is referred to as “X-axis direction”, a direction parallel to the Y axis is referred to as “Y-axis direction”, and a direction parallel to the Z axis is referred to as “Z-axis direction”. A +Z-axis side is referred to as “upper side”, a −Z-axis side is referred to as “lower side”, a +Y-axis side is referred to as “back side”, a −Y-axis side is referred to as “front side”, a +X-axis side is referred to as “left side”, and a −X-axis side is referred to as “right side”. An XY plane including the X axis and the Y axis is horizontal. The Z axis is vertical. The “horizontal” in this specification is not limited to complete horizontal and includes inclination in a range of ±5° with respect to the horizontal. The “vertical” in this specification is not limited to complete vertical and includes inclination in a range of ±5° with respect to the vertical. The vertical direction and the gravity direction coincide with each other.

A robot system 100 shown in FIGS. 1 to 6 is an apparatus that performs tests of objects (test objects) such as various electronic devices and electronic components used in the electronic devices.

Examples of the electronic components include active components such as a diode and a transistor, passive components such as a capacitor, functional components such as a package and a substrate, and components obtained by combining these components (e.g., a GPS (Global Positioning System) module substrate and an SiP (System in Package). Examples of the electronic devices include a personal computer, a cellular phone (including a multifunction type cellular phone (a smartphone)), a watch (e.g., a watch with GPS function), a camera, and a game machine.

Examples of the test of the objects include a conduction test (an electric test), a sound test, an image test, a communication test, an exterior test, and a function test for confirming driving states of sections such as a vibrator and a sensor.

The robot system 100 includes a housing 6, a supply unit 2, a test unit 3, a collection unit 4, a robot 1 including a robot arm 10, an imaging section for alignment 9, a robot control device 71, a peripheral-apparatus control device 72, and a test control device 73 (see FIGS. 1 to 5).

In the robot system 100, the supply unit 2, the test unit 3, and the collection unit 4 are respectively disposed such that the distal end of the robot arm 10 of the robot 1 is accessible to the supply unit 2, the test unit 3, and the collection unit 4.

The sections of the robot system 100 are explained below in order.

### Housing

As shown in FIGS. 1 to 4, the housing 6 includes a frame 61 and a cover member 62 provided in the frame 61. The housing 6 is a box that houses the supply unit 2, the test unit 3, the collection unit 4, the robot 1, the imaging section for alignment 9, the robot control device 71, the peripheral-apparatus control device 72, and the test control device 73. The housing 6 protects these components from the outside.

An open-closable door 63 is provided on the front side of the housing 6. An operator can access the inside of the housing 6 by opening the door 63. The door 63 includes a member formed of, for example, glass or resin. Therefore, the door 63 also functions as a window member through which the inside of the housing 6 can be visually recognized. Consequently, the operator can visually recognize the inside of the housing 6 without opening and closing the door 63.

An informing section 65 (a signal lamp) that informs, for example, a state of the inside of the robot system 100 according to a combination of colors to be developed is provided in an upper part of the housing 6. Consequently, the operator can grasp whether abnormality or the like occurs on the inside of the robot system 100.

A display device 60 configured by a liquid crystal panel or the like caused to display various screens such as a window is attached to a front side upper part of the housing 6. The operator can grasp, for example, a test result of an object via the display device 60. Note that, although not shown in the figures, an input device configured by, for example, a mouse and a keyboard can be provided in the housing 6. Consequently, the operator can operate the input device and give instructions of various kinds of processing and the like to the robot control device 71, the peripheral-apparatus control device 72, and the test control device 73. The display device 60 may also include a function of the input device. In that case, the display device 60 can be configured by, for example, a touch panel (a display input device).

### Supply Unit

As shown in FIGS. 4 and 5, the supply unit 2 is provided on the −Y-axis side (the front side) of the inside of the housing 6.

The supply unit 2 includes a supply section 20 to which an object is supplied. Note that, in this embodiment, the number of supply sections 20 is one. However, the number of supply sections 20 may be two or more.

The supply section 20 is configured such that a placing member 25 on which an object can be placed as shown in FIG. 7 can be arranged. As shown in FIG. 7, the placing member 25 is configured by a tray conforming to the JEDEC standard. The plan view shape of the placing member 25 is formed in a square plate shape. The placing member 25 includes concave sections 256 on which objects are placed. In the placing member 25, one object can be placed on one concave section 256. A plate surface of the placing member 25 is substantially parallel to the XY plane in a state in which the placing member 25 is placed on the supply section 20. Note that, as the “placing member”, a member other than the tray conforming to the JEDEC standard may be used.

The placing member 25 can be taken out from the supply section 20. For example, the operator can open the door 63 and take out the placing member 25 from the supply section 20 or set the placing member 25 on the supply section 20.

### Test Unit

As shown in FIGS. 4 and 5, the test unit 3 is provided on the +Y-axis side (the back side) on the inside of the housing 6.

As shown in FIG. 8, the test unit 3 includes a plurality of test sections 300 on which objects can be placed and that tests the placed objects. The test sections 300 performs the tests of the contents explained above (e.g., the conduction test) under control by the test control device 73 explained below.

In this embodiment, a plurality of test sections 300 are divided into four groups according to kinds of work of the robot 1 explained below. Specifically, the test unit 3 includes a first test section group 31 including four first test sections 310 (the test sections 300), a second test section group 32 including four second test sections 320 (the test sections 300), a third test section group 33 including four third test sections 330 (the test sections 300), and a fourth test section group 34 including four fourth test sections 340 (the test sections 300). Note that, in this embodiment, contents of tests performed by the test sections 300 are the same. However, the test contents may be different.

The first test section 310, the second test section 320, the third test section 330, and the fourth test section 340 respectively have the same configuration. In the following explanation, the first test section 310, the second test section 320, the third test section 330, and the fourth test section 340 are referred to as “test sections 300” as well. The first test section group 31, the second test section group 32, the third test section group 33, and the fourth test section group 34 are respectively hereinafter referred to as “test section groups 30” as well.

As shown in FIGS. 5 and 7, the plurality of test sections 300 are disposed in an arcuate shape when viewed from the Z-axis direction (the gravity direction). The four first test sections 310 and the four third test sections 330 are located on the same plane. Similarly, the four second test sections 320 and the four fourth test sections 340 are located on the same plane. The four first test sections 310 are located above the four second test sections 320. Similarly, the four third test sections 330 are located above the four fourth test sections 340.

As shown in FIG. 9, the test section 300 includes a test table 301, a first member 302 connected to the test table 301, a second member 303 located above the test table 301, a coupling member 304 that couples the first member 302 and the second member 303, and a moving mechanism 305 that moves the test table 301.

As shown in FIGS. 9 and 10, the test table 301 is a flat member, the plan view shape of which is formed in a square shape. A socket 307 including a concave section 3071 on which an object is placed and a supporting member 306 that supports the socket 307 are provided above the test table 301. Note that the supporting member 306 may be omitted. In that case, for example, the socket 307 may be fixed to the test table 301. The socket 307 may be fixed to the test table 301 via a substrate (not shown in the figures). The test sections 300 include circuits for test (not shown in the figures) electrically connected to the test control device 73 explained below. The socket 307 is electrically connected to the circuit for test. A detection result concerning the object placed on the concave section 3071 is output to the test control device 73 by the circuit for test.

The first member 302 is a flat member, the plan view shape of which is formed in a square shape. The first member 302 is fixed to the end portion of the test table 301 on the opposite side of the supporting member 306. As shown in FIG. 1, the first member 302 is provided in the cover member 62 of the housing 6. A handle 308 is provided in the first member 302. The operator can draw out the test table 301 to the outside of the housing 6 as shown in FIG. 11 by gripping the handle 308 and pulling the handle 308 to the outside of the housing 6. Consequently, the operator can perform, on the outside of the housing 6, maintenance of the socket 307 and the like provided in the test table 301. In this way, the first member 302 has a function of a door member for drawing out the test table 301.

The second member 303 shown in FIG. 9 is a flat member. The plan view shape of the second member 303 is substantially the same as or larger than the plan view shape of the first member 302. A hinge 3031 is attached to the end portion of the second member 303 on the first member 302 side. The second member 303 is connected to the housing 6 by the hinge 3031. One end portion of the coupling member 304 (a link) is connected to a side of the second member 303 opposite to the first member 302. The other end portion of the coupling member 304 is connected to the test table 301 side of the first member 302.

In a state in which the test table 301 is located on the inside of the housing 6, as shown in FIG. 9, the second member 303 is located above the test table 301 and is substantially parallel to the upper surface of the test table 301. When the operator operates the handle 308 to move the test table 301 to the outside of the housing 6 from this state, the second member 303 turns in an arrow a3 direction around the hinge 3031 serving as a turning center section. Consequently, as shown in FIG. 11, the second member 303 is provided to close an opening 620 formed in the cover member 62 by the opening of the first member 302. In this way, when the test table 301 is located on the inside of the housing 6, the second member 303 functions as a cover section that covers the test table 301. When the test table 301 is located on the outside of the housing 6, the second member 303 functions as a partitioning section that closes the opening 620 and partitions the inside and the outside of the housing 6. Consequently, the operator can prevent the operator from inserting a hand into the housing 6 by mistake when the operator performs maintenance on the outside of the housing 6.

When the test table 301 is located on the inside of the housing 6, as shown in FIG. 9, the coupling member 304 is located obliquely above the supporting member 306 (on the side of the first member 302 and the second member 303 of the test section 300). On the other hand, when the test table 301 is located on the outside of the housing 6, as shown in FIG. 11, the coupling member 304 is located below the supporting member 306 (on the test table 301 side of the test section 300) and is substantially parallel to the upper surface of the test table 301. In this way, when the test table 301 is located on the inside of the housing 6, the coupling member 304 realizes disposition for not hindering the operation of the robot 1 that accesses the test table 301. On the other hand, when the test table 301 is located on the outside of the housing 6, the coupling member 304 realizes disposition for not hindering maintenance of the socket 307 and the like by the operator.

As shown in FIG. 9, the moving mechanism 305 for causing the test table 301 to reciprocate is provided below the test table 301. Consequently, as explained above, the operator can move the test table 301 between the inside and the outside of the housing 6 by operating the handle 308.

Although not shown in the figure, the moving mechanism 305 includes, for example, a rail and a slider slidably provided in the rail. Note that the moving mechanism 305 may include a motor. Consequently, even if the operator does not operate the handle 308, the test table 301 can be automatically moved between the inside and the outside of the housing 6.

The test unit 3 is explained above.

As explained above, the robot system 100 includes the housing 6 that houses the supply section 20, the first test section 310, the second test section 320, the third test section 330, the fourth test section 340, a collecting section 40, and the robot 1. The first test section group 31, the second test section group 32, the third test section group 33, and the fourth test section group 34 respectively include the test tables 301 on which objects are placed and the moving mechanisms 305 capable of moving the test table 301 to the outside of the housing 6. Consequently, it is possible to move the test tables 301 to the outside of the housing 6 (the outside of the robot system 100). Therefore, the operator can easily perform, for example, maintenance of the test tables 301.

As explained above, the first test section group 31, the second test section group 32, the third test section group 33, and the fourth test section group 34 respectively include the first members 302 connected to the test tables 301 and provided in the housing 6 in the state in which the test tables 301 are located on the inside of the housing 6, the second members 303 located above the test tables 301 in the state in which the test tables 301 are located on the inside of the housing 6, and the coupling members 304 that couple the first members 302 and the second members 303. The test tables 301 are located on the outside of the housing 6 by drawing out the first members 302 to the outer side of the housing 6. The second members 303 function as the partitioning sections that partition the inside and the outside of the housing 6 in the state in which the test tables 301 are located on the outside of the housing 6. Consequently, when the test tables 301 are located on the inside of the housing 6, the second members 303 function as the cover sections that cover upper parts of the test tables 301. When the test tables 301 are located on the outside of the housing 6, the second members 303 function as the partitioning sections. Therefore, it is possible to prevent the operator from inserting a hand into the housing 6 by mistake when the operator performs maintenance of, for example, the test tables 301 on the outside of the housing 6.

In the above explanation, in the test unit 3, the plurality of test sections 300 are divided into four. However, the number of divisions and places for dividing the test sections 300 are not particularly limited. Therefore, although the test unit 3 includes the first test section group 31, the second test section group 32, and the third test section group 33, and the fourth test section group 34 in the above explanation, the test unit 3 only has to include at least two test section groups 30. The test unit 3 may include five or more test section groups 30. The first test section group 31 and the third test section group 33 maybe collectively grasped as “first test section group”. Although the “first test section group 31” is grasped as the “first test section group” described in the appended claims and the “second test section group 32” is grasped as the “second test section group” described in the appended claims in the above explanation, any one test section group 30 among the first test section group 31, the second test section group 32, the third test section group 33, and the fourth test section group 34 may be grasped as the “first test section group” or the “second test section group” described in the appended claims. For example, the “third test section group 33” maybe grasped as the “first test section group” and the “fourth test section group 34” may be grasped as the “second test section group”. Similarly, although the “first test section 310” is grasped as the “first test section” described in the appended claims and the “second test section 320” is grasped as the “second test section” described in the appended claims in the above explanation, any one test section 300 among the first test section 310, the second test section 320, the third test section 330, and the fourth test section 340 may be grasped as the “first test section” and the “second test section” described in the appended claims.

The number of the test sections 300 maybe any number and is not limited to the number shown in the figures. In this embodiment, the test sections 300 are not provided on the front side of the robot system 100. However, the test sections 300 may be provided on the front side of the robot system 100 as well. That is, the test sections 300 may be provided over the entire circumference of the robot 1 when viewed from the Z-axis direction.

The configuration of the test section 300 is not limited to the configuration explained above and can be set as appropriate according to test content and the like. For example, when a depression resistance test is performed, a cylinder (not shown in the figures) for pressing an object placed on the socket 307 may be provided in the second member 303.

### Collection Unit

As shown in FIGS. 4 and 5, the collection unit 4 is provided on the −Y-axis side (the front side) on the inside of the housing 6. The collection unit 4 is provided on the −X-axis side of the supply unit 2. Note that a relation of disposition between the collection unit 4 and the supply unit 2 is not limited to a relation shown in the figures. For example, the collection unit 4 may be provided on the +X-axis side of the supply unit 2. The collection unit 4 and the supply unit 2 are disposed further on the center side of the robot system 100 than the test unit 3 when viewed from the Z-axis direction.

The collection unit 4 includes a plurality of collecting sections 40 in which objects for which tests in the test sections 300 are finished are collected. In this embodiment, the collection unit 4 includes three collecting sections 40. Objects classified on the basis of a test result in the test sections 300 are divided and collected in the collecting sections 40 for each of the classifications. In this embodiment, the objects are classified into “non-defective product”, “defective product”, and “retest”. For example, the “non-defective product” indicates that a functional defect or the like of the object is absent. The “defective product” indicates that a functional defect or the like is present. The “retest” indicates that a test is performed again, for example, when a test result is an error.

In this embodiment, the collection unit 4 includes a collecting section for non-defective products 41 (the collecting section 40), a collecting section for defective products 42 (the collecting section 40), and a collecting section for retests 43 (the collecting section 40). An object determined as being a non-defective product in the test section 300 is placed on the collecting section for non-defective products 41. An object determined as being a defective product in the test section 300 is placed on the collecting section for defective products 42. An object determined to be retested in the test section 300 is placed on the collecting section for retests 43.

The collecting section for non-defective products 41, the collecting section for defective produce 42, and the collecting section for retests 43 have the same configuration except that types of the objects to be collected (specifically, the non-defective product, the defective product, and the retest) are different. Therefore, in the following explanation, the collecting section for non-defective products 41, the collecting section for defective products 42, and the collecting section for retests 43 are respectively referred to as “collecting sections 40” as well.

Like the supply section 20, the collecting section 40 is configured such that the placing member 25 on which an object can be placed shown in FIG. 7 can be disposed. In the collecting section 40, as in the supply section 20, the plate surface of the placing member 25 is substantially parallel to the XY plane in a state in which the placing member 25 is placed on the collecting section 40. The placing member 25 can be taken out from the collecting section 40.

The collection unit 4 is explained above. Note that, in this embodiment, the number of collecting sections 40 is three. However, the number of collecting sections 40 may be one, two, or four or more. The collection unit 4 classifies objects into the non-defective product, the defective product, and the retest and collects the objects. However, the collection unit 4 may collect the objects without classifying the objects. In that case, all objects to be collected are placed on one placing member 25. The robot control device 71 or the peripheral-apparatus control device 72 stores which of the non-defective product, the defective product, and the retest the objects placed on the placing member 25 are. Consequently, after the objects are collected from the robot system 100, it is also possible to classify the objects into the non-defective product, the defective product, and the retest on the basis of the stored data.

In this embodiment, one set of the collecting sections 40 (the collecting section for non-defective products 41, the collecting section for defective products 42, and the collecting section for retests 43) common to all the test section groups 30 (the first test section group 31 to the fourth test section group 34) are provided. However, not only this, but, for example, separate collecting sections 40 (the the collecting section for non-defective products 41, the collecting section for defective products 42, and the collecting section for retests 43) may be provided for each of the test section groups 30 (the first test section group 31 to the fourth test section group 34). The same applies to the supply section 20.

### Robot

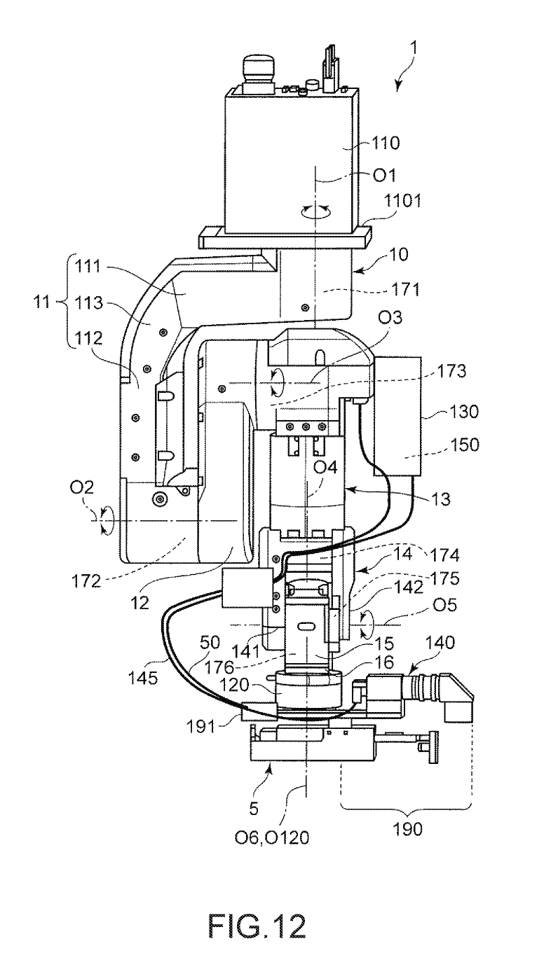

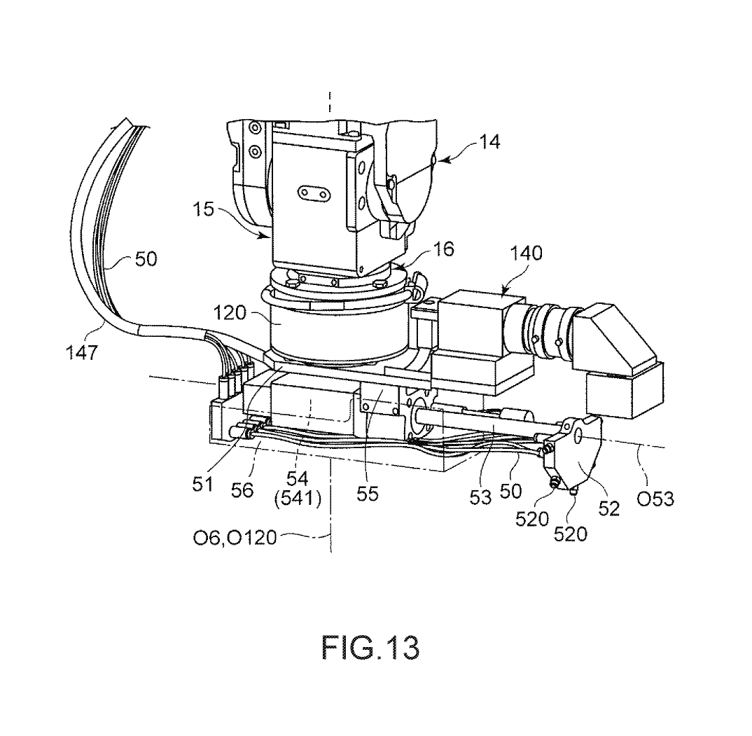

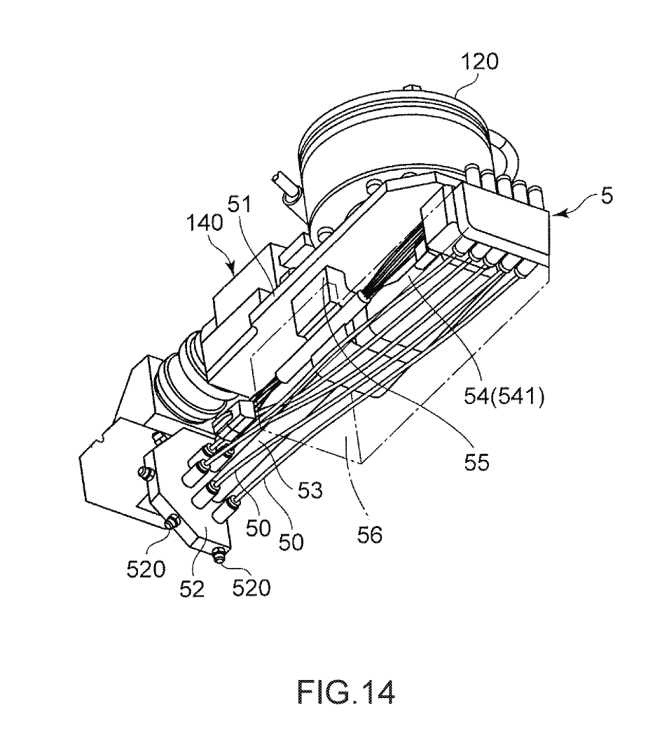

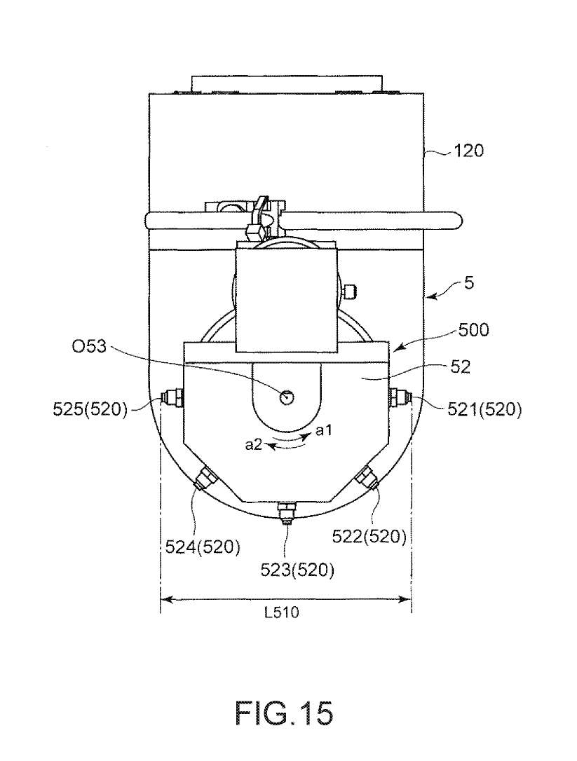

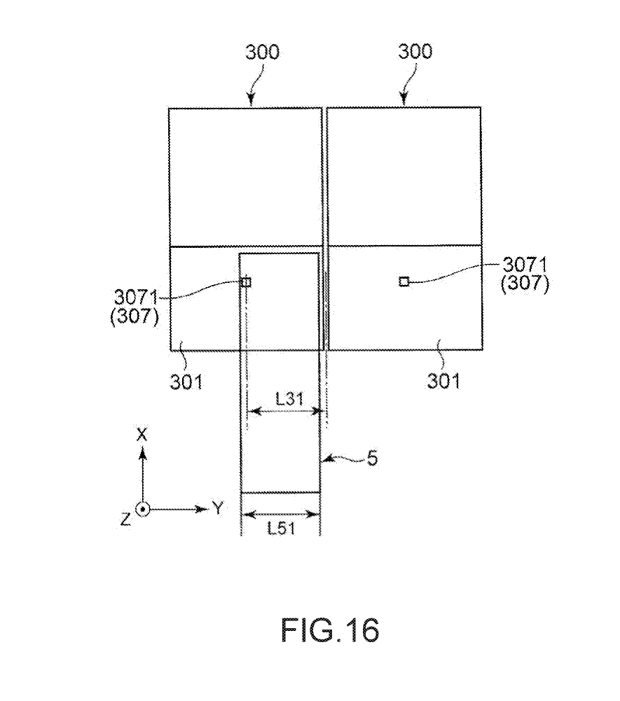

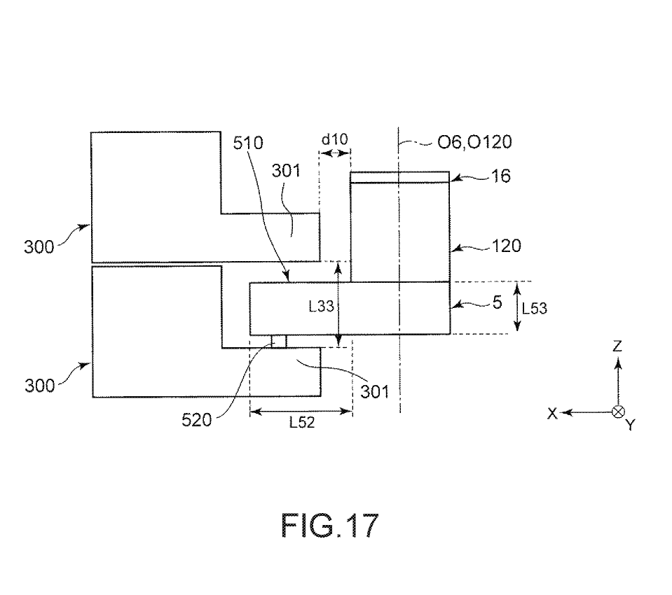

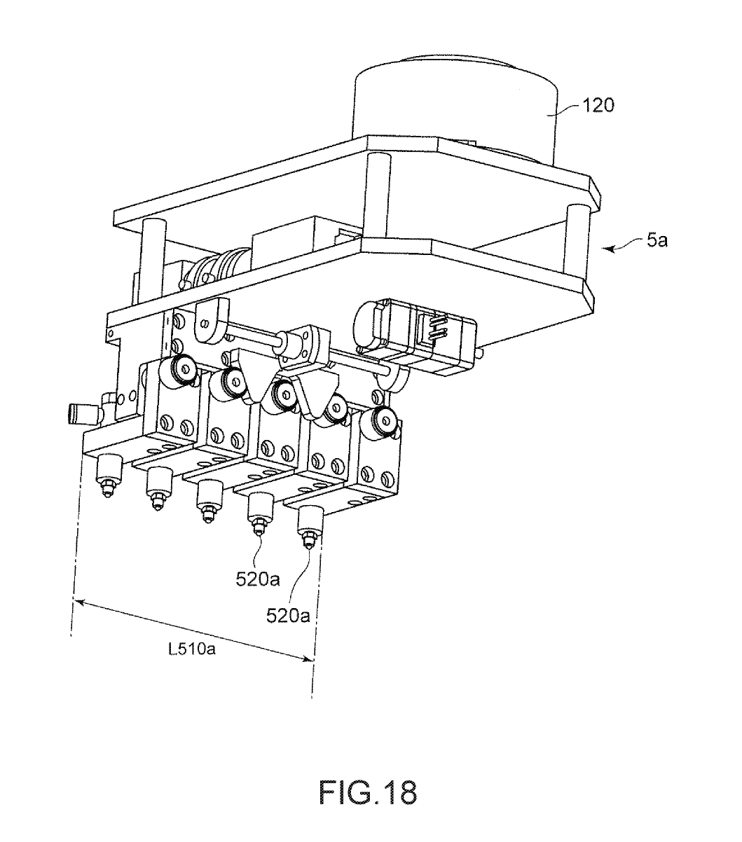

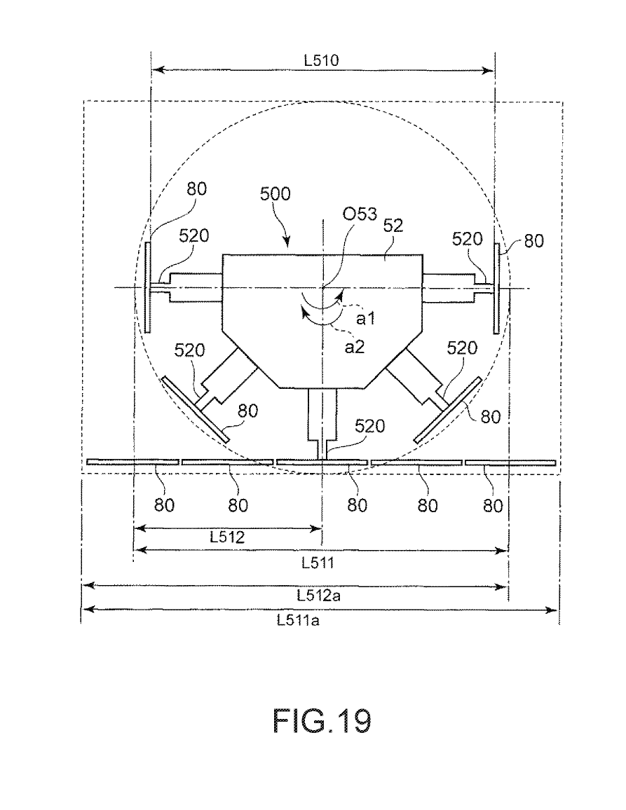

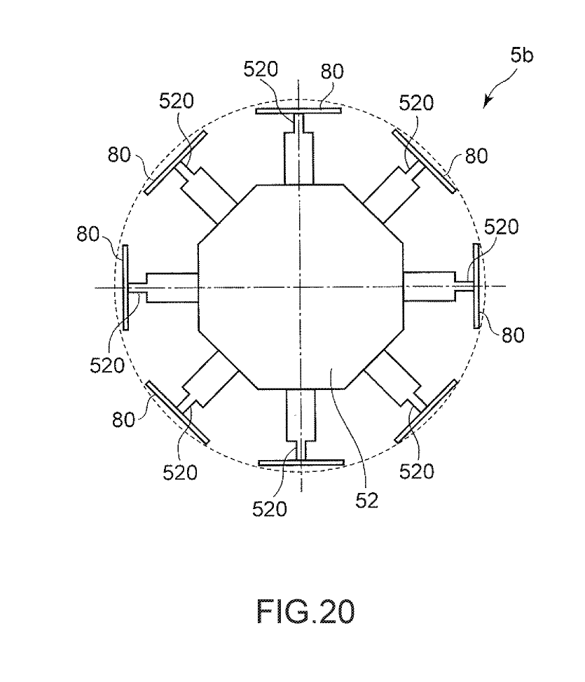

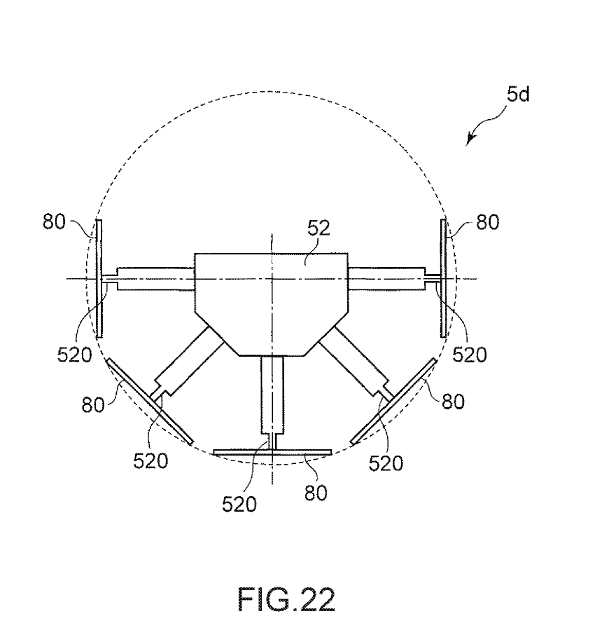

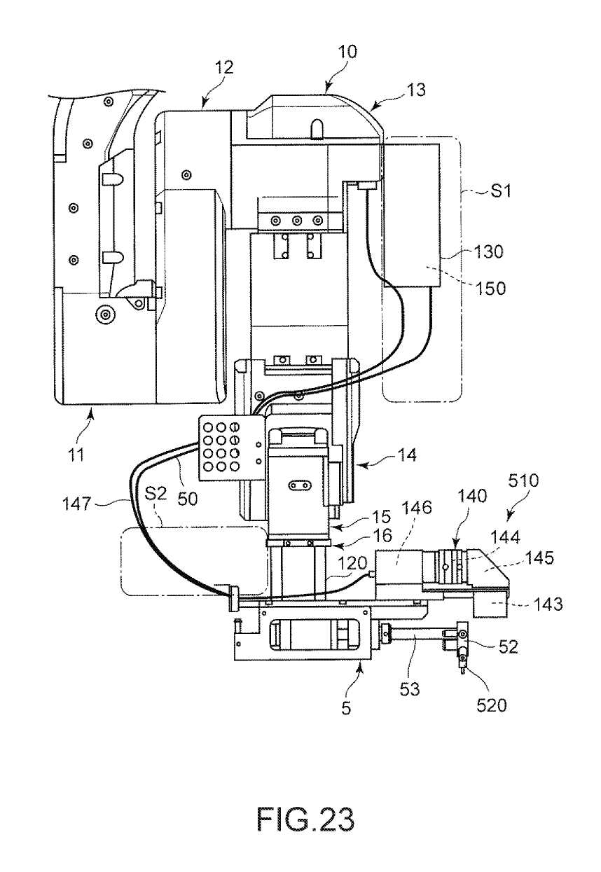

FIG. 12 is a front view of the robot shown in FIG. 1. FIGS. 13 and 14 are respectively diagrams showing an end effector shown in FIG. 12. FIG. 15 is a diagram showing a turning member and a holding section shown in FIG. 13. FIGS. 16 and 17 are respectively schematic diagrams showing a relation between the end effector shown in FIG. 13 and the test section shown in FIG. 8. FIG. 18 is a diagram showing another form of the end effector included in the robot shown in FIG. 12. FIG. 19 is a schematic diagram showing the turning member and the holding section shown in FIG. 15. FIGS. 20, 21, and 22 are respectively schematic diagrams showing modifications of the turning member and the holding section shown in FIG. 19. FIG. 23 is a diagram showing a part of the robot shown in FIG. 12. Note that a base side in FIG. 12 is referred to as “proximal end” or “upstream”. The opposite side of the base side (the end effector side) is referred to as “distal end” or “downstream”.

In the following explanation of the robot, the robot is explained with reference to FIGS. 12 to 23 together with FIGS. 1 to 11.

As shown in FIG. 5, the robot 1 is provided in the center on the inside of the housing 6. As shown in FIG. 4, the robot 1 is attached to a ceiling section of the frame 61 of the housing 6. That is, the robot 1 is a robot of a so-called ceiling-suspended type. Note that a setting place of the robot 1 is not limited to the ceiling section and may be, for example, a floor section or a sidewall section.

As shown in FIG. 12, the robot 1 includes a base 110, the robot arm 10, a force detecting section 120, an end effector 5, a negative-pressure generating device 130, and an imaging section 140. The robot 1 includes, as shown in FIG. 6, driving sections 18 and position sensors 19.

The robot 1 accesses the supply section 20, the test sections 300, and the collecting sections 40 and perform various kinds of work. For example, the robot 1 performs holding or release of an object in each of the supply section 20, the test sections 300, and the collecting sections 40. The robot 1 performs conveyance of the object between the supply section 20 and the test sections 300 and between the test sections 300 and the collecting sections 40.

The configuration of the robot 1 is explained in detail below.

### Base

The base 110 shown in FIG. 12 is a member used for attaching the robot 1 to the housing 6. A flange 1101 attached to the base 110 to surround the base 110 is provided in the base 110. The robot arm 10 is connected to the lower end portion of the base 110.

In this embodiment, as explained above, the robot 1 is attached to the ceiling section of the frame 61. Therefore, the robot arm 10 is located vertically below the base 110. Consequently, it is possible to particularly improve workability of the robot 1 in a region vertically below the robot 1.

Note that, in this embodiment, the base 110 is attached to the ceiling section. However, the base section 110 may be attached to another place, for example, may be attached to the floor section.

### Robot Arm

The robot arm 10 shown in FIG. 12 is turnably connected to the base 110. The robot arm 10 includes a first arm 11 (an arm), a second arm 12 (an arm), a third arm 13 (an arm), a fourth arm 14 (an arm), a fifth arm 15 (an arm), and a sixth arm 16 (an arm).

The first arm 11 is connected to the lower end portion of the base 110. The first arm 11, the second arm 12, the third arm 13, the fourth arm 14, the fifth arm 15, and the sixth arm 16 are coupled in this order from the proximal end side toward the distal end side.

As shown in FIG. 12, the first arm 11 is formed in a curved or bent shape. The proximal end portion of the first arm 11 is connected to the base 110. The first arm 11 includes a first portion 111 connected to the base 110 and extending in the horizontal direction, a second portion 112 connected to the second arm 12 and extending in the vertical direction (the perpendicular direction), and a third portion 113 located between the first portion 111 and the second portion 112 and extending in a direction inclining with respect to the horizontal direction and the vertical direction. Note that the first portion 111, the second portion 112, and the third portion 113 are integrally formed.

The second arm 12 is formed in a longitudinal shape and connected to the distal end portion of the first arm 11.

The third arm 13 is formed in a longitudinal shape and connected to an end portion opposite to an end portion of the second arm 12 to which the first arm 11 is connected.

The fourth arm 14 is connected to an end portion opposite to an end portion of the third arm 13 to which the second arm 12 is connected. The fourth arm 14 includes a pair of supporting sections 141 and 142 opposed to each other. The supporting sections 141 and 142 are used for connection to the fifth arm 15. Note that the fourth arm 14 is not limited to this structure. For example, the fourth arm 14 includes one supporting section (a cantilever).

The fifth arm 15 is located between the supporting sections 141 and 142. The fifth arm 15 is attached to the supporting sections 141 and 142 to be connected to the fourth arm 14.

The sixth arm 16 is formed in a tabular shape, the plan view shape of which is a circular shape. The sixth arm 16 is connected to the distal end portion of the fifth arm 15.

The exterior (a member configuring an external shape) of each of the arms 11 to 16 may be configured by one member or may be configured by a plurality of members.

As shown in FIG. 12, the robot arm 10 includes six joints 171 to 176 including a mechanism for supporting one arm to be capable of turning with respect to the other arm (or the base 110).

The base 110 and the first arm 11 are coupled via the joint 171. The first arm 11 is capable of turning around a first turning axis O1, which extends along the vertical direction, with respect to the base 110. The first arm 11 and the second arm 12 are coupled via the joint 172. The second arm 12 is capable of turning around a second turning axis O2, which extends along the horizontal direction, with respect to the first arm 11. The second arm 12 and the third arm 13 are coupled via the joint 173. The third arm 13 is capable of turning around a third turning axis O3, which extends along the horizontal direction, with respect to the second arm 12. The third arm 13 and the fourth arm 14 are coupled via the joint 174. The fourth arm 14 is capable of turning around the fourth turning axis O4, which is orthogonal to the third turning axis O3, with respect to the third arm 13. The fourth arm 14 and the fifth arm 15 are coupled via the joint 175. The fifth arm 15 is capable of turning around a fifth turning axis O5, which is orthogonal to the fourth turning axis O4, with respect to the fourth arm 14. The fifth arm 15 and the sixth arm 16 are coupled via the joint 176. The sixth arm 16 is capable turning around a sixth turning axis O6, which is orthogonal to the fifth turning axis O5, with respect to the fifth arm 15.

The robot 1 including the robot arm 10 is a vertical multi-joint robot including the six (plurality of) arms 11 to 16. Therefore, the robot 1 has a wide driving range and can exhibit high workability.

Although not shown in FIG. 12, the driving sections 18 and the position sensors 19 (angle sensors) are respectively provided in the joints 171 to 176 (see FIG. 6). That is, the robot 1 includes the driving sections 18 and the position sensors 19 (in this embodiment, six driving sections 18 and six position sensors 19) as many as the six arms 11 to 16.

The driving section 18 includes a motor (not shown in the figure) that generates a driving force for turning an arm corresponding to the driving section 18 and a reduction gear (not shown in the figure) that reduces the driving force of the motor. The position sensor 19 detects, for example, a rotation angle of a rotating shaft of the motor or the reduction gear included in the driving section 18.

As the motor included in the driving section 18, servomotors such as an AC servomotor and a DC servomotor can be used. As the reduction gear included in the driving section 18, for example, a reduction gear of a planetary gear type and a wave motion gear device can be used. As the position sensor 19, for example, an encoder and a rotary encoder can be used. The driving sections 18 are controlled by the robot control device 71 via a motor driver (not shown in the figure) electrically connected to the driving sections 18. Note that the motor driver is incorporated in, for example, the base 110.

### Force Detecting Section

As shown in FIG. 12, the force detecting section 120 is detachably attached to the distal end portion (the lower end portion) of the robot arm 10. Note that, in this embodiment, the sixth turning axis O6 of the sixth arm 16 and a center axis O120 of the force detecting section 120 substantially coincide with each other (overlap).

The force detecting section 120 detects, for example, a force (including a moment) applied to the robot 1, that is, an external force and outputs a detection result (a force output value) corresponding to the external force. The force detecting section 120 can be configured by, for example, a force sensor or a torque sensor.

In this embodiment, as the force detecting section 120, a six-axis force sensor is used that can detect six components, that is, translational force components Fx, Fy, and Fz in three axis (x axis, y axis, and z axis) directions orthogonal to one another and rotational force components (moments) Mx, My, and Mz around the three axes. In this embodiment, the end effector 5 is set at the distal end portion of the force detecting section 120. A force applied to the end effector 5 is detected by the force detecting section 120.

### End Effector

As shown in FIG. 12, the end effector 5 is detachably attached to the distal end portion (the lower end portion) of the force detecting section 120. The end effector 5 is a device that holds an object. The “holding” of the object indicates fixedly supporting the object with gripping or suction of the object (by a negative pressure, suction, etc.).

As shown in FIGS. 13 and 14, the end effector 5 includes a connecting member 51, a driving section 54, an attaching member 55, a shaft 53, a turning member 52, five holding sections 520, and a restricting member 56. The end effector 5 is capable of turning around the sixth turning axis O6 according to the turning of the sixth arm 16. The end effector 5 is configured to not interfere with the second arm 12 even if the end effector 5 turns around the sixth turning axis O6.

The connecting member 51 is a tabular member and used to attach the end effector 5 to the force detecting section 120. As shown in FIG. 12, the connecting member 51 includes a portion further projecting in a direction orthogonal to (crossing) the center axis O120 of the force detecting section 120 than the force detecting section 120. The imaging section 140 explained below is set in the projecting portion. Note that the imaging section 140 is provided on the same surface side of the connecting member 51 as the force detecting section 120.

As shown in FIGS. 13 and 14, the attaching member 55 connected to the connecting member 51 is attached under the connecting member 51. The driving section 54 is attached to the connecting member 51 by the attaching member 55. The shaft 53 is connected to the driving section 54.

The driving section 54 includes a motor (not shown in the figures) or the like that turns the shaft 53 around a turning axis O53 of the shaft 53 and a case 541 that houses the motor or the like. The shaft 53 projects from the driving section 54 in a direction orthogonal to (crossing) the center axis O120 of the force detecting section 120. The turning axis O53 of the shaft 53 is orthogonal to (crosses) the center axis O120.

The flat turning member 52 is attached to the distal end portion (the end portion on the opposite side of the driving section 54) of the shaft 53 to be detachably attachable to the shaft 53. The turning member 52 is located below the imaging section 140.

The turning member 52 is attached to the shaft 53 such that a plate surface of the turning member 52 is orthogonal to (cross) the turning axis O53. Since the shaft 53 is capable of turning around the turning axis O53, the turning member 52 attached to the shaft 53 is turns according to the turning of the shaft 53. Specifically, as shown in FIG. 15, the turning member 52 is capable of turning respectively in an arrow a1 direction and an arrow a2 direction. Note that the shaft 53 may be capable of sliding along the turning axis O53.

As shown in FIG. 15, the turning member 52 is formed in a hexagonal shape in plan view. Specifically, the turning member 52 is formed in a plan view shape obtained by cutting off an upper part of a regular octagonal shape. More specifically, the plan view shape of the turning member 52 is formed in a hexagonal shape, interior angles of which at two vertexes located on the upper side in FIG. 15 are smaller than interior angles at the remaining four vertexes. In this embodiment, the interior angles at the two vertexes in the upper part are respectively 90° and the interior angles at the remaining four vertexes are respectively 135°.

The holding sections 520 are respectively attached to five sides (edges) excluding a side (an edge) in the upper part of the turning member 52 to be detachably attachable to the turning member 52. That is, that is, the five holding sections 520 are provided in the turning member 52. The holding sections 520 are provided in the turning member 52 to prevent the turning member 52 from coming into contact with the imaging section 140 even if the turning member 52 turns.

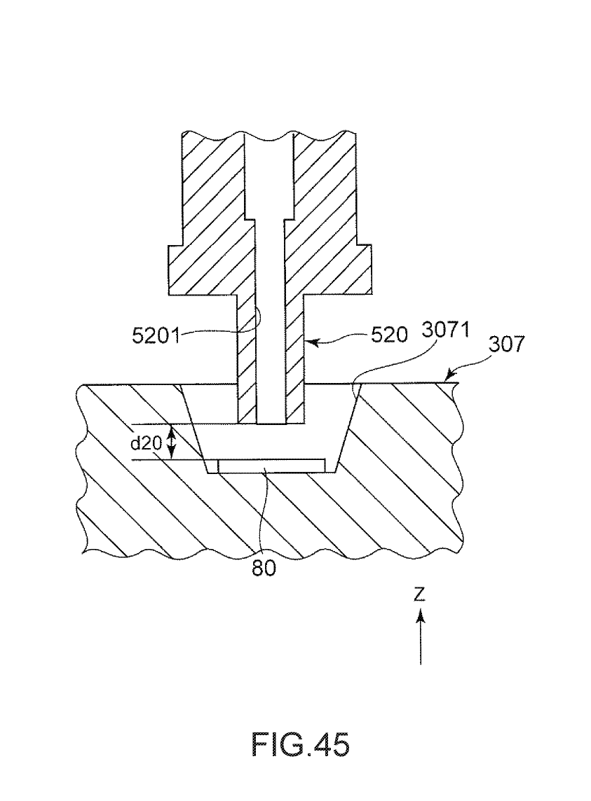

The holding sections 520 are portions that hold an object. In this embodiment, as the holding sections 520, suction pads capable of sucking and holding the object with a negative pressure are used. In the holding sections 520, through-holes 5201 through which gas (specifically, the air) passes are provided (see FIG. 45). As shown in FIGS. 13 and 14, pipes 50 (channel sections) are connected to the holding sections 520. The gas is supplied to the through-holes 5201 of the holding sections 520 through the pipes 50.

The restricting member 56 that restricts the movement of the pipes 50 is attached to the attaching member 55 to prevent the pipes 50 from hindering the turning of the robot arm 10. The restricting member 56 is connected to the outer surface of the attaching member 55 to cover the attaching member 55, the driving section 54, and the plurality of pipes 50.

With the end effector 5 having such a configuration, as explained above, since the turning member 52 is formed in the hexagonal shape and the holding sections 520 are respectively provided in the five sides of the turning member 52, it is possible to hold a plurality of objects. It is possible to further reduce a width L510 of the end effector 5 (see FIG. 15).

The size of the external shape of the end effector 5 is desirably set according to the size of the test section 300.

Specifically, as shown in FIG. 16, a width L51 (length) of the end effector 5 is desirably the same as or equal to or smaller than a half length L31 of the width of the test section 300. Consequently, when the robot 1 performs release (release of holding) and holding of an object in the test section 300, it is possible to reduce or prevent intrusion of the end effector 5 into the test section 300 adjacent to the end effector 5. As shown in FIG. 17, a height L53 (length) of the end effector 5 is smaller than a distance L33 between the test tables 301 included in the stacked two test sections 300. More strictly, although not shown in FIG. 17, the distance L33 is a distance between the socket 307 included in the test section 300 located below and the lower end (the lower surface) of the test section 300 located above. Consequently, it is possible to efficiently slip the distal end portion of the end effector 5 into a space between the test tables 301 included in the stacked two test sections 300. A projecting length L52 of the end effector 5 is desirably set such that a predetermined distance d10 can be secured between the force detecting section 120 and the test section 300 in a state in which the distal end portion of the end effector 5 is located on the test section 300. Consequently, when the robot 1 performs the holding and the release of the object in the test section 300, it is possible to reduce or prevent interference of the force detecting section 120 or the sixth arm 16 with the test section 300. The end effector 5 includes a projecting section 190 projecting further to the outer side than the force detecting section 120 when viewed from the axial direction of the sixth turning axis O6 (see FIG. 12). The projecting length L52 of the end effector 5 means the length of the projecting section 190. Note that, when the width of the force detecting section 120 is smaller than the width of the sixth arm 16 or when the force detecting section 120 is not included, the projecting section 190 means a portion projecting further to the outer side than the sixth arm 16 when viewed from the axial direction of the sixth turning axis O6. The projecting length L52 indicates a length based on the sixth arm 16 instead of the force detecting section 120.

The end effector 5 is explained above. Note that the end effector 5 is not limited to the configuration explained above. For example, an end effector 5a shown in FIG. 18 may be used. The end effector 5a includes five holding sections 520a disposed in one row. The distal ends of the holding sections 520a are located on the same straight line. With the end effector 5a, for example, it is possible to collectively hold a plurality of objects placed on the placing member 25.

However, with the end effector 5 in this embodiment, since the end effector 5 includes the turning member 52, the width L510 of the distal end portion of the end effector 5 can be set smaller than a width L510a of the end effector 5a (see FIGS. 15 and 18). Therefore, from the viewpoint of further reducing the width of the distal end portion, it is desirable to use the end effector 5.

As shown in FIG. 19, a width L511 at the distal end portion of the end effector 5 in a state in which the end effector 5 holds a plurality of objects 80 serving as an example of the “object” is smaller than a width L511a at the distal end portion of the end effector 5a in a state in which the end effector 5a holds the plurality of objects 80. The width L511 is a size including the plurality of objects 80 and the distal end portion of the end effector 5. Similarly, the width L511a is a size including the plurality of objects 80 and the distal end portion of the end effector 5a. Note that, in FIG. 19, illustration of the end effector 5a is omitted. Only the plurality of objects 80 held by the end effector 5a are illustrated.

Specifically, for example, when the objects 80 having a size of 20 mm×20 mm×1 mm is used and intervals among the objects 80 is set to 5 mm to prevent the objects 80 from coming into contact with one another, the width L511a at the distal end portion of the end effector 5a needs to be set to 125 mm or more. On the other hand, unlike the end effector 5a, the end effector 5 does not have to arrange a plurality of objects in one row. Therefore, the width and the thickness of the objects 80 and gaps among the objects 80 do not need to be taken into account as much as in the end effector 5a. In this embodiment, for example, the width L510 of a structure 500 including the turning member 52, which is the distal end portion of the end effector 5, and the plurality of holding sections 520 is set to 73 mm. Therefore, the width L511 at the distal end portion of the end effector 5 set taking into account the thickness of the objects 80 can be set to 75 mm. In this way, with the end effector 5, even if the end effector 5 holds the objects 80 as many as the objects 80 held by the end effector 5a, it is possible to set the width L511 of the end effector 5 smaller than the width L511a of the end effector 5a.

A maximum necessary width L512 in the width direction of the end effector 5 is smaller than a maximum necessary width L512a in the width direction of the end effector 5a (see FIGS. 15, 18, and 19). The maximum necessary width L512 is a distance from the position of the holding section 520, which holds and releases the object 80, to one end portion in the width direction of the end effector 5 including the object 80 (see FIGS. 15 and 19). In the case of the end effector 5, the maximum necessary width L512 is the same irrespective of whether which holding section 520 among the five holding sections 520 holds the object 80. The maximum necessary width L512a is a distance from the position of the holding section 520a located at the most distant end to one end portion in the width direction of the end effector 5a including the object 80 (see FIGS. 18 and 19). In this way, with the end effector 5, the maximum necessary width L512 can be set smaller than the maximum necessary width L512a of the end effector 5a. Therefore, it is possible to more effectively reduce or prevent the intrusion into the adjacent test section 300. From the viewpoint of reducing or preventing the intrusion into the adjacent test section 300, the maximum necessary width L512 of the end effector 5 and the maximum necessary width L512a of the end effector 5a are desirably smaller than the half length L31 of the width of the test section 300 (see FIGS. 16 and 19). In this embodiment, for example, the length L31 of the test section 300 is 112.5 mm, the maximum necessary width L512a of the end effector 5a is 110 mm, and the maximum necessary width L512 of the end effector 5 is 37.5 mm.

From the viewpoint of achieving a reduction in size while holding the plurality of objects as explained above, the end effector 5 can also be configured, for example, as shown in FIGS. 20, 21, and 22.

An end effector 5b shown in FIG. 20 includes the turning member 52, the plan view shape of which is a regular octagonal shape, and eight holding sections 520 provided in the sides of the turning member 52. With the end effector 5b, by increasing the number of sides of the turning member 52, it is possible to hold a larger number of the objects 80 than the end effector 5 while keeping the same width as the width L511 of the end effector 5.

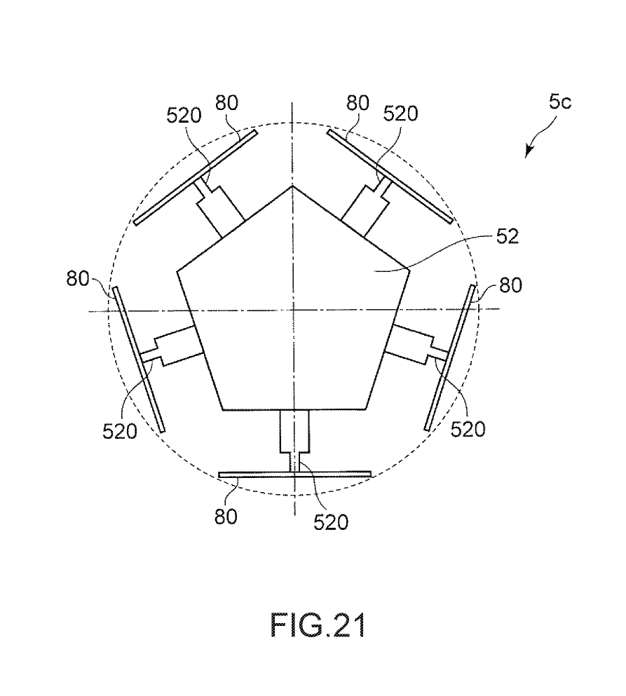

An end effector 5c shown in FIG. 21 includes the turning member 52, the plan view shape of which is a regular pentagonal shape, and five holding sections 520 provided in the sides of the turning member 52. With the end effector 5c, by reducing the number of sides of the turning member 52, it is possible to hold the object 80 larger than the object 80 that can be held by the end effector 5.

As explained above, the robot 1 includes the end effector 5 connected to the robot arm 10. The end effector 5 includes the turning member 52 capable of turning around the turning axis O53 and the plurality of holding sections 520 that are provided in the turning member 52 and hold the objects 80 (see FIG. 15). Consequently, it is possible to realize the end effector 5 that is small and can collectively convey the plurality of objects 80.

Note that the “robot” in the aspect of the invention is not limited to the robot 1 shown in FIG. 12. For example, the “robot” maybe a vertical multi-joint robot other than the robot 1 shown in FIG. 12 or a so-called horizontal multi-joint robot. However, when the postures of the objects placed in the supply section, the test section, and the collecting section are different from one another, the robot is desirably a vertical multi-joint robot including a plurality of arms such that the posture of an end effector provided at the distal end of a robot arm can be changed.

### Negative-Pressure Generating Device

As shown in FIG. 23, the negative-pressure generating device 130 is provided in a region S1 of the third arm 13 on the opposite side of the second arm 12. The negative-pressure generating device 130 is attached to the third arm 13 of the robot arm 10.

Although not shown in the figure, the negative-pressure generating device 130 is connected to, via a pipe inserted through the first arm 11 and the second arm 12 of the robot 1, a compressed-air supply device that generates gas (specifically, compressed air). The negative-pressure generating device 130 is connected to the pipe 50 of the end effector 5.

Although not shown in the figure, the negative-pressure generating device 130 includes an ejector that changes the inside of the pipe 50 to a negative pressure state (a vacuum state) using the gas (specifically, the compressed air), an air valve used for switching the inside of the pipe 50 to a negative pressure state or a positive pressure state, and a dividing unit that divides the pipe into the pipes 50 as many as the holding sections 520 of the end effector 5.

A flow of the gas in the pipe 50 (the channel section) connected to the end effector 5 can be switched by the negative-pressure generating device 130. That is, the inside of the pipe 50 can be switched to the negative pressure state and the positive pressure state. Therefore, the inside of the through-hole 5201 of the holding section 520 communicating with the inside of the pipe 50 can be switched to the negative pressure state and the positive pressure state (see FIG. 45). Consequently, by changing the through-hole 5201 to the negative pressure state, it is possible to suck and grip the object 80 with the holding section 520. On the other hand, by changing the through-hole 5201 to the positive-pressure state, it is possible to release the object 80 from the holding section 520.

In FIG. 23, the negative-pressure generating device 130 is provided in the region S1. However, for example, the negative-pressure generating device 130 may be provided in a region S2. The region S2 is a region on the left side in the figure of the sixth arm 16 and the force detecting section 120 and is a region below the first arm 11. By disposing the negative-pressure generating device 130 in the region S2, it is possible to further reduce the distance between the negative-pressure generating device 130 and the holding section 520. Therefore, it is possible to increase response speed of the suction of the holding section 520. It is possible to reduce the number of pipes drawn around from the third arm 13 to the negative-pressure generating device 130. Therefore, it is possible to simplify the drawing-around of the pipe.

The negative-pressure generating device 130 includes a detecting section 150 that detects a state of holding (suction) by the holding section 520 of the robot 1. In this embodiment, as the detecting section 150, a pressure sensor (an air pressure sensor) that detects the pressure of the gas in the pipe 50 (the channel section) connected to the holding section 520 is used. Note that the configuration of the pressure sensor is not particularly limited. The pressure sensor may be any sensor as long as the sensor can detect the pressure in the pipe 50. The detecting section 150 is not limited to the pressure sensor and may be configured by a flow rate sensor (a flowmeter) or the like capable of detecting a flow rate per unit time in the pipe 50. The number of detecting sections 150 may be two or more. In that case, the negative-pressure generating device 130 may include, for example, the detecting section 150 configured by the pressure sensor and the detecting section 150 configured by the flow rate sensor. The detecting section 150 may be provided in a section other than the negative-pressure generating device 130.

Note that the regions S1 and S2 are regions where the robot 1 less easily interfere with the robot 1 itself and the like. Therefore, it is effective from the viewpoint of avoiding interference of the robot 1 with the robot 1 itself and the like to dispose the negative-pressure generating device 130 in the regions S1 and S2. Since the regions S1 and S2 are regions where the robot 1 less easily interferes with the robot 1 itself and the like, it is also effective to dispose various components and the like other than the negative-pressure generating device 130 in the regions S1 and S2.

### Imaging Section

As shown in FIG. 23, the imaging section 140 having an imaging function is provided above the end effector 5. The imaging section 140 is set to be capable of imaging the downward direction of the imaging section 140, that is, the downward direction of the turning member 52. Note that the imaging section 140 is provided in the turning member 52 and may turn together with the turning member 52.

The imaging section 140 includes an illuminating section 143 including an LED, a lens group 144 including a plurality of lenses, a prism 145 that refracts light, and an imaging element 146 configured by a CCD (Charge Coupled Device) or the like. Light irradiated by the illuminating section 143 is reflected on an imaging object or the like. Reflected light of the light is made incident on the lens group 144 and the prism 145 and forms an image on a light receiving surface of the imaging element 146. The imaging section 140 converts the light into an electric signal and outputs the electric signal to the robot control device 71.

Since the imaging section 140 includes optical components such as the prism 145 that changes the direction of the light, it is possible to reduce the length in the height direction of the imaging section 140 (the up-down direction in FIG. 23). Therefore, a structure 510 including the end effector 5, which is the distal end portion of the robot 1, and the imaging section 140 can be configured to be flat, thin, and narrow. Therefore, it is possible to efficiently slip the structure 510 into a space between the test tables 301 included in the stacked two test sections 300 (see FIG. 17).

The imaging section 140 includes an autofocus function for automatically adjusting a focus and a zoom function for adjusting magnification of imaging.

A wire 147 connected to the imaging section 140 is drawn around to the third arm 13 of the robot 1 together with the pipes 50 connected to the holding sections 520 of the end effector 5. Note that the wire 147 drawn around to the third arm 13 passes through the second arm 12 and the first arm 11 and is electrically connected to the robot control device 71 via a circuit board (not shown in the figure) in the base 110.

The configuration of the robot 1 is explained above.

### Imaging Section for Alignment

As shown in FIG. 5, the imaging section for alignment 9 is provided in the center on the inside of the housing 6. The imaging section for alignment 9 is located below the robot 1.

The imaging section for alignment 9 has an imaging function and is fixed to, for example, the floor surface of the housing 6. Although not shown in the figure, the imaging section for alignment 9 includes an illuminating section including an LED, a lens group including a plurality of lenses, and an imaging element configured by a CCD or the like. Light irradiated by the illuminating section is reflected on an imaging object or the like. Reflected light of the light is made incident on the lens group and forms an image on a light receiving surface of the imaging element. The imaging section for alignment 9 converts the light into an electric signal and outputs the electric signal to, for example, the peripheral-apparatus control device 72. Note that the signal from the imaging section for alignment 9 may be output to the robot control device 71.

The imaging section for alignment 9 is capable of imaging the upward direction of the imaging section for alignment 9. Therefore, the imaging section for alignment 9 can image the distal end portion of the robot 1 located above the imaging section or alignment 9. Therefore, it is possible to grasp a held state of an object by the robot 1 on the basis of an image picked up by the imaging section for alignment 9. When the holding is not appropriately performed, deviation from a proper value of the holding is calculated as a correction value. The correction value is output to the peripheral-apparatus control device 72. Consequently, the robot 1 can perform work such as conveyance and release of the object under the control by the robot control device 71 on the basis of data concerning the correction value acquired from the peripheral-apparatus control device 72. Therefore, it is possible to more highly accurately perform the work of the robot 1.

### Robot Control Device 71

As shown in FIG. 1, the robot control device 71 is provided on the front side (−Y-axis side) on the inside of the housing 6. The robot control device 71 controls the sections of the robot 1.

The robot control device 71 can be configured by, for example, a personal computer (PC) incorporating a processor like a CPU (Central Processing Unit), a ROM (Read Only Memory), and a RAM (Random Access Memory). The robot control device 71 maybe connected to the robot 1 by either wired communication or wireless communication.

As shown in FIG. 6, the robot control device 71 includes a control section 711 (a processing section), an input/output section 712 (an information acquiring section), and a storing section 713.

The control section 711 has, for example, a function of controlling driving of the robot 1, actuation of the imaging section 140, and the like and a function of processing various arithmetic operations and the like. The control section 711 is configured by, for example, a processor. The functions of the control section 711 can be realized by the processor executing various computer programs stored in the storing section 713. Specifically, the control section 711 controls driving of the driving sections 18 included in the robot 1 and controls the arms 11 to 16 independently from one another. The control section 711 controls driving of the driving section 54 of the end effector 5. For example, the control section 711 moves the holding section 520 of the end effector 5 to a target position on the basis of signals (detection results) output from the position sensor 19, the force detecting section 120, and the imaging section 140. For example, the control section 711 calculates a coordinate of an imaging target in an image coordinate system on the basis of an image of the imaging section 140. For example, the control section 711 calculates a correction parameter for converting a coordinate (an image coordinate) in the image coordinate system of the imaging section 140 into a coordinate (a robot coordinate) in a coordinate system of the robot 1. Similarly, the control section 711 calculates a correction parameter for converting a coordinate (an image coordinate) in an image coordinate system of the imaging section for alignment 9 into a coordinate in the coordinate system of the robot 1.

The input/output section 712 is configured by, for example, an interface circuit and acquires signals output from the position sensor 19, the force detecting section 120, and the imaging section 140. The input/output section 712 outputs target values of motors to the driving sections 18 and the driving section 54. The input/output section 712 exchanges data and the like with the peripheral-apparatus control device 72 and the test control device 73. Note that the robot control device 71, the peripheral-apparatus control device 72, and the test control device 73 maybe connected to one another by either wired communication or wireless communication.

The storing section 713 is configured by, for example, a RAM and a ROM and stores computer programs, various data, and the like for the robot control device 71 to perform various kinds of processing. Note that the storing section 713 is not limited to a storing section (a RAM, a ROM, etc.) incorporated in the robot control device 71 and may include a so-called external storage device (not shown in the figure).

### Peripheral-Apparatus Control Device 72

As shown in FIG. 1, the peripheral-apparatus control device 72 is provided on the front side (the −Y-axis side) on the inside of the housing 6. The peripheral-apparatus control device 72 controls the imaging section for alignment 9, the display device 60, and the like. The peripheral-apparatus control device 72 may be configured to control the supply section 20, the test sections 300, and the collecting sections 40 depending on the configurations of the sections. Although not shown in the figure, the peripheral-apparatus control device 72 is configured to control an illumination, a temperature sensor, and the like provided in the housing 6. Note that the imaging section for alignment 9, the display device 60, and the like may be controlled by the robot control device 71 instead of being controlled by the peripheral-apparatus control device 72.

The peripheral-apparatus control device 72 can be configured by, for example, a personal computer incorporating a processor, a ROM, and a RAM. The peripheral-apparatus control device 72 may be connected to the imaging section for alignment 9, the display device 60, and the like by either wired communication or wireless communication.

As shown in FIG. 6, the peripheral-apparatus control device 72 includes a control section 721 (a processing section) an input/output section 722 (an information acquiring section), and a storing section 723.

The control section 721 has, for example, a function of controlling, for example, actuation of the imaging section for alignment 9 and a function of processing various kinds of arithmetic operations and the like. The control section 721 is configured by, for example, a processor. The functions of the control section 721 can be realized by the processor executing various computer programs stored in the storing section 723. For example, the control section 721 calculates, on the basis of an image of the imaging section for alignment 9, a coordinate of an imaging target in an image coordinate system.

The input/output section 722 is configured by, for example, an interface circuit and acquires a signal output from the imaging section for alignment 9. The input/output section 722 outputs a signal for displaying a desired window (screen) on the display device 60. The input/output section 722 exchanges data and the like with the robot control device 71 and the test control device 73. The storing section 723 is configured by, for example, a RAM and a ROM and stores computer programs, various data, and the like for the peripheral-apparatus control device 72 to perform various kinds of processing and the like. Note that the storing section 723 is not limited to a storing section (a RAM, a ROM, etc.) incorporated in the peripheral-apparatus control device 72 and may include a so-called external storage device (not shown in the figure).

### Test Control Device 73

As shown in FIG. 1, the test control device 73 is provided on the back side (+Y-axis side) on the inside of the housing 6. The test control device 73 controls the test sections 300.

The test control device 73 can be configured by, for example, a personal computer incorporating a processor, a ROM, and a RAM. The test control device 73 may be connected to the test sections 300 by either wired communication or wireless communication.

As shown in FIG. 6, the test control device 73 includes a control section 731 (a processing section), an input/output section 732 (an information acquiring section), and a storing section 733.

The control section 731 has, for example, a function of controlling, for example, actuation of the test sections 300 and a function of processing various arithmetic operations and the like. The control section 731 is configured by, for example, a processor. The functions of the control section 731 are realized by the processor executing various computer programs stored in the storing section 733. For example, the control section 731 determines on the basis of test results from the test sections 300 whether an object is a non-defective product, a defective product, or retested.

The input/output section 732 is configured by, for example, an interface circuit and acquires signals output from the test sections 300. The input/output section 732 exchanges data and the like with the robot control device 71 and the test control device 73. The storing section 733 is configured by, for example, a RAM and a ROM and stores computer programs, various data, and the like for the test control device 73 to perform various kinds of processing and the like. Note that the storing section 733 is not limited to a storing section (a RAM, a ROM, etc.) incorporated in the test control device 73 and may include a so-called external storage device (not shown in the figure).

Note that the test control device 73 does not have to be included as a component of the robot system 100. In that case, the test unit 3, the robot control device 71, and the peripheral-apparatus control device 72 only have to be capable of performing wired communication or wireless communication with a “test control device” separate from the robot system 100.

The configurations of the sections of the robot system 100 are explained above.

### 2. Operation of the Robot, Disposition of the Sections of the Robot System, and the Like

The operation of the robot 1, disposition of the sections of the robot system 100, and the like are explained.

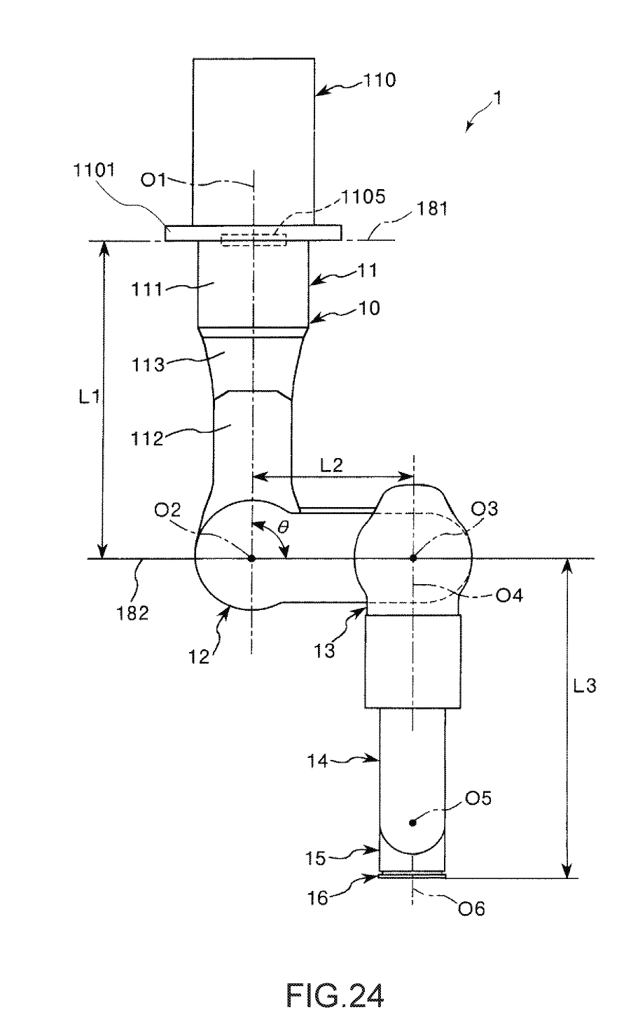

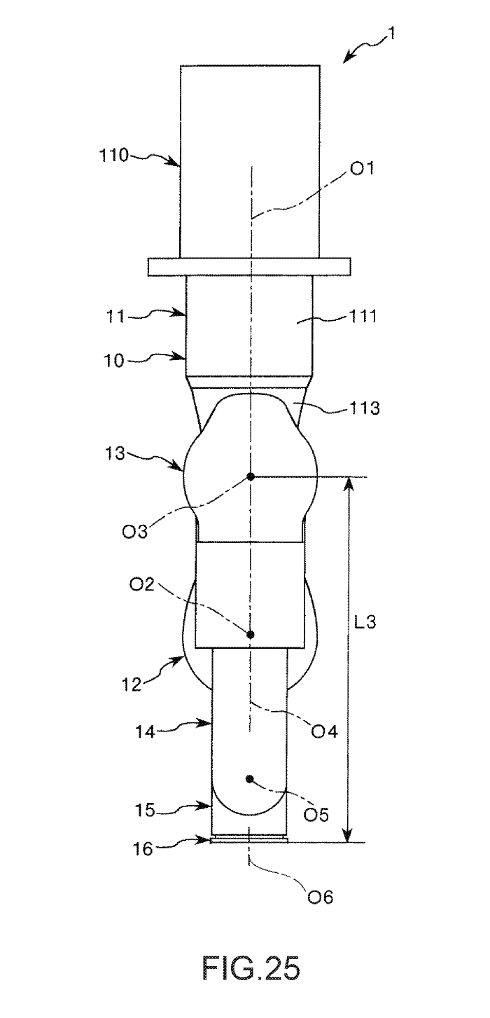

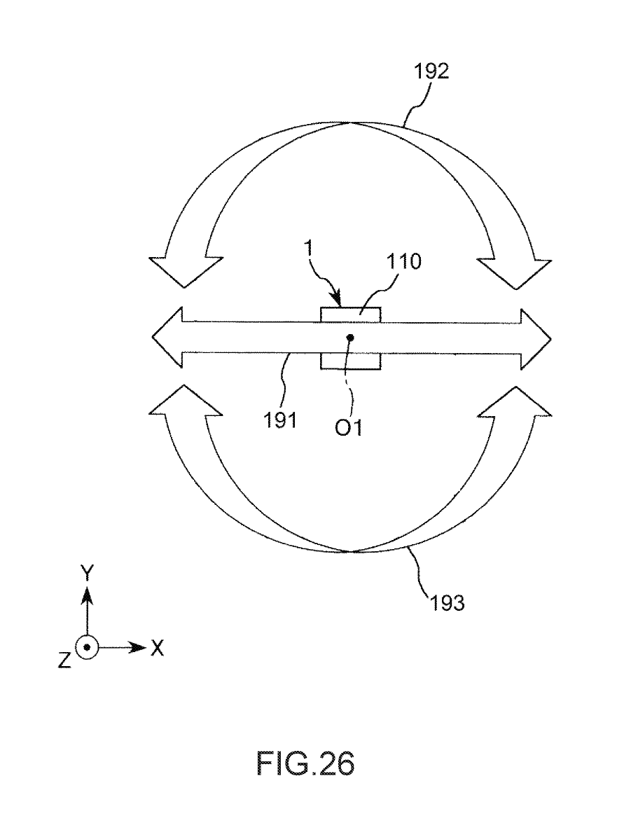

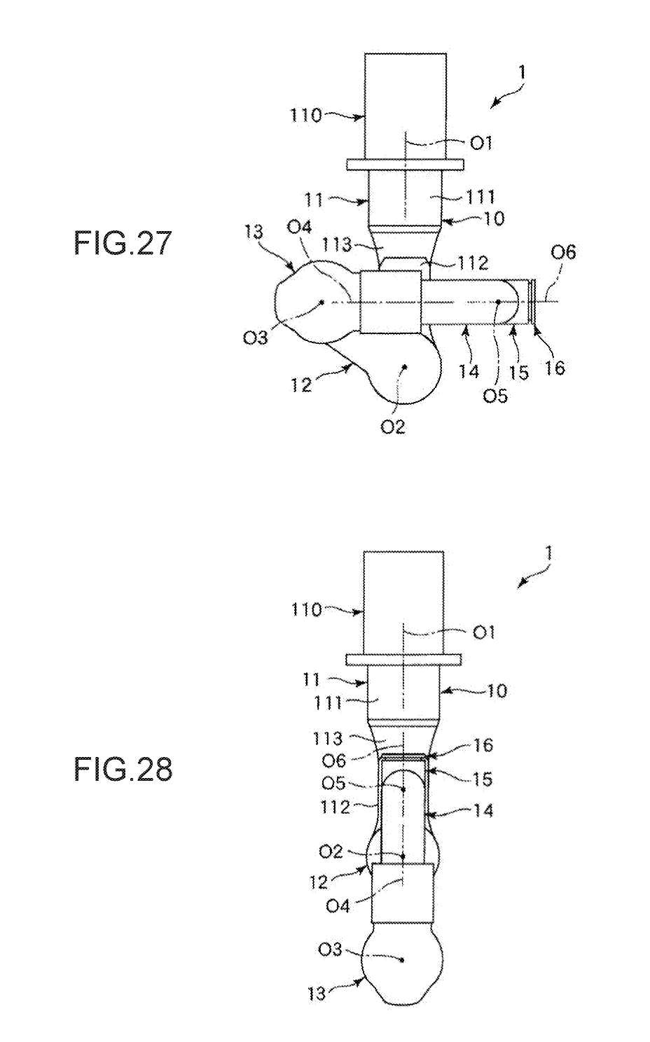

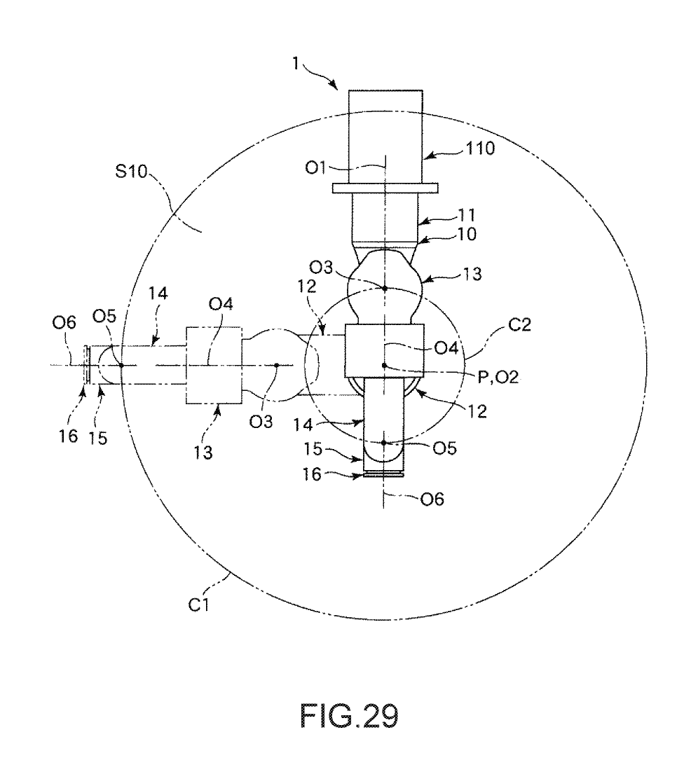

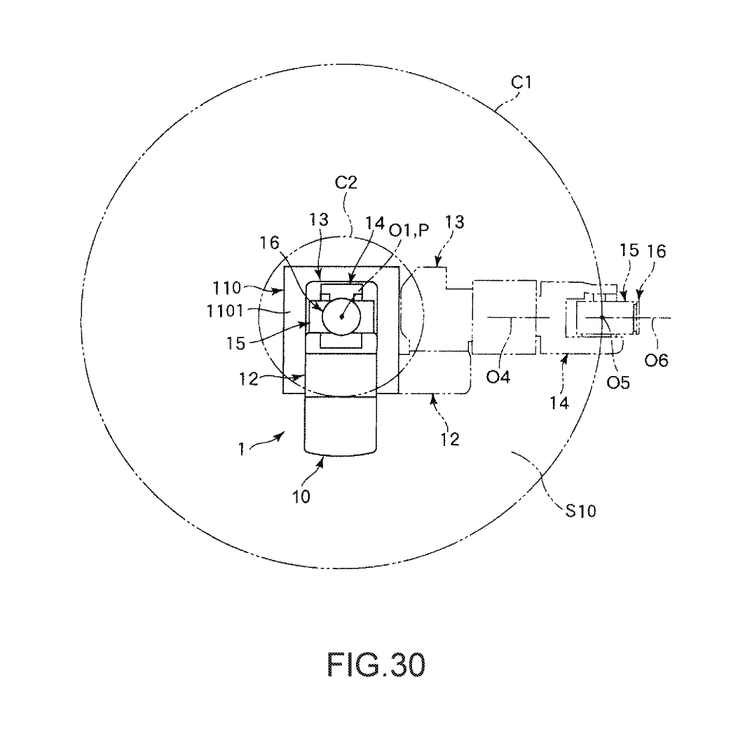

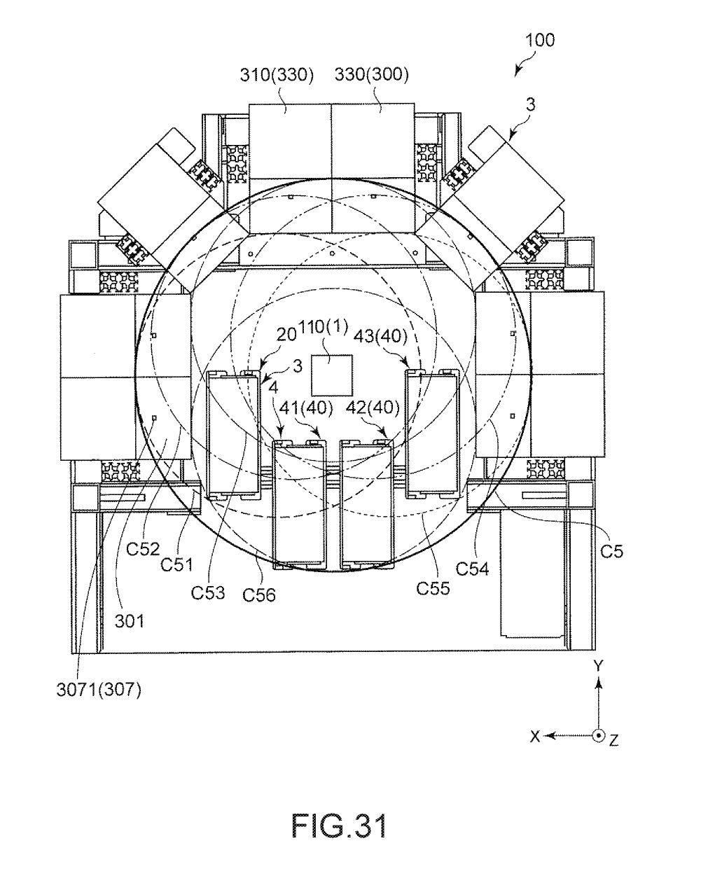

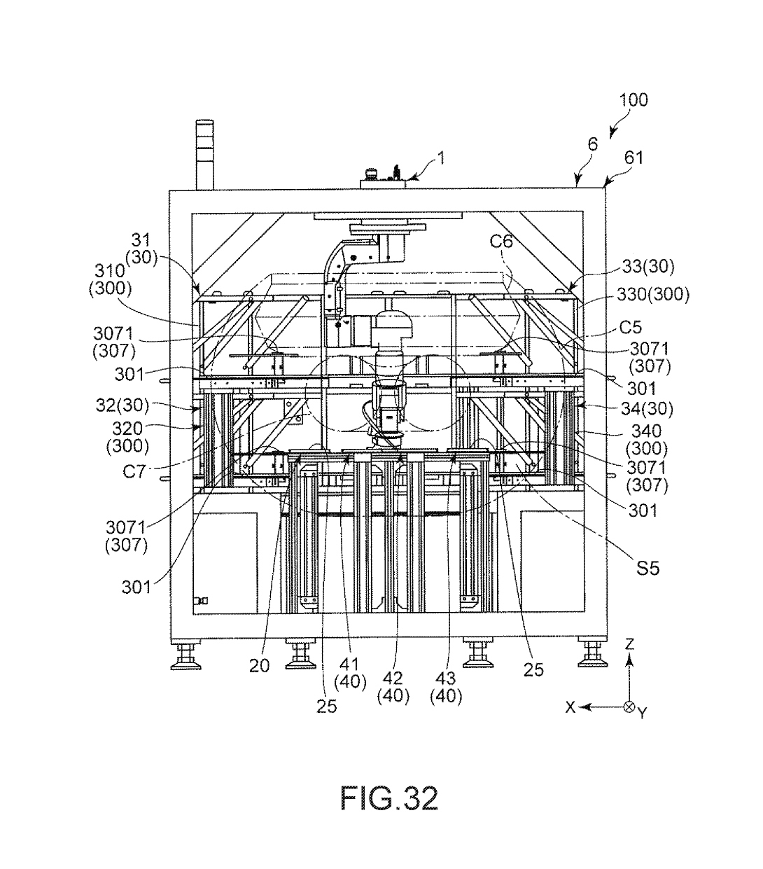

FIG. 24 is a side view showing a state in which the first arm, the second arm, and the third arm of the robot shown in FIG. 12 do not overlap. FIG. 25 is a side view showing a state in which the first arm, the second arm, and the third arm of the robot shown in FIG. 12 overlap. FIG. 26 is a diagram showing a moving route of the distal end of the robot arm in the operation of the robot shown in FIG. 12. FIG. 27 is a schematic side view of a state in which the first arm and the third arm of the robot shown in FIG. 12 cross. FIG. 28 is a schematic side view of a state in which the first arm and a fourth arm of the robot shown in FIG. 12 overlap. FIG. 29 and FIG. 30 are respectively diagrams for explaining a movable range of the distal end portion of the robot arm included in the robot shown in FIG. 12. FIG. 31 and FIG. 32 are respectively diagrams showing a movable range of the distal end of the end effector included in the robot shown in FIG. 12. Note that, in FIGS. 24, 25, and 27 to 30, illustration of the end effector 5 and the like is omitted. In FIG. 32, illustration of the cover member 62 of the housing 6 is omitted.

As shown in FIG. 24, in the robot 1, a length L1 of the first arm 11 is set larger than a length L2 of the second arm 12. The length L1 of the first arm 11 is a distance between the second turning axis O2 and a line segment 181 (or a center line of a bearing section 1105 included in the driving section 18 provided on the base 110), which extends along a plate surface of the flange 1101, when viewed from the second turning axis O2. Note that the flange 1101 is formed in a frame shape provided to surround the base 110. Therefore, the plate surface of the flange 1101 and the lower surface of the base 110 coincide with each other. The length L2 of the second arm 12 is a distance between the second turning axis O2 and the third turning axis O3 when viewed from the axial direction of the second turning axis O2.

As shown in FIG. 25, the robot 1 is configured to be capable of setting an angle θ formed by the first arm 11 and the second arm 12 to 0° when viewed from the axial direction of the second turning axis O2. That is, as shown in FIG. 25, the robot 1 is configured such that the first arm 11 and the second arm 12 can overlap when viewed from the axial direction of the second turning axis O2. The second arm 12 is configured not to interfere with the first arm 11 when the first arm 11 and the second arm 12 overlap when viewed from the axial direction of the second turning axis O2. The angle θ formed by the first arm 11 and the second arm 12 is, as shown in FIG. 24, an angle formed by a straight line 182, which passes the second turning axis O2 and the third turning axis O3, and the first turning axis O1 when viewed from the axial direction of the second turning axis O2.

As shown in FIG. 25, the robot 1 is configured such that the second arm 12 and the third arm 13 overlap when viewed from the axial direction of the second turning axis O2. Therefore, the robot 1 is configured such that the first arm 11, the second arm 12, and the third arm 13 simultaneously overlap when viewed from the axial direction of the second turning axis O2.

As shown in FIG. 24, a total length L3 of the third arm 13, the fourth arm 14, the fifth arm 15, and the sixth arm 16 is set larger than the length L2 of the second arm 12. As shown in FIG. 25, the robot 1 is configured such that the distal end of the robot arm 10 can be projected from the second arm 12 when the second arm 12 and the third arm 13 overlap when viewed from the axial direction of the second turning axis O2. The total length L3 of the third arm 13, the fourth arm 14, the fifth arm 15, and the sixth arm 16 is a distance between the third turning axis O3 and the distal end of the sixth arm 16 when viewed from the axial direction of the second turning axis O2. In this case, as shown in FIG. 25, the third arm 13, the fourth arm 14, and the fifth arm 15 are in a state in which the fourth turning axis O4 and the sixth turning axis O6 coincide with each other or are parallel to each other.

In the robot 1 including the robot arm 10, by satisfying the relation explained above, it is possible to move, by turning the second arm 12 and the third arm 13 without turning the first arm 11, the distal end of the robot arm 10 to positions 180° different from each other around the first turning axis O1 through a state in which the first arm 11 and the second arm 12 overlap when viewed from the axial direction of the second turning axis O2. Therefore, as shown in FIG. 26, it is possible to perform operation for moving the distal end of the robot arm 10 as indicated by an arrow 191 without performing operation for moving the distal end of the robot arm 10 as indicated by arrows 192 and 193 when viewed from the first turning axis O1 direction. That is, it is possible to perform operation for moving the distal end of the robot arm 10 on a straight line when viewed from the axial direction of the first turning axis O1. Consequently, it is possible to reduce a space for preventing interference of the robot 1.

Since it is possible to perform the operation for moving the distal end of the robot arm 10 on a straight line, when moving the distal end of the robot arm 10 to the positions 180° different from each other around the first turning axis O1, it is possible to not turn the first arm 11 or to reduce a turning angle (a turning amount) of the first arm 11. Therefore, it is possible to reduce interference of the second portion 112 and the third portion 113 of the first arm 11, which are portions protruding further to the outer side than the base 110 when viewed from the axial direction of the first turning axis O1, with a peripheral apparatus of the robot 1. Since it is possible to perform the operation for moving the distal end of the robot arm 10 on a straight line, it is easy to grasp a movement of the robot 1.

For example, when it is attempted to move the distal end of the robot arm 10 as indicated by arrows 192 and 193 in FIG. 26, since the robot 1 is likely to interfere with a peripheral apparatus, it is necessary to teach the robot 1 a large number of retraction points for avoiding the interference. Therefore, a lot of labor and a long time are required for the teaching. On the other hand, in the robot 1, since the distal end of the robot arm 10 can be moved as indicated by an arrow 191 in FIG. 26, a region where the robot 1 is likely to interfere with the peripheral apparatus is extremely small. Therefore, it is possible to reduce the number of retraction points taught to the robot 1. It is possible to reduce the labor and time required for the teaching. For example, with the robot 1, it is possible to reduce the number of retraction points taught to the robot 1 to approximately one third of the number of retraction points taught to a robot in the past. Therefore, it is remarkably easy to teach the retraction points.

As shown in FIG. 27, the robot 1 is configured such that the first arm 11 and at least one arm of the third arm 13, the fourth arm 14, and the fifth arm 15 can cross when viewed from the axial direction of the second turning axis O2. In FIG. 27, the first arm 11 and the third arm 13 cross. Since the arms can take this crossing posture, it is possible to further increase the driving range of the robot 1. As shown in FIG. 28, the robot 1 is configured such that the first arm 11 and at least one arm of the third arm 13, the fourth arm 14, and the fifth arm 15 overlap when viewed from the axial direction of the second turning axis O2. In FIG. 28, the first arm 11 and the fourth arm 14 overlap. Since the arms can take an overlapping posture in this way, it is possible to further increase the driving range of the robot 1.

As shown in FIGS. 29 and 30, the robot 1 can move the distal end portion (specifically, the fifth turning axis O5) of the robot arm 10 along an imaginary surface C1 formed in a spherical shape. Note that FIG. 29 is a side view of the robot 1. FIG. 30 is a bottom view of the robot 1. The imaginary surface C1 is a spherical surface centering on an intersection P of the first turning axis O1 and the second turning axis O2 at the time when the robot 1 is in the state shown in FIG. 25 and is a surface formed by an aggregate of tracks drawn by the fifth turning axis O5 at the time when the robot arm 10 is driven in a state in which the intersection P and the fifth turning axis O5 are most apart from each other (in a posture of the robot 1 indicated by an alternate long and two short dashes line shown in FIGS. 29 and 30). Therefore, the imaginary surface C1 indicates a largest movable region of the distal end portion (specifically, the fifth turning axis O5) of the robot arm 10.

As shown in FIGS. 29 and 30, the robot 1 can move the distal end portion of the robot arm 10 along an imaginary surface C2 formed in a spherical shape. The imaginary surface C2 is a spherical surface centering on the intersection P and is a surface formed by an aggregate of tracks drawn by the fifth turning axis O5 at the time when the robot arm 10 is driven in a state in which the intersection P and the fifth turning axis O5 are closest to each other (a state of the robot 1 indicated by a solid line shown in FIGS. 29 and 30). Therefore, the imaginary surface C2 indicates a smallest movable region of the distal end portion (specifically, the fifth turning axis O5) of the robot arm 10.

As explained above, the robot 1 is capable of taking the postures shown in FIGS. 25, 27, and 28. Therefore, the robot 1 can move the distal end portion of the robot arm 10 into a range between the largest movable region and the smallest movable region. Therefore, a movable range of the distal end portion of the robot arm 10 is a space S10 between the imaginary surface C1 and the imaginary surface C2 (see FIGS. 29 and 30). Note that, more strictly, the movable range of the distal end portion of the robot arm 10 is set to a range excluding the base 110 and the vicinity of the base 110 in the space S10 to prevent the robot arm 10 from interfering with the base 110 and the like (the robot 1 itself).

In this way, the robot 1 can move the distal end portion of the robot arm 10 substantially in a spherical shape centering on the intersection P.

As explained above, the robot 1 includes the projecting section 190. In this embodiment, the projecting section 190 includes the imaging section 140, the shaft 53 of the end effector 5, the turning member 52, and the plurality of holding sections 520. Therefore, a movable range of the distal end of the end effector 5 is shifted from the movable range of the distal end portion of the robot arm 10 by the length of the projecting section 190. In the robot system 100, the dispositions of the supply section 20, the plurality of test sections 300, and the plurality of collecting sections 40 are set taking into account the shift.

In FIG. 31, imaginary surfaces C51, C52, C53, C54, C55, and C56 indicating largest movable regions of the holding section 520 of the end effector 5 are shown. The imaginary surfaces C51 to C55 respectively indicate largest movable regions of the holding section 520 in a state in which the projecting section 190 is directed to the test sections 300 side. The imaginary surface C56 indicates a largest movable region of the holding section 520 in a state in which the projecting section 190 is directed to the supply section 20 and the plurality of collecting sections 40. Therefore, an imaginary surface C5 obtained by connecting places of the imaginary surfaces C51 to C56 most apart from the base 110 of the robot 1 can be considered a largest movable region of the holding section 520 in all the directions. Therefore, by disposing the supply section 20, the concave sections 3071 of the sockets 307 included in the plurality of test sections 300, and the plurality of collecting sections 40 in the imaginary surface C5, the robot 1 is capable of accessing the sections. In particular, as shown in FIG. 31, it is desirable to dispose the concave sections 3071 of the sockets 307 on the imaginary surface C5 or in the vicinity of the imaginary surface C5. Consequently, it is possible to efficiently operate the robot 1.

In FIG. 32, the imaginary surface C5 at the time when the robot system 100 is viewed from the front side is shown. In FIG. 32, an imaginary surface C7 indicating a smallest movable region of the holding section 520 in all the directions is shown. The inner side of an imaginary surface C6 shown in FIG. 32 is a region where the robot 1, for example, interferes with the robot 1 itself. Therefore, a movable range of the holding section 520 is a space S5 obtained by excluding a space on the inner side of the imaginary surface C7 and a space on the inner side of the imaginary surface C6 from a space on the inner side of the imaginary surface C1. Therefore, in this embodiment, the supply section 20, the concave sections 3071 of the sockets 307 included in the test sections 300, the collecting sections 40, and the like are disposed in the space S5 such that the robot 1 can accelerate.

In this way, with the robot 1, it is possible to form a largest movable range of the holding section 520 in a substantially spherical shape. Therefore, as shown in FIGS. 8 and 31, in the robot system 100, the plurality of first test sections 310, the plurality of second test sections 320, the plurality of third test sections 330, and the plurality of fourth test sections 340 are desirably respectively disposed on an arc centering on the robot 1 (more strictly, the first turning axis O1) when viewed from the Z-axis direction (viewed from the gravity direction). Consequently, it is possible to efficiently set the plurality of first test sections 310, the plurality of second test sections 320, the plurality of third test sections 330, and the plurality of fourth test sections 340 in the movable range of the holding section 520 included in the end effector 5. Therefore, it is possible to achieve space saving of a setting area of the robot system 100.

As explained above, the first test section 310 and the second test section 320 are disposed to overlap when viewed from the Z-axis direction (viewed from the gravity direction) (see FIG. 8). Similarly, the third test section 330 and the fourth test section 340 are disposed to overlap when viewed from the Z-axis direction (viewed from the gravity direction) (see FIG. 8). Consequently, it is possible to set a larger number of the first test sections 310, the second test sections 320, the third test sections 330, and the fourth test sections 340 in a relatively small setting area. Therefore, it is possible to further improve the space saving of the setting area of the robot system 100. Note that the overlapping of the first test section 310 and the second test section 320 include overlapping of at least a part of the first test section 310 and at least a part of the second test section 320. The overlapping of two test sections 300 include overlapping of at least a part of one test section 300 and at least a part of the other test section 300.

Specifically, the setting area of the robot system 100 is desirably 256 m² or less, more desirably 250 m² or less, and still more desirably 240 m² or less. In this embodiment, as shown in FIG. 5, a length L13 in the X-axis direction of the robot system 100 is approximately 1600 mm. A length L12 in the Y-axis direction of the robot system 100 is approximately 1600 mm. Therefore, the setting area of the robot system 100 is 256 m² or less. In this way, the robot system 100 can be set in a place having a relatively small setting area. Therefore, it is possible to sufficiently reduce the robot system 100 in size.

The robot system 100 includes the robot 1 having the configuration explained above. The dispositions and the like of the supply section 20, the test sections 300, and the collecting sections 40 are contrived according to the driving of the robot 1. Therefore, with the robot system 100, even if the robot system 100 is set in the setting area smaller than a setting are of the robot system in the past, it is possible to increase the number of test sections 300 to approximately 1.3 to 2.6 times compared with the robot system in the past.

In the robot system 100, the setting area is desirably 150 m² or more, more desirably 160 m² or more, and still more desirably 170 m² or more. Consequently, it is possible to particularly efficiently drive the robot 1.

As shown in FIG. 3, in the robot 100, a setting height L11 (the length in the Z-axis direction of the robot system 100) is desirably 2100 mm or less, more desirably 2000 mm or less, and still more desirably 1900 mm or less. In this embodiment, the setting height L11 is approximately 1880 mm. In this way, the robot system 100 includes the robot 1 and the dispositions and the like of the supply section 20, the test sections 300, and the collecting sections 40 are contrived according to the driving of the robot 1. Consequently, the it is possible to sufficiently reduce the setting height of the robot system 100.

As shown in FIG. 5, the robot 1, the collecting sections 40, and the supply section 20 are located on the inner side of the first test section group 31, the second test section group 32, the third test section group 33, and the fourth test section group 34 (located on the center side of the robot system 100) when viewed from the Z-axis direction (viewed from the gravity direction). The height of the upper part of the supply section 20 (more strictly, the placing member 25) is equal to or smaller than the height of the upper part of the first test section 310 and the height of the upper part of the supply section 20 (more strictly, the placing member 25) is equal to or smaller than the height of the position of the upper part of the second test section 320 (see FIG. 32). In this embodiment, the height of the upper part of the supply section 20 (more strictly, the placing member 25) is equal to or smaller than the height of the upper part of the third test section 330 and the height of the upper part of the supply section 20 (more strictly, the placing member 25) is equal to or smaller than the height of the position of the upper part of the fourth test section 340 (see FIG. 32). In particular, in this embodiment, as shown in FIG. 32, the position of the upper surface of the test table 301 and the position of the upper surface of the placing member 25 are substantially equal. Consequently, when holding, conveyance, and release of an object by the robot 1 are performed, it is possible to reduce or prevent likelihood of interference of the robot 1 with the supply section 20, the first test section 310, the second test section 320, the third test section 330, and the fourth test section 340.

### 3. Example of Work of the Robot 1

An example of work of the robot 1 is explained.

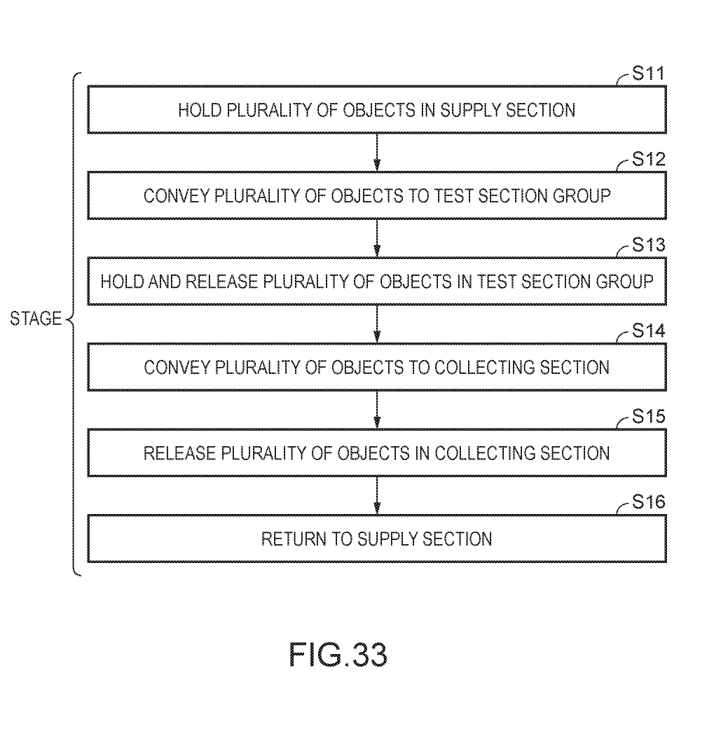

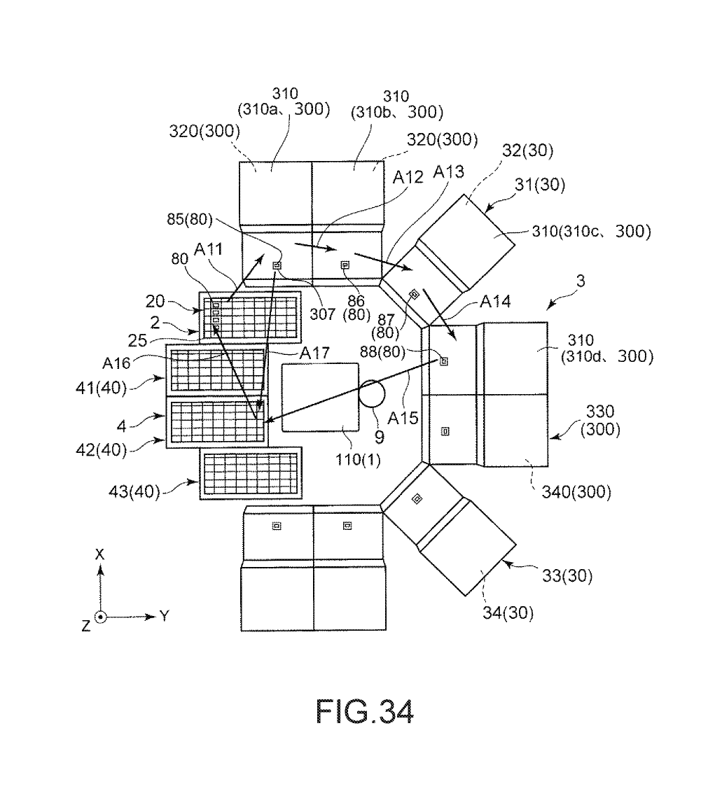

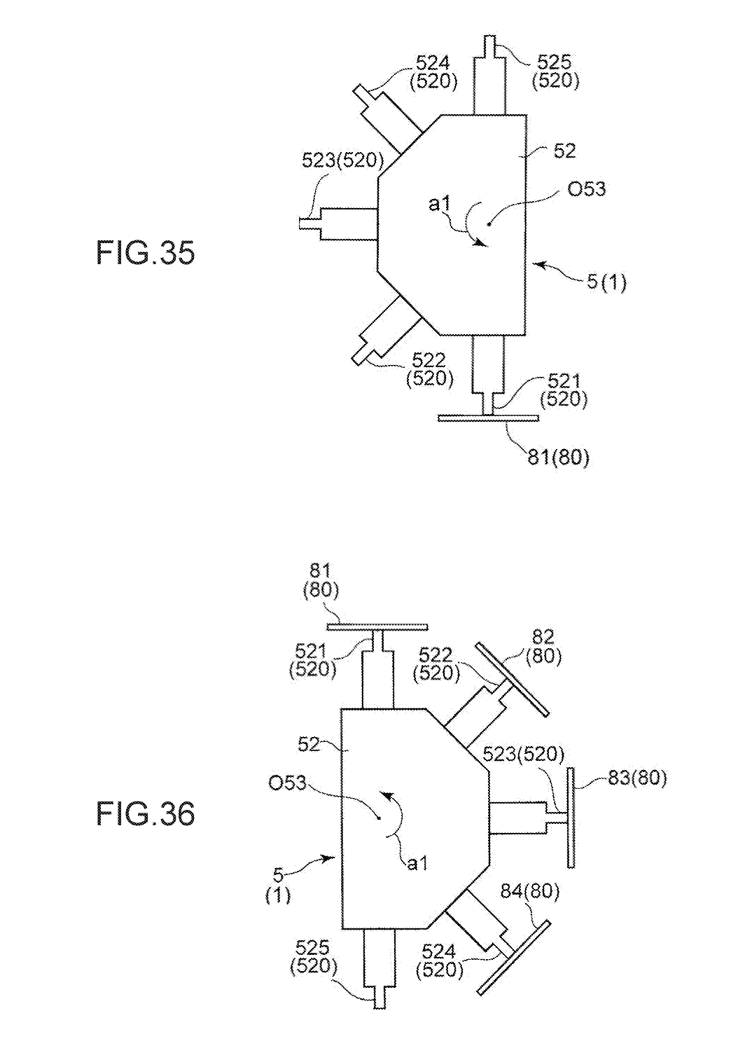

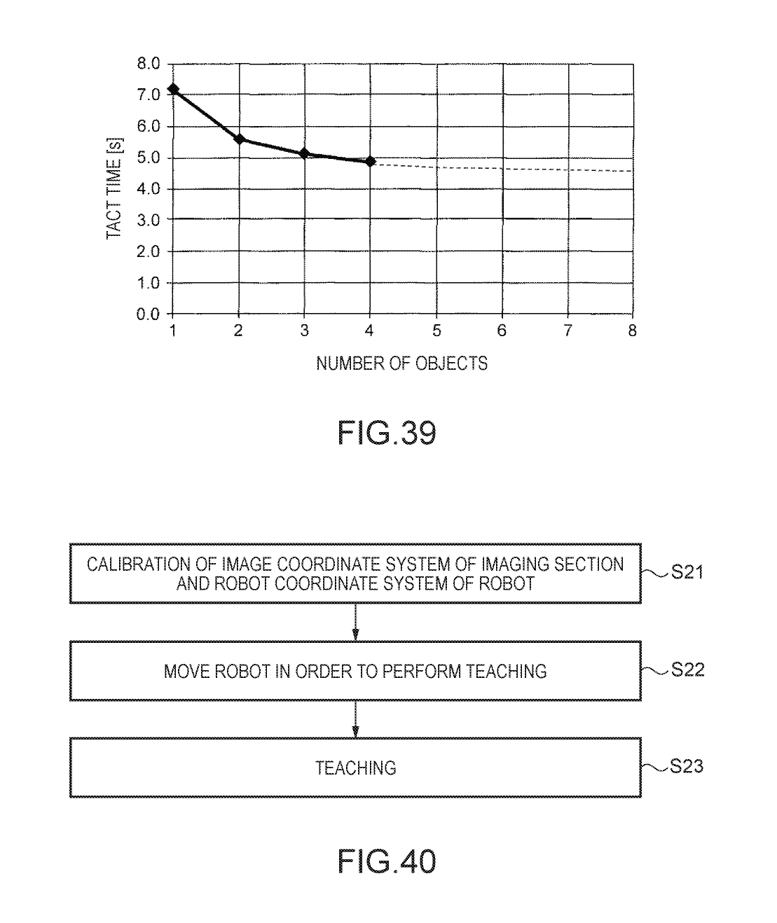

FIG. 33 is a flowchart for explaining an example of work of the robot shown in FIG. 12. FIG. 34 is a diagram for explaining an example of the work of the robot shown in FIG. 12. FIGS. 35 to 38 are respectively diagrams for explaining holding and release of an object by the end effector included in the robot shown in FIG. 12. FIG. 39 is a graph showing a relation between the number of objects conveyed by the robot shown in FIG. 12 and a tact time.

Note that, in the work explained below, it is assumed that calibration of the robot 1, calibration of the robot 1 and the imaging section 140, and calibration of the robot 1 and the imaging section for alignment 9 are finished. In the work explained below, it is assumed that teaching of the robot 1 concerning the operation of the robot 1 and the positions and the like of the supply section 20, the test sections 300, and the collecting sections 40 is finished.

As shown in FIG. 33, the robot 1 [1] performs holding of a plurality of objects in the supply section 20 (step S11), [2] performs conveyance of the plurality of objects to the test section group 30 (step S12), [3] performs holding and release of the plurality of objects in the test section group 30 (step S13), [4] performs conveyance of the plurality of objects to the collecting section 40 (step S14), and [5] performs release of the plurality of objects in the collecting section 40 (step S15). Thereafter, [6] the robot 1 returns to the supply section 20 (step S16).

The robot 1 performs a plurality of stages (units of work) including a series of work of [1] to [6]. In this embodiment, the robot 1 performs the series of work of [1] to [6] on each of the first test section group 31, the second test section group 32, the third test section group 33, and the fourth test section group 34. The series of work performed in the first test section group 31 is referred to as “first stage” as well. The series of work performed in the second test section group 32 is referred to as “second stage” as well. The series of work performed on the third test section group 33 is referred to as “third stage” as well. The series of work performed on the fourth test section group 34 is referred to as “fourth stage” as well. In the stages, holding, conveyance, and release of four objects are collectively performed.

The kinds of work performed in the first stage, the second stage, the third stage, and the fourth stage are the same except that the test section groups 30 set as targets are different. Therefore, the first stage is representatively explained bellow as an example.

### [1] Holding of the Plurality of Objects in the Supply Section 20 (Step S11)

First, the robot 1 drives the robot arm 10 to locate the distal end portion of the end effector 5 on the supply section 20 and holds four objects 80 from the placing member 25 of the supply section 20 (see FIGS. 12, 34, and 36). Specifically, as shown in FIG. 36, the four objects 80 are held by the end effector 5 included in the robot 1. The five holding sections 520 included in the end effector 5 shown in FIG. 36 are referred to as “first holding section 521”, “second holding section 522”, “third holding section 523”, “fourth holding section 524”, and “fifth holding section 525” as well clockwise in order from the holding section 520 located on the uppermost side in FIG. 36. The plurality of objects 80 shown in FIG. 36 are referred to as “first object 81”, “second object 82”, “third object 83”, and “fourth object 84” as well clockwise in order from the object 80 located on the uppermost side in FIG. 36.

The holding of the four objects 80 by the robot 1 is completed by repeating processing for sucking and holding one object 80 with one holding section 520 of the end effector 5. Specifically, first, as shown in FIG. 35, the robot 1 holds the first object 81 in the first holding section 521. Thereafter, the robot 1 turns the turning member 52 around the turning axis O53 of the turning member 52 (in this embodiment, in an arrow a1 direction) and holds the second object 82 in the second holding section 522. Similarly, the robot 1 turns the turning member 52 in the arrow a1 direction and, after holding the third object 83 in the third holding section 523, turns the turning member 52 in the arrow a1 direction, and holds the fourth object 84 in the fourth holding section 524. The robot 1 turns the turning member 52 in the arrow a1 direction and locates the fifth holding section 525 on the lowermost side. Consequently, as shown in FIG. 36, the objects 80 are respectively held by the four holding sections 520 excluding the fifth holding section 525. In this way, with the end effector 5 including the turning member 52 and the plurality of holding sections 520, it is possible to turn the turning member 52 and hold the plurality of objects 80. Since intervals among the holding sections 520 adjacent to one another are equal, it is possible to hold the objects 80 by turning the turning member 52 in the same direction by a fixed amount at a time. Therefore, control of the holding of the objects 80 is relatively easy.

### [2] Conveyance of the Plurality of Objects to the Test Section Group 30 (Step S12)

Subsequently, the robot 1 drives the robot arm 10 and moves the distal end portion of the end effector 5 along an arrow A11 to convey the four objects 80 from the supply section 20 to the first test section group 31 (see FIGS. 12, 34, and 36). The distal end portion of the end effector 5 is moved to the first test section 310 present in a position closest to the supply section 20.

In step S12, it is also possible to perform conveyance through the imaging section for alignment 9. Consequently, it is possible to grasp a held state of an object in the imaging section for alignment 9. Therefore, in step S13, it is possible to highly accurately perform placing of the object in the test section 300.

### [3] Holding and Release of the Plurality of Objects in the Test Section Group 30 (Step S13)

Subsequently, as shown in FIG. 34, the robot 1 performs holding and release of the objects 80 in the first test sections 310 of the first test section group 31. In this embodiment, after holding one object 80 before a test on one first test section 310, the robot 1 releases one object 80 after a test. It is assumed that tested objects 80 are placed on the first test sections 310. Note that, when the tested objects 80 are not placed on the test sections 300, holding of the objects 80 only has to be omitted. The first test sections 310 are referred to as “first test section 310a”, “first test section 310b”, “first test section 310c”, and “first test section 310d” as well toward the right side in order from the first test section 310 located on the leftmost side in FIG. 34.

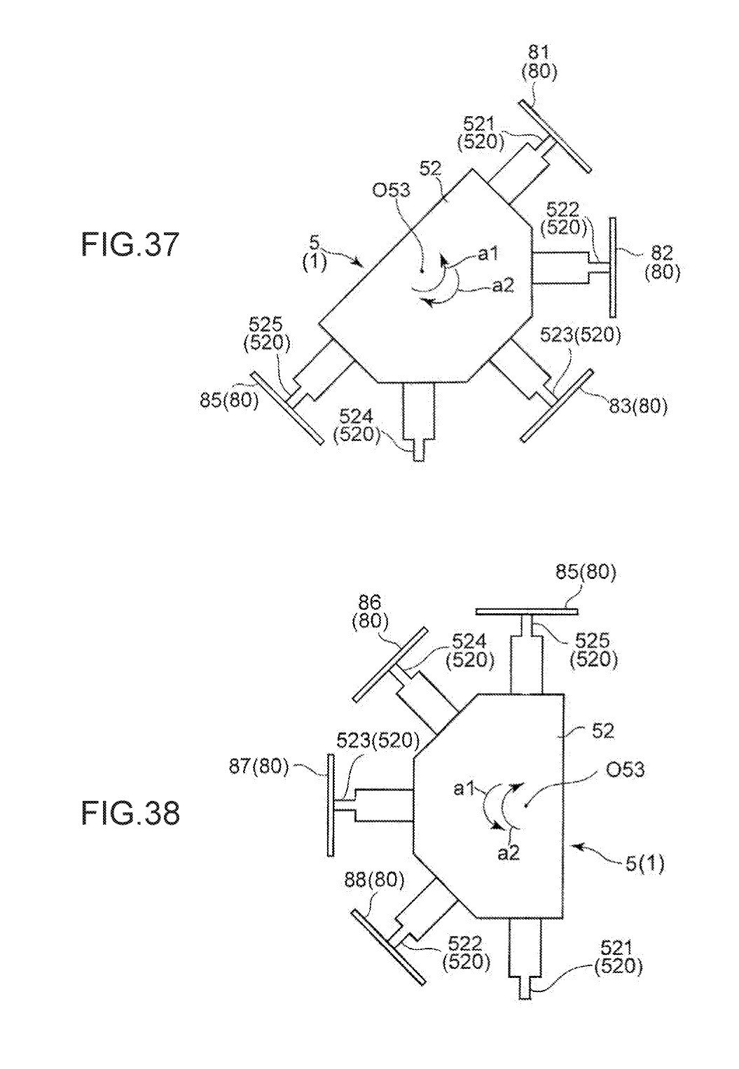

Specifically, first, in the first test section 310a, after holding a fifth object 85 (the object 80) placed on the first test section 310a with the fifth holding section 525, the robot 1 turns the turning member 52 around the turning axis O53 of the turning member 52 (in this embodiment, the arrow a2 direction opposite to the arrow a1 direction) and releases the fourth object 84 in the fourth holding section 524 (see FIGS. 12, 34, and 37). Consequently, as shown in FIG. 37, the object 80 is held by each of the four holding sections 520 excluding the fourth holding section 524.

Subsequently, the robot 1 drives the robot arm 10 and moves the distal end portion of the end effector 5 along an arrow A12 to locate the distal end portion of the end effector 5 in the first test section 310b (see FIGS. 12, 34, and 37). Thereafter, after holding a sixth object 86 (the object 80) placed on the first test section 310b with the fourth holding section 524, the robot 1 turns the turning member 52 in the arrow a2 direction and releases the third object 83 in the third holding section 523. Subsequently, similarly, as shown in FIG. 34, the robot 1 moves the distal end portion of the end effector 5 along an arrow A13 to locate the distal end portion of the end effector 5 in the first test section 310c. Thereafter, after holding a seventh object 87 (the object 80) placed on the first test section 310c with the third holding section 523, the robot 1 turns the turning member 52 in the arrow a2 direction and releases the second object 82 in the second holding section 522. Subsequently, similarly, as shown in FIG. 34, the robot 1 moves the distal end portion of the end effector 5 along an arrow A14 to locate the distal end portion of the end effector 5 in the first test section 310d. Thereafter, after holding an eighth object 88 (the object 80) placed on the first test section 310d with the second holding section 522, the robot 1 turns the turning member 52 in the arrow a2 direction and releases the first object 81 in the first holding section 521. Consequently, as shown in FIG. 38, the object 80 is held by each of the four holding sections 520 excluding the first holding section 521.

In step S11 explained above, the fifth holding section 525 (or the first holding section 521) located at the most distant end among the five holding sections 520 does not hold the object 80. As explained above, in the holding and the release of the objects 80 by the robot 1 in the first test section group 31 (step S13), the robot 1 turns the turning member 52 in the opposite direction of the turning direction of the turning member 52 in the holding of the objects 80 by the robot 1 in the supply section 20 (step S11). Consequently, it is possible to efficiently perform holding and release of the objects 80.

Note that, in this embodiment, the holding and the release of the objects 80 are performed in the order of the first test section 310a, the first test section 310b, the first test section 310c, and the first test section 310d. However, the order of the holding and the release is not limited to this order and may be any order. For example, the holding and the release of the objects 80 may be performed in the order of the first test section 310d, the first test section 310c, the first test section 310d, and the first test section 310a.

### [4] Conveyance of the Plurality of Objects to the Collecting Sections 40 (Step S14)

Subsequently, the robot 1 drives the robot arm 10 and moves the distal end portion of the end effector 5 along an arrow A15 to convey the four objects 80 (the fifth object 85, the sixth object 86, the seventh object 87, and the eighth object 88) from the first test section group 31 to the collection unit 4 (see FIGS. 12, 34, and 38).

### [5] Release of the Plurality of Objects in the Collecting Sections 40 (Step S15)

Subsequently, the robot 1 performs release of the object 80 in the collection unit 4. Specifically, the robot 1 places the objects 80 on the placing members 25 of the collecting sections 40 corresponding to the objects 80 on the basis of test results (a non-defective product, a defective product, or a retest) of the objects 80 sent from the test control device 73 to the robot control device 71. The robot 1 performs the placing of the objects 80 on the collecting sections 40 by releasing the objects 80 one by one in the holding sections 520 while turning the turning member 52 in the arrow a1 direction (see FIG. 38).

### [6] Return to the Supply Section 20 (Step S16)

When the release (the placing) of all the objects 80 in the collection unit 4 is completed, the robot 1 drives the robot arm 10 and moves the distal end portion of the end effector 5 along an arrow A16 to return to the supply section 20 from the collection unit 4 (see FIGS. 12 and 34).

According to the processing explained above, the first stage by the robot 1 is completed. In the first stage, a total of conveyance times by the robot 1 is a total t1 of times consumed for steps S12 and S14. In the first stage, a total of processing times by the robot 1 is a total T1 of times consumed for steps S11, S13, and S15. The total t1 of the times (the conveyance times) in the first stage and the total T1 of the times (the processing times) in the first stage are in a relation of t1<T1. When the first stage is completed, the robot 1 sequentially performs the second stage, the third stage, and the fourth stage in the same manner as the first stage. In the second, third, and fourth stages, the relation between the total t1 of the times and the total T1 of the times is the same. A total t2 of times (conveyance times) in the second stage and a total T2 of times (processing times) in the second stage are in a relation of t2<T2. A total t3 of times (conveyance times) in the third stage and a total T3 of times (processing times) in the third stage are in a relation of t3<T3. A time t4 of times (conveyance times) in the fourth stage and a total T4 of times (processing times) in the fourth stage are in a relation of t4<T4. When the fourth stage ends, the test work of the robot system 100 ends. Note that, after the fourth stage ends, it is also possible to repeat the first stage to the fourth stage a plurality of times. In the above explanation, the work is performed in the order of the first stage, the second stage, the third stage, and the fourth stage. However, the order may be any order. For example, the third stage may be performed after the first stage.

A total Σ_{t1 to t4} of the conveyance times of all the stages (the first to fourth stages) and a total Σ_{T1 to T4} of the processing times of all the stages (the first to fourth stages) are in a relation of Σ_{t1 to t4}<Σ_{T1 to T4}. A total (Σ_{t1 to t4})×m of conveyance times and a total (Σ_{T1 to T4})×m of processing times at the time when all the stages are repeated a plurality of times (m times: m is an integer equal to or larger than 1) are in a relation of (Σ_{t1 to t4})×m<(Σ_{T1 to T4})×m.

The example of the work of the robot 1 is explained above.

As explained above, with the robot 1, it is possible to collectively convey the plurality of objects 80. Therefore, it is possible to reduce a tact time.

When the objects 80 were conveyed one by one dividedly four times by the robot 1, that is, when the conveyance through the arrows A11 and A17 shown in FIG. 34 was performed four times, a tact time (Σ_{t1 to t4}+Σ_{T1 to T4}) of the conveyance was approximately 22.4 s. This is, for example, a result (a simulation result) at the time when the objects 80 having weight of 1.5 kg was conveyed by the robot 1. On the other hand, when the four objects 80 were collectively conveyed by the robot 1, that is, the conveyance through the arrows A11 to A15 shown in FIG. 34 was performed under the same conditions (the weight of the objects 80 and the speed and the acceleration of the robot 1), the tact time (Σ_{t1 to t4}+Σ_{T1 to T4}) of the conveyance was approximately 19.5 s. In this way, it is possible to greatly reduce the tact time by collectively conveying the plurality of objects 80 with the robot 1.

Times in steps S11 to S15 were actually measured. When the four objects 80 were, for example, collectively conveyed to the first test section group 31 by the robot 1, a tact time in step S11 was 2.84 s, a tact time in step S12 was 1.30 s, a tact time in step S13 was 5.87 s, a tact time in step S14 was 1.53 s, and a tact time in step S15 was 3.24 s. Therefore, when the four objects 80 were, for example, collectively conveyed to the first test section group 31 by the robot 1, that is, in the first stage, a conveyance time was 2.83 s and a processing time was 11.95 s. In the second stage, a conveyance time was 2.40 s and a processing time was 14.02 s.

On the other hand, when the objects 80 were, for example, conveyed one by one dividedly four times by the robot 1, that is, in the first stage, a conveyance time was 9.44 s and a processing time was 10.64 s. In the second stage, a conveyance time was 9.04 s and a processing time was 12.4 s.

In FIG. 39, a relation (a simulation result) between the number of objects 80 conveyed at a time and a tact time ((Σ_{t1 to tZ}+Σ_{T1 to TZ}: Z is an integer equal to or larger than 1) is shown. The horizontal axis of the graph indicates the number of objects 80 conveyed at a time and the vertical axis indicates a tact time [s] per one object 80. In this example, when the number of objects 80 conveyed at a time is two or more and four or less, the tact time [s] per one object 80 greatly decreases. In this example, when the number of objects 80 conveyed at a time is five or more, the decrease in the tact time per one object 80 is gentle.

The number of objects 80 conveyed at a time by the robot 1 only has to be plural from the viewpoint of reducing the tact time and is not particularly limited. However, the number of objects 80 conveyed at a time by the robot 1 is desirably two to eight, more desirably six or less, and particularly desirably five or less. In particular, in this embodiment, as explained above, the number of objects 80 conveyed at a time is set to four. Consequently, it is possible to, while particularly reducing the tact time, particularly reduce the size of the end effector 5 that holds the plurality of objects 80.

With the robot system 100, the total (Σ_{t1 to t4}) of the conveyance times of the robot 1 in the work including all the stages (the first to fourth stages) is shorter than the total (Σ_{T1 to T4}) of the processing times (holding and releasing times) in the work. In this way, since the total of the conveyance times is short, it is possible to reduce the tact time. Since the total of the processing times is long, it is possible to reduce holding mistakes and the like of the objects 80. As a result, it is possible to increase a throughput. Further, with the robot system 100, it is possible to set the total of the conveyance times of the robot 1 shorter than the total of the processing times in each of the first stage, the second stage, the third stage, and the fourth stage. Therefore, it is possible to more conspicuously exhibit the effects explained above.

The conveyance time is, for example, a time for conveyance between the supply section 20 and the test section group 30 by the robot 1 and a time for conveyance between the test section group 30 and the collecting section 40 by the robot 1. In this embodiment, a time consumed for step S12 and a time consumed for step S14 are equivalent to the conveyance time. The conveyance time includes a time for conveyance through any place (e.g., a place on the imaging section for alignment 9) in the conveyance of the objects 80. However, the conveyance time does not include times for the holding and the release of the object 80. More strictly, the conveyance time refers to a time for operation from a state in which the robot 1 starts to accelerate in one region (e.g., in any one of the supply section 20, the test section group 30, or the collecting section 40) to a state in which the robot 1 ends deceleration in another region different from the one region.

The processing time is, for example, a time for the holding of the object 80 in the supply section 20 by the robot 1, a time for the holding and the release of the object 80 in the test section group 30 by the robot 1, and a time for the release of the object 80 in the collecting section 40 by the robot 1. The processing time includes a time for the movement among the test sections 300 included in the test section group 30 of the robot 1. The processing time includes a time for the movement among the collecting sections 40 included in the collection unit 4 of the robot 1. That is, a time for the movement in one unit (the supply unit 2, the test unit 3, or the collection unit 4) is included in the processing time. In this embodiment, a time consumed for step S11, a time consumed for step S13, and a time consumed for step S15 are equivalent to the processing time. More strictly, the processing time refers to a time for operation from a state in which the robot 1 starts to perform operation for holding (or releasing) a first object in one unit to a state in which holding (or release) of a last object by the robot 1 is completed and the robot 1 is about to start conveyance to another unit. In this specification, the processing time means that a time for only holding by the robot 1 is included and a time for only release by the robot 1 is included.

As explained above, the robot system 100 includes the supply section 20 that supplies the object 80, the first test section group 31 including the plurality of first test sections 310 in which the supplied object 80 is tested, a second test section group 32 including the plurality of second test sections 320 in which the supplied object 80 is tested, the collecting section 40 that collects the tested object 80, and a robot 1 that includes the robot arm 10 and performs holding, conveyance, and release of the object 80. The robot 1 is capable of collectively conveying the plurality of objects 80. From the supply to the collection of the object 80, the total of the conveyance times for the conveyance of the object 80 by the robot is shorter than the total of the processing times for the holding or the release of the object 80 by the robot 1.

With the robot system 100 explained above, since the robot 1 can collectively convey the plurality of objects 80, it is possible to convey the plurality of objects 80 to the first test section group 31 or the second test section group 32 all together at a time. Since the robot system 100 includes the plurality of first test sections 310 and the plurality of second test sections 320, it is possible to test the plurality of objects 80 with one robot system 100. Further, since the total of the conveyance times by the robot 1 is shorter than the total of the processing times (the times of holding and release: the material supply and removal times), it is possible to convey a larger number of the objects 80 to the first test sections 310 or the second test sections 320 in a shorter time while reducing occurrence of, for example, holding mistakes of the objects 80. Consequently, with the robot system 100, it is possible to test a larger number of objects 80 in a shorter time. Therefore, it is possible to further increase a throughput (the number of tests of objects that can be processed per unit time) than in the past.

The total of the conveyance times is desirably one third or less of the total of the processing times and more desirably one fourth or less of the processing times. Consequently, it is possible to test a larger number of the objects 80 in the first test sections 310 and the second test sections 320 in a shorter time while reducing occurrence of, for example, holding mistakes of the objects 80.

Further, in this embodiment, the robot system 100 includes the third test section group 33 including the plurality of third test sections 330 in which the supplied object 80 is tested and a fourth test section group 34 including the plurality of fourth test sections 340 in which the supplied object 80 is tested. Therefore, it is possible to test a larger number of the objects 80 with one robot system 100.

In general, an IC test handler that tests a single IC (integrated circuit) includes one test section and collectively tests a plurality of ICs in the one test section. On the other hand, in general, in a test of a circuit board on which an IC and the like are mounted, one circuit board is tested in one test section. Therefore, since the robot system 100 includes the plurality of test sections 300, it is possible to particularly conspicuously exhibit the effects explained above when a test of a circuit board or the like (e.g., an SiP) on which an IC and the like are mounted is performed. That is, it is possible to particularly conspicuously exhibit the effects explained above when one object 80 is tested in one test section 300.

When the robot system 100 includes two or more “robots”, a total of conveyance times by the robots is shorter than a total of processing times by the robots. A time obtained by adding up totals of the conveyance times of the robots is shorter than a time obtained by adding up totals of the processing times of the robots. Consequently, it is possible to further increase the throughput.

At least one of the holding and the release of the object 80 by the robot 1 is performed in each of the supply section 20, the first test section group 31, the second test section group 32, and the collecting section 40. By increasing the processing times in such places, it is possible to appropriately hold and release the object 80 while reducing likelihood of, for example, breakage and holding mistakes of the objects 80.

The conveyance of the object 80 by the robot 1 is performed in each of the sections between the supply section 20 and the first test section group 31, between the first test section group 31 and the collecting section 40, between the supply section 20 and the second test section group 32, and between the second test section group 32 and the collecting section 40. By reducing the conveyance times in such sections, it is possible to further reduce the total of the conveyance times and further increase the throughput.

Further, in this embodiment, the conveyance of the object 80 by the robot 1 is performed in each of the sections between the supply section 20 and the third test section group 33, between the third test section group 33 and the collecting section 40, between the supply section 20 and the fourth test section group 34, and between the fourth test section group 34 and the collecting section 40. Consequently, it is possible to further reduce the total of the conveyance times and further increase the throughput.

As explained above, the work for the object 80 by the robot 1 includes the first stage including at least one of the holding and the release of the object 80 in the supply section 20, the first test section group 31, and the collecting section 40 and the conveyance of the object 80 between the supply section 20 and the first test section group 31 and between the first test section group 31 and the collecting section 40 and the second stage including at least one of the holding and the release of the object 80 in the supply section 20, the second test section group 32, and the collecting section 40 and the conveyance of the object 80 between the supply section 20 and the second test section group 32 and between the second test section group 32 and the collecting section 40. In the first stage, the total of the conveyance times of the object 80 by the robot 1 is shorter than the total of the processing times of the object 80 by the robot 1. In the second stage, the total of the conveyance times of the object 80 by the robot 1 is shorter than the total of the processing times of the object 80 by the robot 1. In this way, in both of the first stage and the second stage, since the total of the conveyance times is shorter than the total of the processing times, it is possible to further increase the throughput.

More specifically, the robot 1 performs the first work (step S11 of the first stage) for holding the plurality of objects 80 from the supply section 20 with the robot arm 10, the second work (step S12 of the first stage) for conveying the plurality of objects 80 from the supply section 20 to the first test section group 31 with the robot arm 10 after the first work, the third work (step S13 of the first stage) for performing the work for releasing the plurality of objects 80 and the work for holding the plurality of objects 80 with the robot arm 10 in the first test section group 31 after the second work, the fourth work (step S14 of the first stage) for conveying the plurality of objects 80 from the first test section group 31 to the collecting section 40 with the robot arm 10 after the third work, and the fifth work (step S15 of the first stage) for releasing the plurality of objects 80 in the collecting section 40 with the robot arm 10 after the fourth work. The robot 1 performs the sixth work (step S11 of the second stage) for holding the plurality of objects 80 from the supply section 20 with the robot arm 10 after the fifth work, the seventh work (step S12 of the second stage) for conveying the plurality of objects 80 from the supply section 20 to the second test section group 32 with the robot arm 10 after the sixth work, the eighth work (step S13 of the second stage) for performing the work for releasing the plurality of objects 80 and the work for holding the plurality of objects 80 with the robot arm 10 in the second test section group 32 after the seventh work, the ninth work (step S14 of the second stage) for conveying the plurality of objects 80 from the second test section group 32 to the collecting section 40 with the robot arm 10 after the eighth work, and the tenth work (step S15 of the second stage) for releasing the plurality of objects 80 in the collecting section 40 with the robot arm 10 after the ninth work. The total of the second time serving as the conveyance time for the second work and the fourth time serving as the conveyance time for the fourth work is shorter than the total of the first time serving as the processing time for the first work, the third time serving as the processing time for the third work, and the fifth time serving as the processing time for the fifth work. Further, the total of the seventh time serving as the conveyance time for the seventh work and the ninth time serving as the conveyance time for the ninth work is shorter than the total of the sixth time serving as the processing time for the sixth work, the eighth time serving as the processing time for the eighth work, and the tenth time serving as the processing time for the tenth work. Consequently, it is possible to test a larger number of the objects 80 in a shorter time in the first test sections 310 and the second test sections 320 while reducing occurrence of, for example, holding mistakes of the objects 80. Therefore, it is possible to further increase the throughput.

Further, in this embodiment, in the third stage, the total of the conveyance times of the object 80 by the robot 1 is shorter than the total of the processing times of the object 80 by the robot 1. In the fourth stage, the total of the conveyance times of the object 80 by the robot 1 is shorter than the total of the processing times of the object 80 by the robot 1. Consequently, it is possible to further increase the throughput.

As explained above, the robot arm 10 includes the coupled at least two arms (e.g., the first arm 11 and the second arm 12). From the supply to the collection, the robot 1 desirably performs the conveyance of the object 80 in the state in which the at least two arms (e.g., the first arm 11 and the second arm 12) cross. Consequently, it is possible to reduce vibration of the robot arm 10 at the time of the conveyance of the object 80. Therefore, it is possible to further increase the speed and the acceleration of the robot 1 at the time when the object 80 is moved. Therefore, it is possible to further increase the throughput. It is possible to more quickly start the holding and the release of the object 80 after the conveyance.

The influence of the vibration is larger when the robot arm 10 is moved in a state in which the robot arm 10 is stretched than when the robot arm 10 is moved in a state in which the robot arm 10 is bent. The vibration is caused by forces applied to the arms 11 to 16. Therefore, when the robot arm 10 is operated in the stretched state, since the center of gravity position of the robot 1 is far from the rotation center of the first turning axis O1, acceleration in the center of gravity position increases. Since a force (F) is in a relation of force (F)=mass(m)×acceleration(a), when the acceleration in the center of gravity position increases, a force applied to the robot arm 10 increases. Therefore, amplitude (a vibration amount) increases. Since the distance to the distal end of the robot arm 10 is larger when the robot arm 10 is stretched, even when an amplitude amount of the root of the robot arm 10 (a connecting portion to the base 110) is the same in the stretched state and the bent stage of the robot arm 10, the vibration amount at the distal end of the robot arm 10 is more greatly displaced in the stretched state of the robot arm 10 in which the position of the distal end of the robot arm 10 is far from the root. Therefore, it is desirable to convey the object 80 in the state in which at least two arms cross.

In the work of the robot 1 explained above, the holding and the release of the object 80 by the robot 1 are performed in all of the four test sections 300 included in the test section group 30. However, the holding and the release of the object 80 may be performed on only any test section 300 among all the test sections 300. Therefore, the robot 1 is also capable of performing the holding or the release of the object 80 on the selected first test section 310 among the plurality of first test sections 310 included in the first test section group 31 and performing the holding and the release of the object 80 on the selected second test section 320 among the plurality of test sections 320 included in the second test section group 32. Consequently, the robot 1 can, for example, skip the first test section 310 or the second test section 320 under maintenance and perform the holding or the release of the object 80 on the remaining first test sections 310 or second test sections 320. Therefore, since it is unnecessary to stop, for example, all kinds of work (the holding, the conveyance, and the release) by the robot 1 during the maintenance, it is possible to reduce a standby time of the robot 1. As a result, it is possible to reduce a decrease in the throughput. Note that the work of the robot 1 is performed under the control by the robot control device 71.

When maintenance or the like is performed in any one of the first test sections 310, the robot control device 71 can also control the robot 1 to skip the first stage and perform the second stage, the third stage, and the fourth stage. That is, the robot control device 71 may select, for each of the test sections 300, whether the robot 1 performs work and may select, for each of the test section groups 30 whether the robot 1 performs work. For example, the robot control device 71 may control the robot 1 to perform work at any time from the test section 300 or the test section group 30 for which maintenance is completed.

### 4. Auto-Teaching

Auto-teaching by the robot control device 71 is explained.

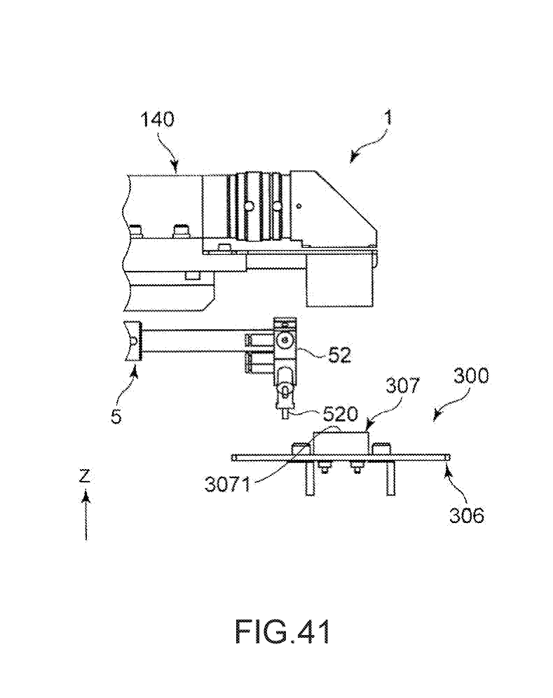

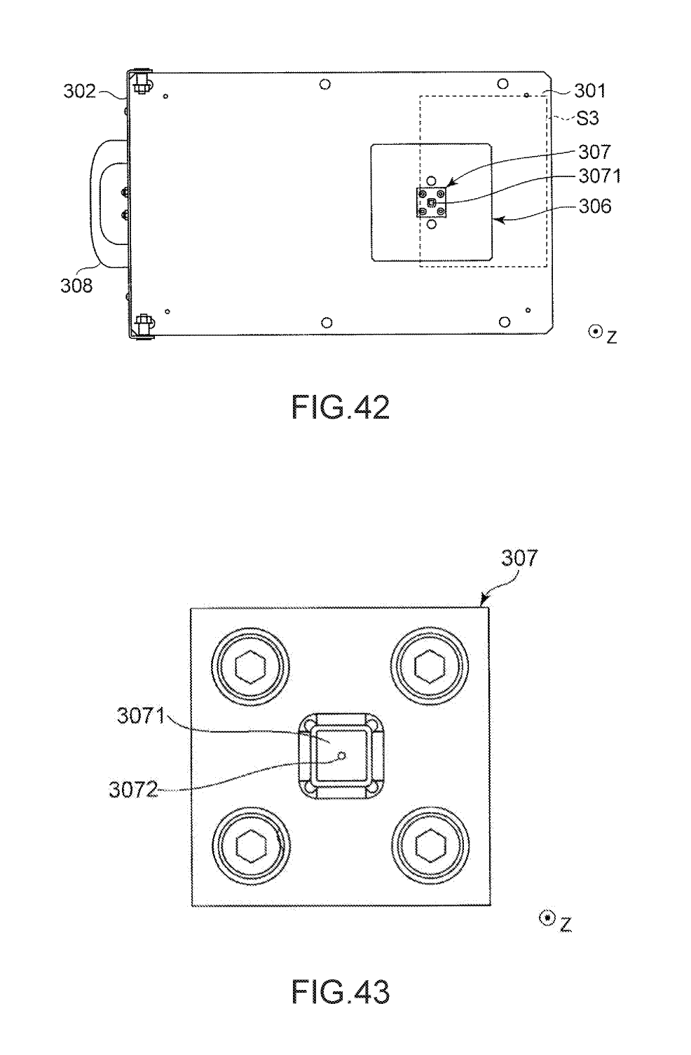

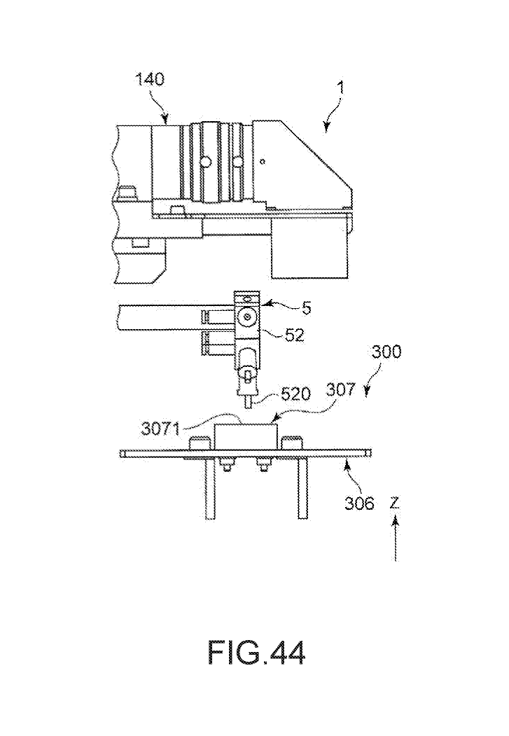

FIG. 40 is a flowchart for explaining an example of auto-teaching of a socket to the robot shown in FIG. 12. FIG. 41 is a diagram showing the distal end portion of the robot for explaining the auto-teaching of the socket to the robot shown in FIG. 12. FIG. 42 is a diagram showing a test table for explaining the auto-teaching of the socket to the robot shown in FIG. 12. FIG. 43 is a diagram showing a reference mark provided in the socket shown in FIG. 42. FIG. 44 is a diagram showing the distal end portion of the robot for explaining the auto-teaching of the socket to the robot shown in FIG. 12. FIG. 45 is a diagram showing the distance between the holding section of the end effector and the object on the test table for explaining the auto-teaching of the socket to the robot shown in FIG. 12.

An example of the auto-teaching is explained below. In the following explanation, for example, teaching of a socket 307 of the test section 300 to the robot 1 is explained as an example (see FIG. 42).

As shown in FIG. 40, the robot control device 71 [1] performs calibration of an image coordinate system of the imaging section 140 and a robot coordinate system of the robot 1 (step S21), [2] moves the robot 1 in order to perform teaching (step S22), and [3] performs the teaching (step S23).

### [1] Calibration of the Image Coordinate System of the Imaging Section 140 and the Robot Coordinate System of the Robot 1 (Step S21)

First, the robot control device 71 causes the imaging section 140 to image any mark (not shown in the figure) provided in, for example, a calibration board (not shown in the figure) and causes the robot 1 to touch the mark with the distal end of the holding section 520. Consequently, the robot control device 71 calculates an offset amount of the holding section 520 with respect to the distal end of the robot arm 10. Note that a contact place is not limited to the holding section 520. Subsequently, the robot control device 71 performs so-called nine-point calibration and performs association, that is, calibration with the robot coordinate system of the robot 1. Consequently, it is possible to convert a coordinate (a robot coordinate) in the robot control system of the robot 1 into a coordinate (an image coordinate) in the image coordinate system of the imaging section 140.

Note that step S21 is desirably performed when, for example, replacement of the end effector 5 is performed and may be omitted as appropriate.

### [2] Movement of the Robot 1 for Teaching the Socket 307 (Step S22)

Subsequently, the robot control device 71 moves the robot 1 in order to teach the socket 307 to the robot 1.

Specifically, first, the robot control device 71 moves, on the basis of a coordinate in design of the socket 307 (more strictly, a coordinate in design of the concave section 3071), the end effector 5 of the robot 1 to a position where the socket 307 can be imaged by the imaging section 140 (see FIG. 41). Alternatively, the robot control device 71 finds the position of the socket 307 by, while causing the imaging section 140 to image the test table 301, driving the robot 1 such that the distal end of the end effector 5 moves into a certain determined region S3 (see FIGS. 41 and 42). Consequently, the robot control device 71 determines positions in the X-axis direction and the Y-axis direction of the socket 307. Subsequently, the robot control device 71 searches for a position focused by autofocus of the imaging section 140. Consequently, the robot control device 71 determines a position in the Z-axis direction of the socket 307.

### [3] Teaching (Step S23)

Subsequently, the robot control device 71 performs teaching in the X-axis direction and the Y-axis direction and performs teaching in the Z-axis direction.

In the teaching in the X-axis direction and the Y-axis direction, the robot control device 71 uses the imaging section 140. Specifically, the robot control device 71 images, with the imaging section 140, a reference mark 3072 of the concave section 3071 prepared in the socket 307 and stores a robot coordinate (x, y) of the X axis and the Y axis in the position of the reference mark 3072 (see FIGS. 43 and 44). Note that the reference mark 3072 may be present in any place of the concave section 3071. However, the reference mark 3072 is desirably provided in the center of the bottom surface of the concave section 3071 as shown in FIG. 43. Alternatively, the reference mark 3072 is desirably provided at, for example, a corner of the bottom surface of the concave section 3071. Consequently, it is possible to more highly accurately calculate a teaching point for more accurately performing holding and release of the object 80.

In the teaching in the Z-axis direction, the robot control device 71 uses the detecting section 150 provided in the negative-pressure generating device 130 (see FIG. 23). The object 80 is placed in advance in the concave section 3071 of the socket 307 (see FIG. 45).

Specifically, first, as shown in FIG. 44, the robot control device 71 drives the robot 1 such that the holding section 520 of the end effector 5 is located on the center of the concave section 3071 of the socket 307. Subsequently, the robot control device 71 actuates the negative-pressure generating device 130 to change the inside of the pipe 50 to a negative pressure state and brings the distal end of the holding section 520 close to the object 80 in the concave section 3071, for example, by 0.01 to 0.05 mm at a time. The robot control device 71 stores a point at the time when a detection result (a pressure value) from the detecting section 150 is smaller than a threshold. The robot control device 71 sets this point as an upper limit value of height (a position in the Z-axis direction) at which suction of the object 80 by the holding section 520 is possible.

Subsequently, the robot control device 71 actuates the negative-pressure generating device 130 to change the inside of the pipe 50 to a positive pressure state and further brings the distal end of the holding section 520 close to the object 80 in the concave section 3071 by, for example, 0.01 to 0.05 mm at a time. The robot control device 71 stores a point where a detection result (a pressure value) from the detecting section 150 exceeds the threshold. The robot control device 71 sets this point as a lower limit of the height at which suction of the object 80 by the holding section 520.

Subsequently, as shown in FIG. 45, the robot control device 71 determines a range d20 of the height at which suction of the object 80 by the holding section 520 is possible. The robot control device 71 stores a robot coordinate (z) of the Z axis, for example, at intermediate height of the range d20.

The robot control device 71 stores, as a teaching point in the concave section 3071 of the socket 307, a robot coordinate (x, y, z) calculated in this way.

Note that, in this embodiment, the teaching is performed in a state in which the object 80 is placed on the concave section 3071. However, for example, the teaching may be performed with respect to the bottom surface of the concave section 3071 without placing the object 80 on the concave section 3071. In that case, a coordinate calculated by adding thickness in design of the object 80 to the calculated robot coordinate only has to be used as a teaching point.

In this embodiment, the pressure sensor is used in the detecting section 150. However, when a flow rate sensor is used in the detecting section 150, the upper limit value and the lower limit value of the height may be calculated by detecting a flow rate per unit time of gas in the pipe 50 detected by the detecting section 150. The height may be calculated by detecting, for example, contact of the holding section 520 of the end effector 5 and the object 80 using the force detecting section 120.

The auto-teaching is explained above.

As explained above, the robot 1 includes the end effector 5 functioning as the “member” connected to the robot arm 10 and including the holding sections 520 functioning as the plurality of “suction sections” that holds the object 80 with suction, the pipes 50 functioning as the “channel sections” connected to the holding sections 520, which functions as the “suction sections”, and including channels (the insides of the pipes 50) in which gas flows, the detecting section 150 that detects pressure or a flow rate per unit time of the gas in the pipes 50 functioning as the “channel sections”, and the imaging section 140 having the imaging function (see FIG. 23). The robot 1 calculates a teaching point in holding and release of the object 80 by the robot 1 on the basis of a detection result (image data) from the imaging section 140 and a detection result (a pressure value) from the detecting section 150. With such a method, it is possible to highly accurately calculate the teaching point. Therefore, since the robot 1 performs the holding and the release of the object 80 using the teaching point, it is possible to reduce or prevent, for example, holding mistakes of the objects 80. Therefore, it is possible to accurately perform the holding and the release of the object 80 by the robot 1.

When the test table 301 included in the test section 300 is put in or taken out from the housing 6 in maintenance for a model change, daily inspection, cleaning, or the like of the test section 300, the position of the socket 307 is likely to deviate. Therefore, in this embodiment, it is desirable that, for example, after the test table 301 is returned to the inside of the housing 6, teaching (auto-teaching) to the socket 307 of the robot 1 is automatically performed as explained above under the control by the robot control device 71. Consequently, it is possible to save labor and time of the user for manually performing positioning (teaching) of the socket 307 according to, for example, a model change of the test section 300. Therefore, since the model change can be efficiently performed, with the robot system 100, it is possible to suitable cope with multiproduct variable quantity production. Note that the same holds true in the supply section 20 and the collecting section 40.

For example, by using the imaging section 140 and the detecting section 150, it is possible to detect, for example, positional deviation of the placing member 25 placed on the supply section 20 or the collecting section 40, floating of the placing member 25 from the supply section 20 or the collecting section 40, and a warp of the placing member 25. These can be calculated in the same manner as step S23 of the auto-teaching explained above. For example, the robot control device 71 calculates positions (robot coordinates: x, y) of eight corner sections 257 of the placing member 25 using the imaging section 140, calculates a deviation amount from a position (a robot coordinate: x, y) in design of the placing member 25 as a correction value on the basis of the calculated positions, and stores the correction value (see FIG. 7). Note that, even if the robot control device 71 does not calculate the positions of the eight corner sections 257, the robot control device 71 may calculate a correction value using four corner sections 257 located in corners of the placing member 25. For example, the robot control device 71 calculates heights (robot coordinates: x, y) of the eight corner sections 257 of the placing member 25 using the detecting section 150, calculates a deviation amount from height (a robot coordinate: x, y) in design of the placing member 25 as a correction value on the basis of the calculated height, and stores the correction value.

By driving the robot 1 taking into account the correction value, it is possible to more highly accurately perform the work of the robot 1 in the supply section 20 and the collecting section 40.

For example, when foreign matters such as dust enter the concave section 3071 of the socket 307, a conduction failure is sometimes caused in a test. In such a case, the negative-pressure generating device 130 is actuated to change the inside of the pipe 50 to a positive pressure state to blow out gas (specifically, compressed air) from the through-hole 5201 of the holding section 520. Consequently, it is possible to remove the foreign matters from the concave section 3071 of the socket 307. That is, it is possible to perform auto-cleaning of the holding section 520 and the socket 307. Although not shown in the figures, for example, it is desirable to provide, in the robot system 100, a button for the operator to instruct the robot control device 71 to start the auto-cleaning. Consequently, the operator can execute the auto-cleaning at any timing by operating the button. The auto-cleaning is desirably performed, for example, when a failure occurs a plurality of times in the same test content. Note that a pad (not shown in the figures) exclusive for the auto-cleaning other than the holding section 520 may be provided in the end effector 5.

### Second Embodiment

A second embodiment of the invention is explained.

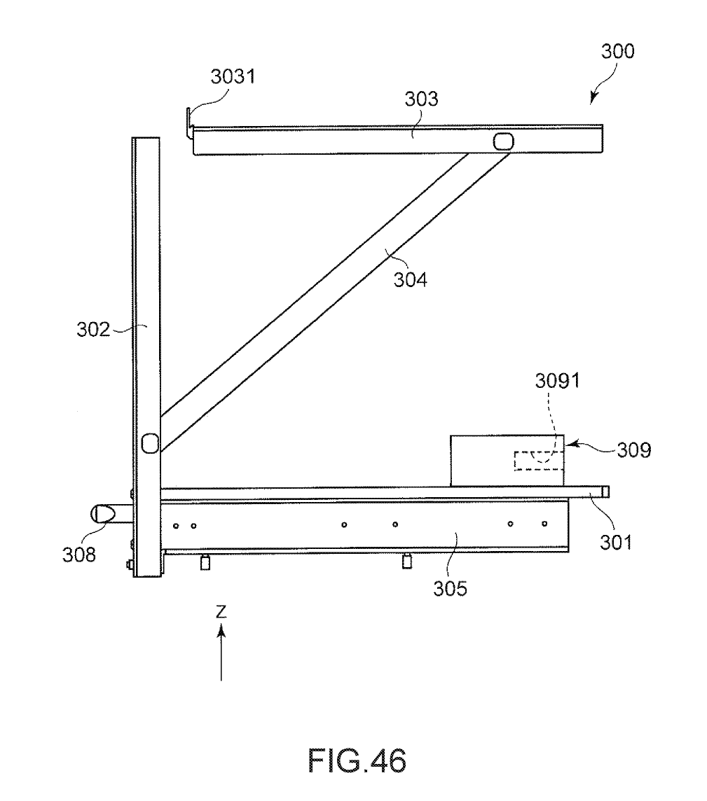

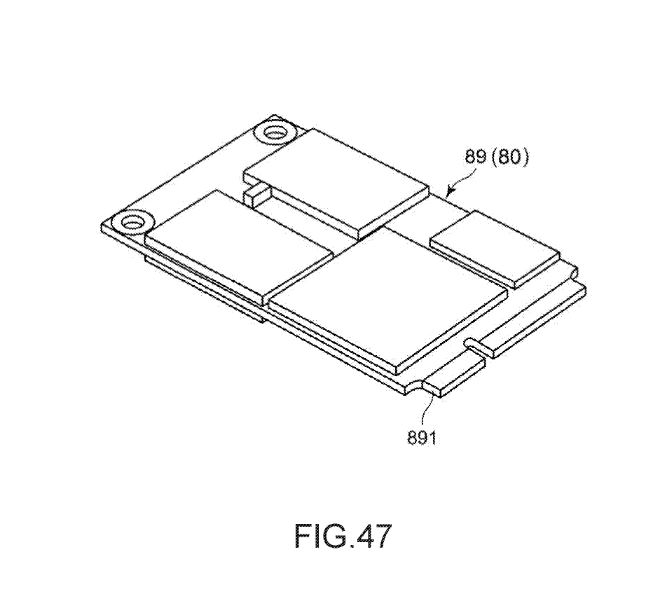

FIG. 46 is a side view showing a test section included in a robot system according to the second embodiment of the invention. FIG. 47 is a diagram showing an example of an object tested in the test section shown in FIG. 46.

The robot system according to this embodiment is the same as the robot system in the first embodiment except that the configuration of the test section is different. Note that, in the following explanation, concerning the second embodiment, differences from the first embodiment are mainly explained. Explanation of similarities is omitted.

The test section 300 in this embodiment includes, as shown in FIG. 46, a socket 309 including a concave section 3091 functioning as an insertion section into which the object 80 can be inserted. The concave section 3091 is opened to the right side in FIG. 46. The socket 309 is formed in, for example, a flat shape and is suitable for a test of an object, a test target portion of which is present in an outer peripheral portion. Examples of the objects include an object 89 that is configured by an SSD (solid state drive) or the like and in which a connector 891 provided in an outer peripheral portion is a test target as shown in FIG. 47.

When the robot 1, for example, conveys the object 89, the robot 1 only has to use, as an “end effector”, a hand (not shown in the figure) including a plurality of fingers and grip the outer peripheral portion of the object 89 with the plurality of fingers. When the connector 891 of the object 89 is inserted into and pulled out from the concave section 3091 by the robot 1, it is desirable to insert the connector 891 into the concave section 3091 and pull out the connector 891 from the concave section 3091 on the basis of a detection result from the force detecting section 120. Consequently, it is possible to more appropriately perform the insertion and the pull-out of the connector 891.

### Third Embodiment

A third embodiment of the invention is explained.

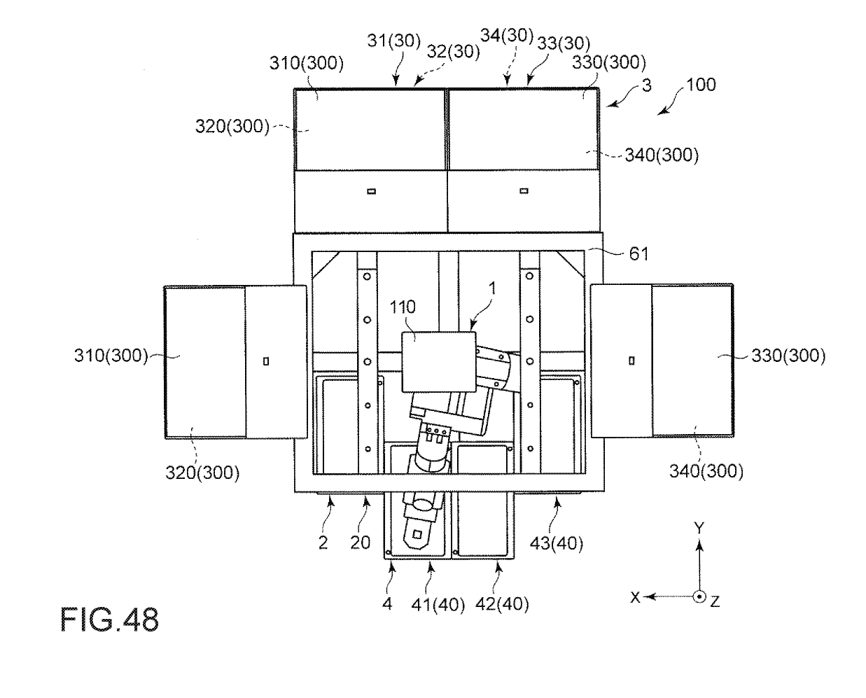

FIG. 48 is a schematic diagram of the inside of a robot system according to the third embodiment of the invention viewed from the upper side.

The robot system according to this embodiment is the same as the robot systems in the embodiments explained above except that the configuration of a test section is different. Note that, in the following explanation, concerning the third embodiment, differences from the embodiments explained above are mainly explained. Explanation of similarities is omitted.

The test unit 3 in this embodiment includes eight test sections 300. Specifically, the first test section group 31 includes two first test sections 310 (test sections 300), the second test section group 32 includes two second test sections 320 (test sections 300), the third test section group 33 includes two third test sections 330 (test sections 300), and the fourth test section group 34 includes two fourth test sections 340 (test sections 300).

In this embodiment, a series of work performed in the first test section group 31 and the third test section group 33 is referred to as “first stage” and a series of work performed in the second test section group 32 and the fourth test section group 34 is referred to as “second stage”. Therefore, in this embodiment, release of a plurality of objects is performed in the collecting section 40, for example, after the plurality of objects are held in the supply section 20, after the plurality of objects are conveyed to the two first test sections 310 and the two third test sections 330 and held and released. Similarly, release of the plurality of objects is performed in the collecting section 40, for example, after the plurality of objects are held in the supply section 20, after the plurality of objects are conveyed to the two second test sections 320 and the two fourth test sections 340. Note that, in this embodiment, as in the embodiments explained above, when an object is not placed on the test section 300 in advance, holding of the object does not have to be performed in the test section 300. In this way, it is also possible to perform work on two or more test section groups 30 in one stage.

### Fourth Embodiment

A fourth embodiment of the invention is explained.

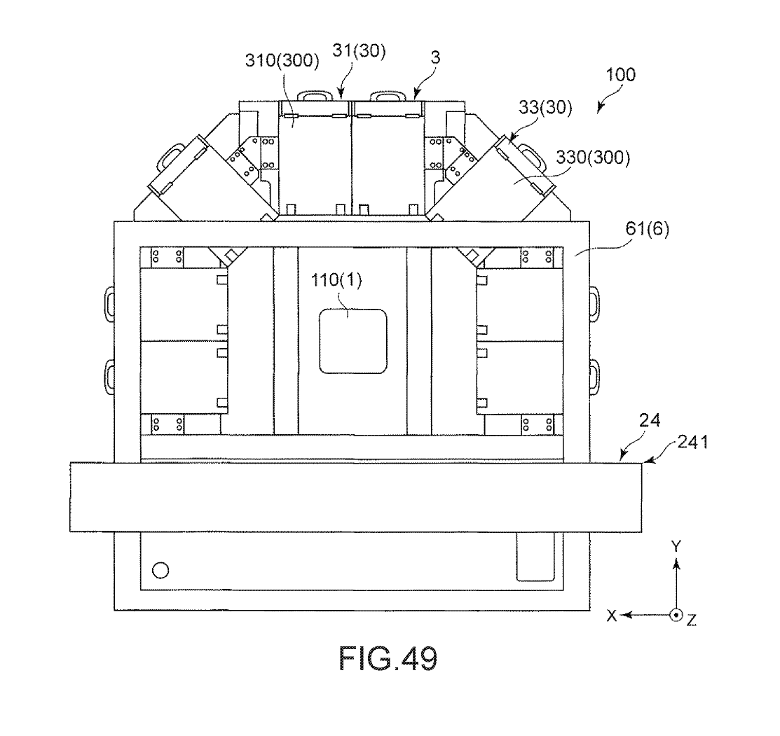

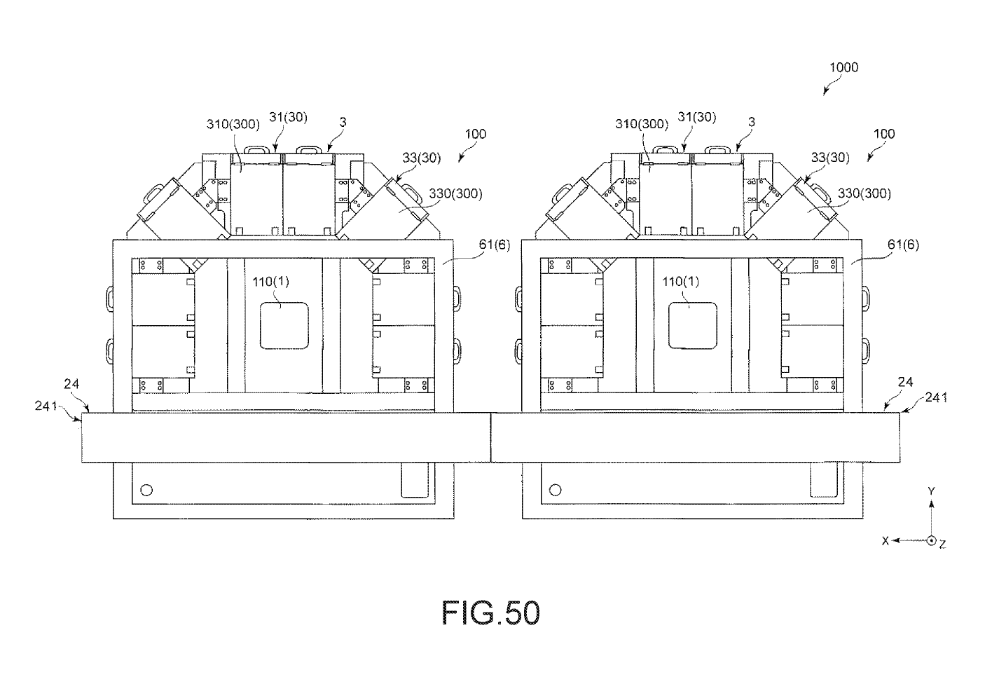

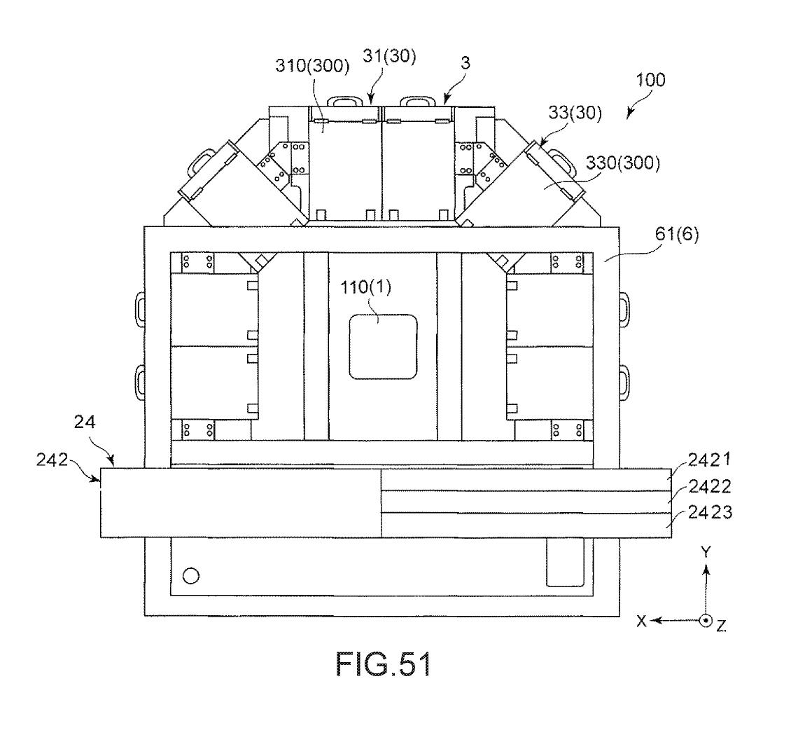

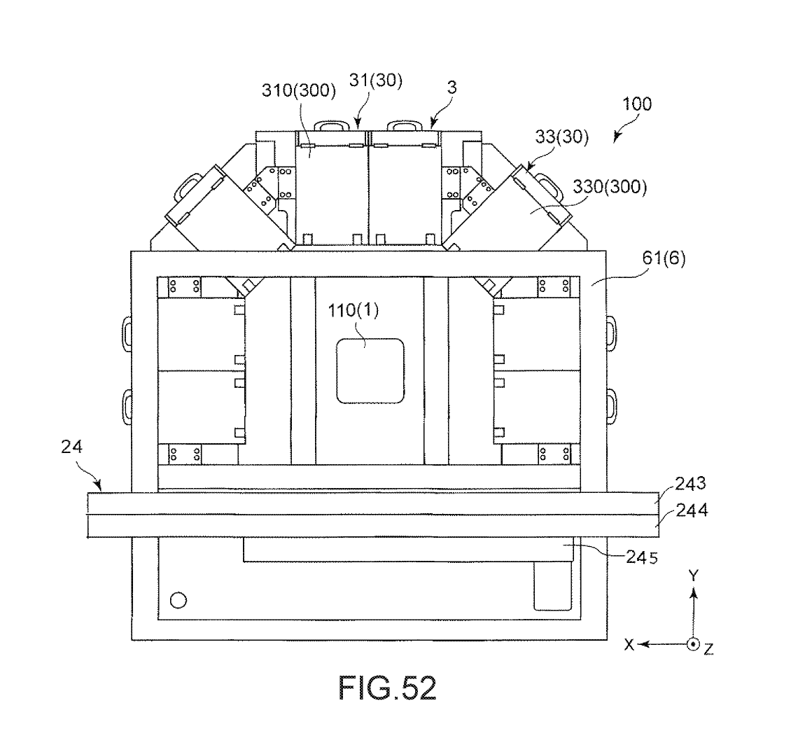

FIG. 49 is a schematic diagram of the inside of a robot system according to the fourth embodiment of the invention viewed from the upper side. FIG. 50 is a diagram showing a robot system unit including a plurality of the robot systems shown in FIG. 49. FIGS. 51 and 52 are respectively schematic diagrams showing modifications of a supply and collection unit shown in FIG. 49. Note that, in FIGS. 49 to 52, illustration of the cover member 62 is omitted.

The robot system according to this embodiment is the same as the robot systems in the embodiments explained above. Note that, in the following explanation, concerning the fourth embodiment, differences from the embodiments explained above are mainly explained. Explanation of similarities is omitted.

As shown in FIG. 49, the robot system 100 in this embodiment includes a supply and collection unit 24 including a conveyor 241 having functions of a supply section and a collecting section.

In this embodiment, the conveyor 241 is provided on the outside of the housing 6. Note that a part or the entire conveyor 241 may be provided on the inside of the housing 6. A conveying direction of the conveyor 241 is the −X-axis direction. The conveyor 241 can convey an object in the −X-axis direction (from the left to the right in FIG. 49). Note that the conveying direction of the conveyor 241 may be the +X-axis direction. The conveyor 241 may convey an object in the +X-axis direction (from the right to the left in FIG. 49). The configuration of the conveyor 241 is not particularly limited as long as the conveyor 241 is capable of conveying an object. The conveyor 241 may be any conveyor such as a so-called belt conveyor or roller conveyor.

A region on the +X-axis side of the conveyor 241 functions as the supply section. A region on the −X-axis side of the conveyor 241 functions as the collecting section. Therefore, after holding an object in the region on the +X-axis side of the conveyor 241, the robot 1 conveys the held object to the test section 300. The robot 1 places (releases) the object, for which a test is completed, on the region on the −X-axis side of the conveyor 241.

Since the robot system 100 includes the supply and collection unit 24 having such a configuration, it is possible to save labor and time of an operator for supplying an object to the robot system 100 and collecting the object. It is possible to automate all kinds of work.

A robot system unit 1000 including a plurality of robot systems 100 is shown in FIG. 50. The plurality of robot systems 100 are provided side by side in the X-axis direction. The belt conveyors 241 included in the robot systems 100 are coupled. Consequently, for example, by performing tests of different contents in the robot systems 100, it is possible to realize the robot system unit 1000 that can perform a variety of tests.

The supply and collection unit 24 can also be configured, for example, as shown in FIGS. 51 and 52.

The supply and collection unit 24 shown in FIG. 51 includes a conveyor 242. In the conveyor 242, a region on the −X-axis side functioning as the collecting section is divided into three regions 2421, 2422, and 2423. The region 2421 functions as a collecting section for non-defective products on which an object determined as being a non-defective product in the test section 300 is placed. The region 2422 functions as a collecting section for defective products on which an object determined as being a defective product in the test section 300 is placed. The region 2423 functions as a collecting section for retests on which an object determined to be retested in the test section 300 is placed. By dividing, according to test results, the region on the −X-axis side functioning as the collecting section in this way, it is possible to save labor and time for classifying objects for each of the test results.

The supply and collection unit 24 shown in FIG. 52 includes the three conveyors 243, 244, and 245.

The conveyor 243 has a function of a supply section and a function of a collecting section for non-defective products. The +X-axis side of the conveyor 243 functions as the supply section and the −X-axis side of the conveyor 243 functions as the collecting section for non-defective products. The conveyor 244 functions as a collecting section for defective products. The conveyor 244 is configured to be capable of conveying an object in the +X-axis direction in addition to the −X-axis direction. The conveyor 244 changes a conveying direction according to content of post-processing after a test of the object. For example, when a placed object is analyzed or discarded, the conveyor 244 is driven to convey the object in the −X-axis direction. For example, when a placed object is returned to the preceding process, the conveyor 244 is driven to convey the object in the +X-axis direction.

The conveyor 245 has a function of a collecting section for retests. Since the conveyor 245 does not have a function of a supply section, as shown in FIG. 52, the length in a conveying direction of the conveyor 245 is shorter than the length in the conveying direction of the conveyor 243 having the function of the supply section. In this way, the supply and collection unit 24 shown in FIG. 52 includes the conveyor 243 having the functions of the supply section and the collecting section for non-defective products, the conveyor 244 having the function of the collecting section for defective products, and the conveyor 245 having the function of the collecting section for retests. Consequently, it is possible to efficiently perform supply and collection and post-processing of objects.

Note that, in FIG. 52, the conveyor 243, the conveyor 244, and the conveyor 245 are provided side by side along the Y-axis direction (the horizontal direction) in this order from the +Y-axis side. However, the arrangement order of the conveyors 243, 244, and 245 is not limited to this and may be any order.

### Fifth Embodiment

A fifth embodiment of the invention is explained.

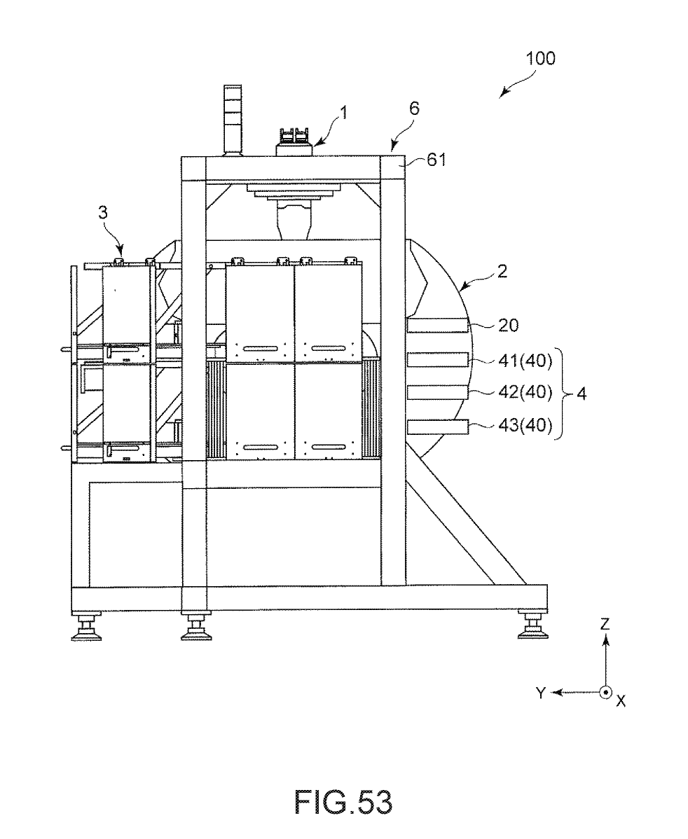

FIG. 53 is a left side view of a robot system according to the fifth embodiment of the invention. Note that, in FIG. 53, illustration of a cover member is omitted.

The robot system according to this embodiment is the same as the robot systems in the embodiments explained above except that the configurations of a supply section and a collecting section are different. Note that, in the following explanation, concerning the fifth embodiment, differences from the embodiments explained above are mainly explained. Explanation of similarities is omitted.

As shown in FIG. 53, the supply unit 2 and the collection unit 4 are disposed side by side along the Z-axis direction (the vertical direction). In this embodiment, the collection unit 4 is located below the supply unit 2. The collecting section for non-defective products 41 (the collecting section 40), the collecting section for defective products 42 (the collecting section 40), and the collecting section for retests 43 (the collecting section 40) included in the collection unit 4 are provided side by side along the Z-axis direction in this order from the +Z-axis side. Since the robot system 100 includes the supply unit 2 and the collection unit 4 having such configurations, it is possible to reduce the length in the X-axis direction of the robot system 100 compared with when the supply section 20 and the collecting sections 40 are provided side by side along the X-axis direction.

Although not shown in the figure, the supply unit 2 and the collection unit 4 in this embodiment can be configured to include, for example, a shelf including four column plates disposed side by side in the Z-axis direction. The column plate located at the top can be caused to function as the supply section 20. The column plate located second from the top can be caused to function as the collecting section for non-defective products 41. The column plate located third from the top can be caused to function as the collecting section for defective products 42. The column plate located at the bottom can be caused to function as the collecting section for retests 43. For example, the supply unit 2 and the collection unit 4 can be respectively configured by conveyors, conveying directions of which are the X-axis direction.

### Sixth Embodiment

A sixth embodiment of the invention is explained.

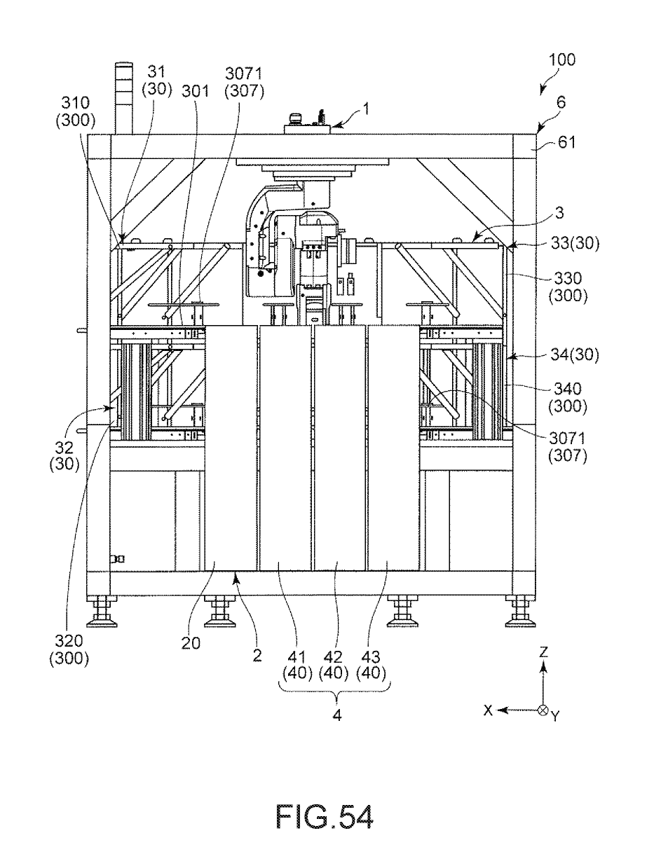

FIG. 54 is a front view of a robot system according to the sixth embodiment of the invention. Note that, in FIG. 54, illustration of a cover member is omitted.

As shown in FIG. 54, the robot system 100 according to this embodiment is the same as the robot systems in the embodiments explained above except that the configurations of a supply section and a collecting section are different. Note that, in the following explanation, concerning the sixth embodiment, differences from the embodiments explained above are mainly explained. Explanation of similarities is omitted.

As shown in FIG. 54, the supply section 20 and the three collecting sections 40 are respectively configured by so-called tray loaders (conveying devices). Although not shown in the figure, the tray loader is a device on which a plurality of trays, which are placing members on which a plurality of objects can be placed, are stacked and placed along the Z-axis direction and is a device capable of moving a desired tray along the Y-axis direction and locating the desired tray within a movable range of the robot 1. The tray loader is controlled by, for example, the peripheral-apparatus control device 72.

Since the robot system 100 includes the supply section 20 and the three collecting sections 40 having such configurations, it is possible to place pluralities of objects on the supply section 20 and the three collecting sections 40. Therefore, it is possible to effectively use the supply section 20 and the three collecting sections 40 as storing sections in which objects are stored. Since the robot system 100 includes the supply section 20 and the three collecting sections 40 having such configurations, it is possible to save labor and time of an operator for supplying objects to the robot system 100 and collecting the objects. It is possible to automate all kinds of work.

Note that the supply section 20 and the three collecting sections 40 may be configured by one tray loader. The supply section 20 and the three collecting sections 40 may be divided for each of the trays.

### Seventh Embodiment

A seventh embodiment of the invention is explained.

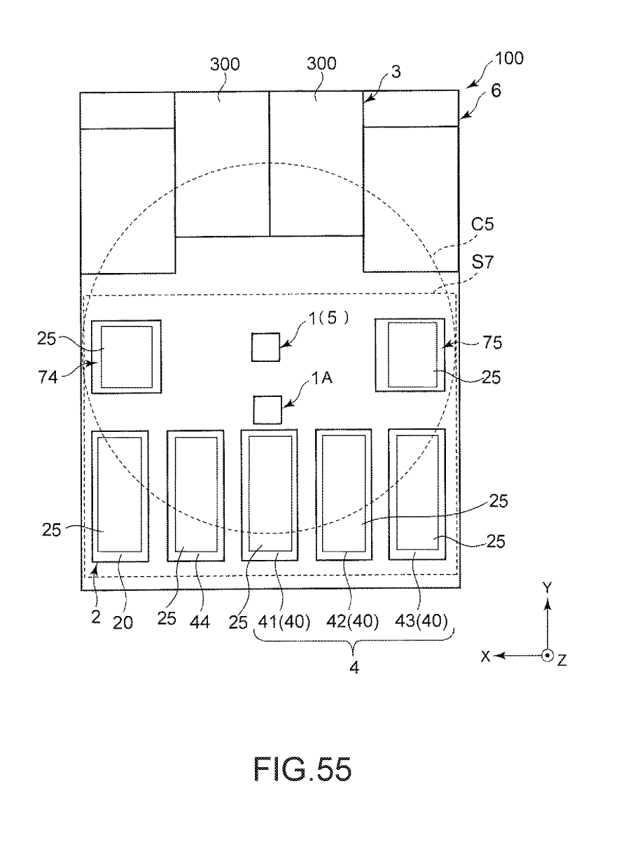

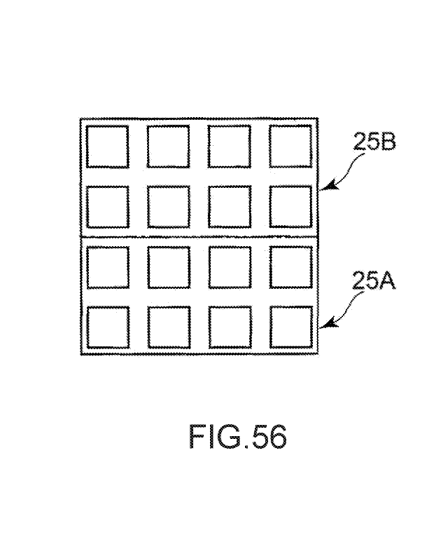

FIG. 55 is a schematic diagram of a robot system according to the seventh embodiment of the invention viewed from an upper side. FIG. 56 is a diagram showing an example of a placing member provided on a placing table included in the robot system shown in FIG. 55.

The robot system according to this embodiment is the same as the robot systems in the embodiments explained above except that the robot system mainly includes an empty-placing-member collecting section, two placing tables, and two robots. Note that, in the following explanation, concerning the seventh embodiment, differences from the embodiments explained above are mainly explained.

As shown in FIG. 55, the robot system 100 according to this embodiment includes an empty-placing-member collecting section 44, two placing tables 74 and 75, the robot 1 having the configuration shown in FIG. 12 explained in the first embodiment, and a robot 1A different from the robot 1.

The empty-placing-member collecting section 44 that collects an empty placing member 25, on which an object is not placed, is provided between the supply unit 2 and the collection unit 4. Although not shown in the figure, the empty-placing-member collecting section 44, the supply unit 2, and the collection unit 4 are coupled. The placing member 25 is configured to be capable of automatically moving among the empty-placing-member collecting section 44, the supply unit 2, and the collection unit 4. Consequently, for example, when all objects disappear from the placing member 25 of the supply section 20, the placing member 25 of the supply section 20 can be moved to the empty-placing-member collecting section 44. When the placing member 25 of the collecting section 40 is removed, the placing member 25 in the empty-placing-member collecting section 44 can be moved to the collecting section 40. Besides, when the placing member 25 of the collecting section 40 is fully loaded, the placing member 25 in the empty-placing-member collecting section 44 can be moved to the collecting section 40 to be stacked on the fully-loaded placing member 25.

The robot 1A is provided in the floor section of the robot system 100. The robot 1A or a apart (e.g., an end effector) that performs work on an object of the robot 1A is capable of moving along the X axis, the Y axis, and the Z axis. A part that performs work on the object of the robot 1A is capable of accessing the supply section 20, the empty-placing-member collecting section 44, the collecting sections 40, and the placing tables 74 and 75. A movable range of the part that performs work on the object of the robot 1A is within a region S7 shown in FIG. 55. On the other hand, a movable range of the end effector 5 included in the robot 1 is within the imaginary surface C5. In this embodiment, conveyance of objects to, griping the objects in, and release of the objects from the test sections 300 are performed by the robot 1. Conveyance of objects to, gripping of the objects in, and release of the objects from the supply section 20 and the collecting section 40 are performed by the robot 1A. By sharing kinds of work on the objects between the robot 1 and the robot 1A, it is possible to reduce moving distances of the end effector 5 of the robot 1 and the part that performs work on the object of the robot 1A. Therefore, it is possible to further increase the tact time.

By placing the robot 1A on a floor and suspending the robot 1 from a ceiling, it is possible to reduce interference of the robot 1A and the robot 1 during work.

The placing tables 74 and 75 are provided between the supply unit 2 and the test unit 3 and between the collection unit 4 and the test unit 3. More specifically, the placing table 74 is located between the supply unit 2 and the test unit 3. The placing table 75 is located between the collection unit 4 and the test unit 3. The placing tables 74 and 75 can be used as places for delivering objects between the robot 1A and the robot 1. For example, the robot 1A holds an object in the supply section 20, conveys the object to the placing table 74, and places the object on the placing table 74. On the other hand, the robot 1 holds an object on the placing table 74, conveys the object to the test section 300, and places the object on the test section 300. The robot 1 holds an object in the test section 300, conveys the object to the placing table 75, and places the object on the placing table 75. On the other hand, the robot 1A holds an object on the placing table 75, conveys the object to the collecting section 40, and places the object on the collecting section 40. In this way, by using the placing tables 74 and 75, it is possible to efficiently perform delivery of the object between the robot 1 and the robot 1A. The robot 1 and the robot 1A can share work for the object. For example, the robot 1 holds the object on the placing table 74, conveys the object to the test section 300, and, after holding and releasing the object, conveys the object to the placing table 75, and places the object on the placing table 75. Thereafter, the robot 1 may return to the placing table 74. However, the robot 1 can hold the object on the placing table 75, convey the object to the test section 300, and, after holding and releasing the object, convey the object to the placing table 74, and place the object on the placing table 74. Consequently, it is possible to further reduce the tact time.

The placing member 25 placed on the placing table 74 desirably has a small warp or the like and is highly accurately positioned. Consequently, even if grasping of a held state of the object by the imaging section for alignment 9 is omitted after the robot 1 holds the object, it is possible to highly accurately perform the placement of the object on the test section 300. Note that, since a tested object is placed on the placing member 25 placed on the placing table 75, positioning accuracy of the placing member 25 maybe lower than positioning accuracy of the placing member 25 placed on the placing table 74.

Note that, in this embodiment, the robot system 100 includes the placing tables 74 and 75. However, the robot system 100 may include one “placing table”. In that case, as shown in FIG. 56, a placing member 25A and a placing member 25B more highly accurately positioned than the placing member 25A are desirably provided in the placing table.

### Eighth Embodiment

An eighth embodiment of the invention is explained.

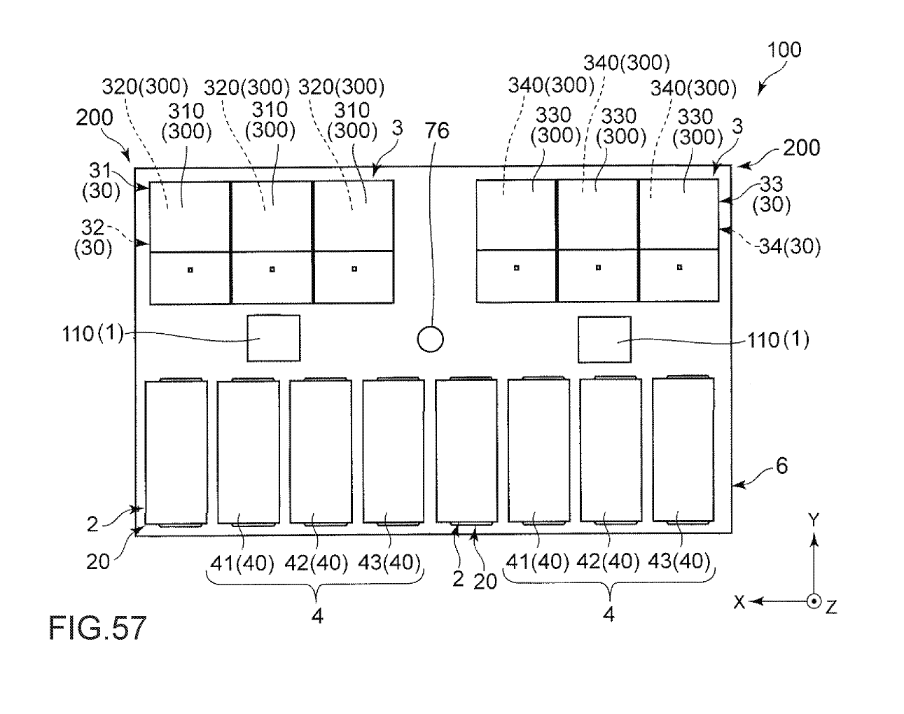

FIG. 57 is a schematic diagram of a robot system according to the eighth embodiment of the invention viewed from the upper side.

The robot system according to this embodiment is the same as the robot systems in the embodiments explained above except that the robot system mainly includes two each of supply units, test units, collection units, and robots. Note that, in the following explanation, concerning the eighth embodiment, differences from the embodiments explained above are mainly explained.

As shown in FIG. 57, the robot system 100 according to this embodiment includes two supply units 2, two test units 3, two collection units 4, and two robots 1. That is, the robot system 100 includes two unit groups 200 each including one supply unit 2, one test unit 3, one collection unit 4, and one robot 1. With such a configuration, for example, by performing tests of different contents in the unit groups 200, it is possible to realize the robot system 100 that can perform a variety of tests.

Various “end effectors” can be prepared between the two robots 1. A tool changer 76 that can replace the end effectors can be disposed. Consequently, the robots 1 can attach an end effector corresponding to test content with the tool changer 76.

### Ninth Embodiment

A ninth embodiment of the invention is explained.

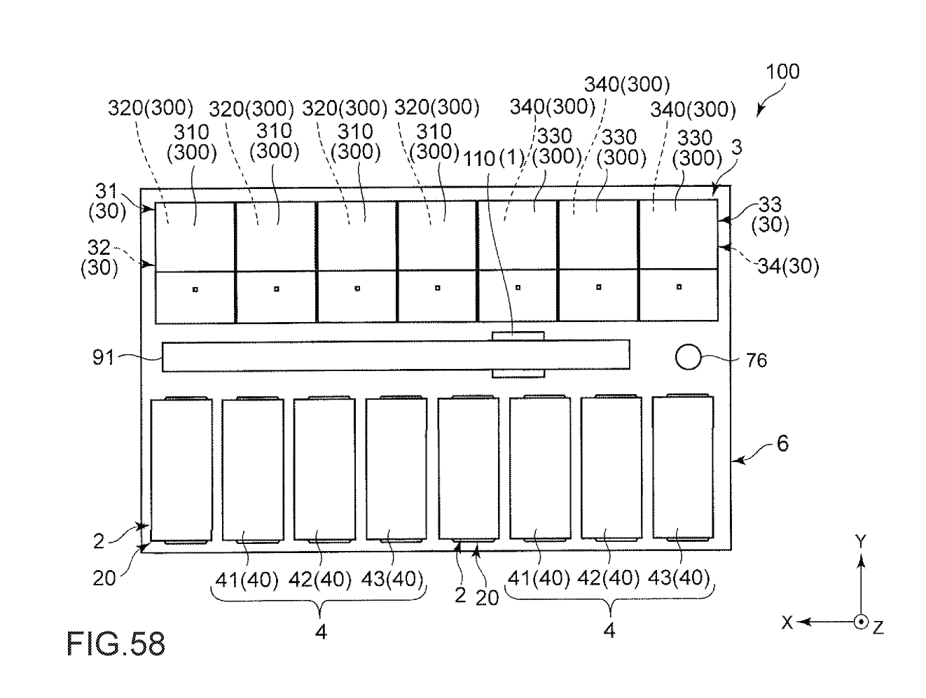

FIG. 58 is a schematic diagram of a robot system according to the ninth embodiment of the invention viewed from the upper side.

The robot system according to this embodiment is the same as the robot system in the eighth embodiment explained above except that the robot system mainly includes a moving mechanism and that two supply units and two collection units are provided. Note that, in the following explanation, concerning the ninth embodiment, differences from the eighth embodiment are mainly explained.

The robot system 100 shown in FIG. 58 includes two supply units 2 and two collection units 4. Consequently, for example, by supplying different kinds of objects to the two supply sections 20, it is possible to realize the robot system 100 that can perform tests of two kinds of objects.

The robot 1 is provided in a moving mechanism 91. The moving mechanism 91 has a function of supporting the robot 1 to be capable of reciprocating along the X-axis direction. Although not shown in the figure, the moving mechanism 91 includes, for example, an attaching section for attaching the base 110, a traveling shaft that causes the attaching section to reciprocate along the X-axis direction, and a driving source that drives the traveling shaft. The driving source is controlled by, for example, the peripheral-apparatus control device 72.

Since the robot 1 can move along the X-axis direction with the moving mechanism 91, the robot 1 can perform work in a plurality of test sections 300, a plurality of supply sections 20, and a plurality of collecting sections 40 provided over a wide range along the horizontal direction.

For example, the tool changer 76 can be disposed in the outer circumferential portion in the housing 6. Consequently, the robot 1 can cope with various kinds of objects.

### Tenth Embodiment

A tenth embodiment of the invention is explained.

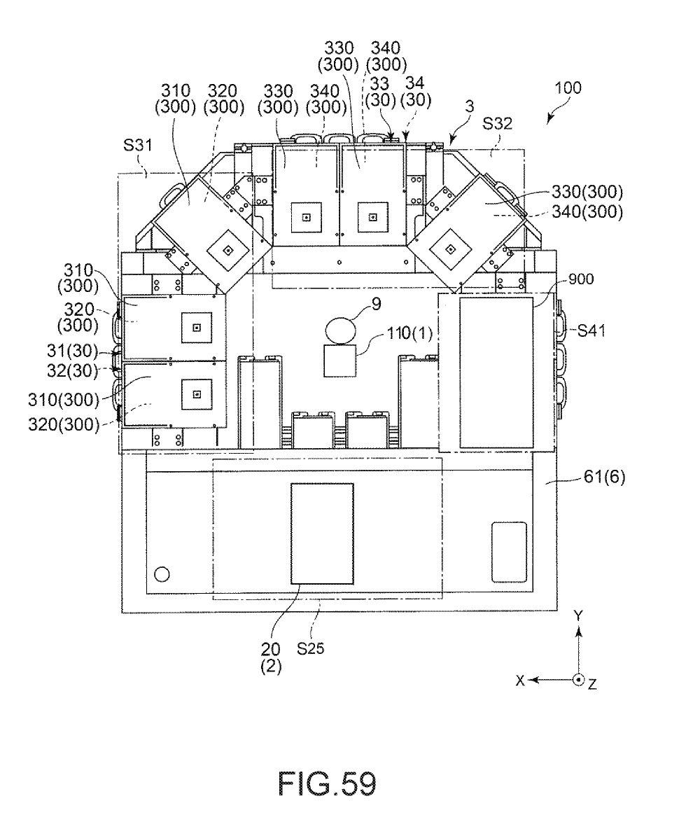

FIG. 59 is a schematic diagram of a robot system according to the tenth embodiment of the invention viewed from the upper side. Note that, in FIG. 59, illustration of a cover member is omitted.

The robot system according to this embodiment is the same as the robot systems in the embodiments explained above except that the robot system mainly includes a post-process region. Note that, in the following explanation, concerning the tenth embodiment, differences from the embodiments explained above are mainly explained.

The robot system 100 shown in FIG. 59 includes a work unit 900 capable of performing a post-process of a tested object. The work unit 900 can perform, as the post-process, for example, assembly (including, for example, packaging on a substrate and soldering), packaging, and packing of objects by the robot 1.

The robot system 100 is divided into a supply area S25 where the supply unit 2 is disposed, a first test area S31 where the first test section group 31 and the second test section group 32 are disposed, a second test area S32 where the third test section group 33 and the fourth test section group 34 are disposed, and a work area S41 where the work unit 900 is disposed.

In the robot system 100, the robot 1 holds an object from the supply area S25, conveys the object to the first test area S31, and places the object in the first test area S31. In the first test area S31, the robot 1 performs, for example, conduction test of the object. The robot 1 holds the tested object from the first test area S31, conveys the tested object to the work area S41, and places the tested object in the work area S41. In the work area S41, the robot 1 performs, for example, packing of an object determined as being a non-defective product. The robot 1 holds, for example, the packed object from the work area S41, conveys, for example, the packed object to the second test area S32, and places, for example, the packed object in the second test area S32. In the second test area S32, the robot 1 performs, for example, an exterior test of, for example, the packed object. The robot 1 holds, for example, the packed object from the second test area S32, conveys, for example, the packed object to the work area S41, and places, for example, the packed object in the work area S41. An operator collects, for example, the packed object from the work area S41. Therefore, the work unit 900 provided in the work area S41 functions as a collection unit as well.

In this way, it is possible to perform the test, the post-process of the test, and the test after the post-process with one robot system 100.

For example, in the first test area S31, the robot system 100 may perform a conduction test or the like of an object (e.g., an IC), package the object (e.g., the IC) on a substrate, solder the object (e.g., the IC), and manufacture a module substrate in the work unit 900. In the second test area S32, the robot system 100 may perform a conduction test or the like of the module substrate.

The robot systems in the embodiments of the invention are explained above with reference to the drawings. However, the invention is not limited to the robot systems. The components of the sections can be replaced with any components having the same functions. Any other components maybe added. The invention may be an invention obtained by combining any two or more components (features) among the embodiments.

In the embodiments, the number of turning axes of the robot arm included in the robot is six. However, the invention is not limited to this. The number of turning axes of the robot arm may be, for example, two, three, four, five, or seven or more. In the embodiments, the number of arms included in the robot is six. However, the invention is not limited to this. The number of arms included in the robot may be, for example, two, three, four, five, or seven or more.

In the embodiments, the number of robot arms included in the robot is one. However, the invention is not limited to this. The number of robot arms included in the robot may be, for example, two or more. That is, the robot may be, for example, a plural-arm robot such as a double-arm robot.

The entire disclosure of Japanese Patent Application No. 2016-214723, filed Nov. 1, 2016 is expressly incorporated by reference herein.

What is claimed is:

1. A robot system comprising:
a supply section configured to supply an object;
a first test section group including a plurality of first test sections configured to test the supplied object;
a second test section group including a plurality of second test sections configured to test the supplied object;
a collecting section configured to collect the tested object; and
a robot including a robot arm and configured to hold, convey, and release the object, wherein
the robot is capable of collectively conveying a plurality of the objects, and
a total of conveyance times for the conveyance of the object by the robot from the supply to the collection of the object is shorter than a total of processing times for the holding and the release of the object by the robot.

2. The robot system according to claim 1, wherein at least one of the holding and the release of the object by the robot is performed in each of the supply section, the first test section group, the second test section group, and the collecting section.

3. The robot system according to claim 1, wherein the conveyance of the object by the robot is performed in each of sections between the supply section and the first test section group, between the first test section group and the collecting section, between the supply section and the second test section group, and between the second test section group and the collecting section.

4. The robot system according to claim 1, wherein
the work on the object by the robot includes
a first stage including at least one of the holding and the release of the object in the supply section, the first test section group, and the collecting section and the conveyance of the object between the supply section and the first test section group and between the first test section group and the collecting section, and
a second stage including at least one of the holding and the release of the object in the supply section, the second test section group, and the collecting section and the conveyance of the object between the supply section and the second test section group and between the second test section group and the collecting section,
in the first stage, a total of conveyance times of the object by the robot is shorter than a total of processing times of the object by the robot, and
in the second stage, a total of conveyance times of the object by the robot is shorter than a total of processing times of the object by the robot.

5. The robot system according to claim 1, wherein the robot performs
first work for holding the plurality of objects from the supply section with the robot arm,
second work for conveying the plurality of objects from the supply section to the first test section group with the robot arm after the first work,
third work for performing work for releasing the plurality of objects and work for holding the plurality of objects with the robot arm in the first test section group after the second work,
fourth work for conveying the plurality of objects from the first test section group to the collecting section with the robot arm after the third work,
fifth work for releasing the plurality of objects in the collecting section with the robot arm after the fourth work,
sixth work for holding the plurality of objects from the supply section with the robot arm after the fifth work,
seventh work for conveying the plurality of objects from the supply section to the second test section group with the robot arm after the sixth work,
eighth work for performing work for releasing the plurality of objects and work for holding the plurality of objects with the robot arm in the second test section group after the seventh work,
ninth work for conveying the plurality of objects from the second test section group to the collecting section with the robot arm after the eighth work, and
tenth work for releasing the plurality of objects in the collecting section with the robot arm after the ninth work,
a total of a second time serving as the conveyance time for the second work and a fourth time serving as the conveyance time for the fourth work is shorter than a total of a first time serving as the processing time for the first work, a third time serving as the processing time for the third work, and a fifth time serving as the processing time for the fifth work, and
a total of a seventh time serving as the conveyance time for the seventh work and a ninth time serving as the conveyance time for the ninth work is shorter than a total of a sixth time serving as the processing time for the sixth work, an eighth time serving as the processing time for the eighth work, and a tenth time serving as the processing time for the tenth work.

6. The robot system according to claim 1, wherein
the robot includes an end effector connected to the robot arm, and
the end effector includes a turning member capable of turning around a turning axis and a plurality of holding sections provided in the turning member and configured to hold the object.

7. The robot system according to claim 1, wherein the plurality of first test sections and the plurality of second test sections are respectively disposed on an arc centering on the robot when viewed from a gravity direction.

8. The robot system according to claim 1, wherein the first test section and the second test section are disposed to overlap when viewed from a gravity direction.

9. The robot system according to claim 1, wherein
the robot and the supply section are located on an inner side of the first test section group and the second test section group when viewed from a gravity direction, and
height of an upper part of the supply section is equal to or smaller than height of an upper part of the first test section and height of the upper part of the supply section is equal to or smaller than height of an upper part of the second test section.

10. The robot system according to claim 1, wherein a setting area is 256 m² or less.

11. The robot system according to claim 1, further comprising a housing configured to house the supply section, the first test section, the second test section, the collecting section, and the robot, wherein
the first test section and the second test section respectively include test tables on which the object is placed and moving mechanisms capable of moving the test tables to an outside of the housing.

12. The robot system according to claim 11, wherein
the first test section and the second test section respectively include first members connected to the test tables and provided in the housing in a state in which the test tables are located on an inside of the housing, second members located in upper parts of the test tables in the state in which the test tables are located on the inside of the housing, and coupling members configured to couple the first members and the second members,
the test tables are located on the outside of the housing by drawing out the first members to an outer side of the housing, and
the second members function as partitioning sections for partitioning the inside and the outside of the housing in a state in which the test tables are located on the outside of the housing.

13. The robot system according to claim 1, wherein the robot performs the holding and the release of the object in the first test section selected out of the plurality of first test sections included in the first test section group and performs the holding and the release of the object in the second test section selected out of the plurality of second test sections included in the second test section group.

14. The robot system according to claim 1, wherein
the robot arm includes coupled at least two arms, and
the robot performs the conveyance of the object in a state in which the at least two arms cross from the supply to the collection of the object.

15. The robot system according to claim 1, wherein
the robot includes:
a member connected to the robot arm and including a plurality of suction sections configured to hold the object with suction;
a channel section connected to the suction section and including a channel in which gas flows;
a detecting section configured to detect pressure or a flow rate per unit time of the gas in the channel section; and
an imaging section having an imaging function, and
the robot calculates, on the basis of a detection result from the imaging section and a detection result from the detecting section, teaching points in the holding and the release of the object by the robot.
